(19) United States
(12) Patent Application Publication
(10) Pub. No.: US 2012/0250185 A1
(43) Pub. Date: Oct. 4, 2012

(54) ELECTRONIC COMPONENT CONTAINER AND ELECTRONIC DEVICE

(75) Inventor: Masaki Ishikawa, Kawasaki (JP)

(73) Assignee: FUJITSU LIMITED, Kawasaki-shi (JP)

(21) Appl. No.: 13/432,771

(22) Filed: Mar. 28, 2012

Related U.S. Application Data
(63) Continuation of application No. PCT/JP2009/067507, filed on Oct. 7, 2009.

(51) Int. Cl. H05K 7/02; G11B 5/012

(52) U.S. Cl. 360/99.08; 361/808; G9B/5.024

(57) ABSTRACT

An electronic component container includes an electronic component; a holder including a holder base part and ribs standing on the holder base part to form a container of the electronic component; and a supporting plate including a supporting plate base part and fixed to the holder. Further, the holder further includes latch protrusions protruding from the ribs above the holder base part; the supporting plate includes cutout sections so as to avoid interference with the latch protrusions when the supporting plate base part is first placed on the holder base part at a mounting position; and the supporting plate base part is latched between the latch protrusions and the holder base part.

### CROSS-REFERENCE TO RELATED APPLICATION

This application is a continuation application filed under 35 USC 111(a) claiming benefit under 35 USC 120 and 365(c) of PCT Application JP2009/067507 filed on Oct. 7, 2009, the entire contents of which are incorporated herein by reference.

### FIELD

The embodiment discussed herein is related to an electronic-component accommodating member accommodating electronic components and an electronic device including the electronic-component accommodating member.

### BACKGROUND

In recent years, products such as not only a conventional-type computer but also a television set and audio equipment and the like including a hard disk drive (hereinafter may be referred to as an “HDD”) having a large amount of capacity for storing and recording images and music have become more and more popular. For example, there has been provided a television set having a large amount of HDD which is mounted (provided) on the rear side of the image display panel including an image display screen.

Further, there has been provided a computer in which an arithmetic processing unit and the display unit are integrally configured in a manner such that, for example, in addition to the HDD, a large circuit board on which various electronic components (electronic parts) such as a Central Processing Unit (CPU) and the like and a fan for cooling heating electronic components including the CPU are mounted on the rear side of the image display panel.

In such various electronic devices, when the HDD is provided for storing images and sounds (music), a large capacity of 3.5-inch HDD or the like may be mounted (used). In such electronic devices, the size of the HDD alone is large. Further, it is desired to reserve a space due to, for example, the mounting of the HDD and cooling of the HDD. This may not be preferable to reduce the size or the thickness of the entire electronic device.

Here, Japanese Laid-open Patent Publication No. 09-82005 discloses a structure in which a guide projection is cut from a chassis side, and, on the other hand, a guide hole is formed on the bottom surface of the slide plate, and by engaging the guide projection with the guide hole the slide plate is positioned relative to the chassis in the vertical and horizontal directions.

Further, Japanese Laid-open Patent Publication No. 11-283307 discloses a structure in which a disk holder is sandwiched and guided by cut and rising pieces of the main frame.

### SUMMARY

According to an aspect of the present application, there is provided an electronic component container including an electronic component to be contained; a holder; and a supporting plate. The holder includes a holder base part, and first and second ribs standing on left and right ends, respectively, of the holder base part and extending in a front and back direction so as to form a container for containing the electronic component. The supporting plate includes a supporting plate base part extending along a lower surface of the electronic component, the lower surface facing the supporting plate base part, in a manner that a gap between the lower surface and the supporting plate base part. Further, the supporting plate is to be fixed to the electronic component, and is further to be fixed to the holder in a manner that, when the electronic component is to be contained into the container, the supporting plate base part is placed at a mounting position of the container of the holder in the direction where the supporting plate base part is to be in contact with the holder base part, and the supporting plate is slid forward from the mounting position to a supporting position.

Further, the holder further includes latch protrusions protruding in a lateral direction from the first and the second ribs, above the holder base part, and at a height position corresponding to the height position of the supporting plate base part when the supporting plate base part is placed on the holder base part.

Further, the supporting plate includes cutout sections formed at positions on left and right ends of the supporting plate base part so as to avoid interference with the latch protrusions when the supporting plate base part is placed on the holder base part at the mounting position.

Further, when the supporting plate is slid forward from the mounting position to the supporting position, the supporting plate base part is latched between the latch protrusions and the holder base part.

The objects and advantages of the embodiments disclosed herein will be realized and attained by means of the elements and combinations particularly pointed out in the claims.

It is to be understood that both the foregoing general description and the following detailed description are exemplary and explanatory and are not restrictive of the invention as claimed.

### BRIEF DESCRIPTION OF DRAWINGS

FIG. 1 is an external perspective view of an electronic device according to a first embodiment when obliquely viewed from the front side;

FIG. 2 is an external perspective view of the electronic device of FIG. 1 when obliquely viewed from the rear side;

FIGS. 3A through 3E are views of the electronic device of FIG. 1 when viewed from corresponding directions;

FIG. 4 is a perspective view of the electronic device of FIG. 1 when a supporting stand and a rear cover are removed when obliquely viewed from the rear side;

FIG. 5 another perspective view of the electronic device of FIG. 1 when the supporting stand and the rear cover are removed when obliquely viewed from the rear side;

FIG. 6 is an exploded view of the electronic device when a rear shield plate is further removed in the state of FIG. 5;

FIG. 7 is a perspective view of the electronic device of FIG. 5 after a rear shield plate is removed when obliquely viewed from the rear side;

FIG. 8 is an exploded perspective view of the electronic device when two holders are further removed in the state of FIG. 7;

FIG. 9 is a perspective view of the inside of the electronic device of FIG. 8 after the two holders are removed when obliquely viewed from the rear side;

FIG. 10 is an exploded perspective view of the electronic device when a supporting member is removed in the state of FIG. 8;

FIG. 11 is a perspective view of one of the two holders where electronic components are mounted;

FIG. 12 is a perspective view of the holder of FIG. 11 from which the electronic components are removed;

FIG. 13 is an enlarged perspective view of a side surface of the holder (holder 7) of FIG. 12;

FIG. 14 is a perspective view of the other holder of the two holders;

FIG. 15 is a top view of the surface of the side (rear-cover-side surface) of the holder of FIG. 8;

FIG. 16 is a top view of the surface of the image display panel side of the holder of FIG. 15;

FIG. 17 is a perspective view of one side surface of the supporting member;

FIG. 18 is a top view of the electronic device to which the two holders are fixed;

FIG. 19 illustrates a modified example of the electronic device corresponding to FIG. 18;

FIG. 20 is an exploded perspective view of the electronic device when the holder is removed in a comparative example of this embodiment;

FIGS. 21A through 20E are views of an electronic device according to a second embodiment when viewed from corresponding directions;

FIG. 22 is a perspective view of the electronic device according to the second embodiment when a supporting stand and a rear cover are removed when obliquely viewed from the rear side;

FIG. 23 is an exploded perspective view of the electronic device when a rear shield plate is further removed in the state of FIG. 22;

FIG. 24 is an exploded perspective view of the electronic device when two holders are further removed in the state of FIG. 23;

FIG. 25 is an exploded perspective view of the electronic device when a supporting member is removed in the state of FIG. 24;

FIG. 26 illustrates a modified example of the second embodiment and corresponds to FIG. 19 of the first embodiment;

FIG. 27 is a perspective view of an upper end part of a holder disposed on the supporting part of a supporting member 9 of FIG. 8;

FIG. 28 is an exploded perspective view of the part illustrated in FIG. 27;

FIG. 29 is a perspective view of a part of the upper right corner of the holder 7 on the supporting member 9 (upper left corner in the state of FIG. 1);

FIG. 30 is a perspective view of the part of the holder 7 when viewed from an outer side (upper side of FIG. 1) of the holder 7;

FIG. 31 is an enlarged perspective view of a partial region of the part of FIG. 29 when the holder is disposed at a “mounting position”;

FIG. 32 is an enlarged perspective view of the partial region of FIG. 31 when the holder is disposed at a “supporting position”;

FIG. 33 is a partial perspective view illustrating a structure of another opening part formed on a beam of the holder;

FIG. 34 is a partial perspective view illustrating a structure of the opening part formed on a beam of the holder;

FIG. 35 is an enlarged perspective view of the opening part when viewed from an inner surface side of the beam of the holder;

FIG. 36 is a top view of the opening part when viewed from the rear cover side;

FIG. 37 is a cross-sectional view when cut along the X-X line of FIG. 36;

FIG. 38 is a cross-sectional view when cut along the Y-Y line of FIG. 36;

FIG. 39 is en enlarged view of the part of a circle R of FIG. 38;

FIG. 40 illustrates one comparative example;

FIG. 41 illustrates another comparative example;

FIG. 42 is an exploded perspective view of a structure of fixing an HDD unit according to a comparative example;

FIG. 43 is a top view of a state when the HDD unit of FIG. 42 is in a mounted (assembled) state;

FIG. 44 is a perspective view of a part of an HDD container of the holder of the electronic device according to the first embodiment, the exterior of the electronic device being illustrated in FIGS. 1 through 3;

FIG. 45 is an exploded perspective view of the holder, a supporting plate, and the HDD;

FIG. 46 is a perspective view of the HDD container of the holder when only the supporting plate without the HDD is accommodated (contained) in the HDD container;

FIG. 47 is a perspective view of the HDD unit having the HDD on which the supporting plate is mounted when viewed from an upper side of the HDD;

FIG. 48 is a perspective view of the HDD unit when viewed from a supporting plate based part;

FIG. 49 is a top view illustrating a state where the supporting plate from which the HDD is removed is accommodated (contained) in a supporting position of the HDD container;

FIG. 50 is a left side view of a state where the supporting plate with HDD (i.e., the HDD unit) is contained in the supporting position of the HDD container of the holder;

FIG. 51 is a top view of a state where the supporting plate with HDD (HDD unit) is contained in the supporting position of the HDD container of the holder;

FIGS. 52A and 52B are enlarged views of a part of a circle R of FIG. 49;

FIG. 53 is an enlarged view of a part of a circle R of FIG. 50;

FIG. 54 is a cross-sectional view when cut along the line X-X of FIG. 51;

FIG. 55 is an enlarged view of a part of a circle R of FIG. 54;

FIG. 56 is a view illustrating a procedure of containing the HDD unit in the HDD container;

FIG. 57 is another view illustrating a procedure of containing the HDD unit in the HDD container;

FIG. 58 is another view illustrating a procedure of containing the HDD unit in the HDD container;

FIG. 59 is another view illustrating a procedure of containing the HDD unit in the HDD container;

FIG. 60 is another view illustrating a procedure of containing the HDD unit in the HDD container;

FIG. 61 is another view illustrating a procedure of containing the HDD unit in the HDD container;

FIG. 62 is another view illustrating a procedure of containing the HDD unit in the HDD container;

FIG. 63 is a top view of the HDD unit when being contained in the HDD container;

FIG. 64 is a cross-sectional view when cut along the line Y1-Y1 of FIG. 63;

FIG. 65 is a cross-sectional view when cut along the line Y2-Y2 of FIG. 63;

FIG. 66 is an enlarged view of a part of a circle R of FIG. 64;

FIG. 67 is an enlarged view of a part of a circle R of FIG. 65;

FIG. 68 is a perspective view of the holder and the supporting plate to be fixed to the HDD in the electronic device according to the second embodiment, the exterior electronic device being illustrated in FIG. 21;

FIG. 69 is a perspective view illustrating a state where the supporting plate from which the HDD is removed is contained in the HDD container;

FIG. 70 is another perspective view illustrating the state where the supporting plate from which the HDD is removed is contained in the HDD container;

FIG. 71 is a perspective view of the HDD unit where the supporting plate is attached to the HDD when viewed from the upper surface side of the HDD;

FIG. 72 is a perspective view of the HDD unit when viewed from the supporting plate based part side

FIG. 73 is a perspective view illustrating a state where the HDD unit including the HDD is placed at the mounting position of the HDD container;

FIG. 74 is a perspective view illustrating a state where the HDD unit has been moved from the mounting position in FIG. 73 to the supporting position;

FIG. 75 is a perspective view illustrating a state where the HDD unit is further tightened with a screw;

FIG. 76 is a top view illustrating a state where the supporting plate from which the HDD is removed is contained in (to) the supporting position of the HDD container of the holder;

FIG. 77 is a left side view illustrating a state where the supporting plate having the HDD (i.e., the HDD unit) is contained in the supporting position of the HDD container of the holder;

FIG. 78 is a top view illustrating the state where the supporting plate having the HDD (HDD unit) is contained in the supporting position of the HDD container of the holder;

FIGS. 79A and 79B are enlarged views of a part of a circle R of FIG. 76;

FIG. 80 is an enlarged view of a part of a circle R of FIG. 77;

FIG. 81 is a cross-sectional view when cut along the line X-X of FIG. 78;

FIG. 82 is an enlarged view of a part of the circle R of FIGS. 76 and 77;

FIG. 83 is an exploded perspective view of the image display panel;

FIG. 84 is a perspective view illustrating a state where a double-sided adhesive tape is adhered on the image display plate;

FIG. 85 is a perspective view illustrating a state where a protection panel is further placed on the image display plate;

FIG. 86 is a perspective view illustrating a state where an optical touch sensor is integrated on the protection panel;

FIGS. 87A and 87B are views illustrating a configuration of the double-sided adhesive tape;

FIG. 88 is a schematic view illustrating a corner of the image display panel;

FIG. 89 is a view illustrating a state where the protection panel is separated from the image display plate by drawing a tag of the double-sided adhesive tape;

FIGS. 90A through 90F are views illustrating various types of the double-sided adhesive tapes;

FIG. 91 is a top view illustrating a front surface of the image display panel;

FIG. 92 is a top view illustrating infrared light emitting and receiving units disposed at a left upper corner on the front surface of the image display panel;

FIG. 93 is a top view illustrating the infrared light emitting and receiving units disposed at a right upper corner on the front surface of the image display panel;

FIG. 94 is a view illustrating a front cover supporting the image display panel when viewed from the front side of the front cover;

FIG. 95 is a cross-sectional view when cut along the line X-X of FIG. 94;

FIG. 96 is an enlarged view of a part of a circle R of FIG. 95;

FIG. 97 is a cross-sectional view when cut along the line Y-Y of FIG. 94;

FIG. 98 is an enlarged view of a part of a circle R of FIG. 97;

FIG. 99 is a perspective view of an entire reinforcing bracket;

FIG. 100 is a top view illustrating an upper part of the inner surface of the front cover when the reinforcing bracket is attached to the front cover;

FIG. 101 is a perspective view illustrating an inner surface side of the front cover in the state of FIG. 100;

FIG. 102 is an enlarged perspective view illustrating a part of the upper side of the inner surface of the front cover in the state of FIG. 100;

FIG. 103 is a top view illustrating the upper side of the inner surface of the front cover when a supporting member 9 is further fixed to the front cover;

FIG. 104 is a perspective view illustrating the upper side of the inner surface of the front cover when the supporting member 9 is further fixed to the front cover; and

FIG. 105 is an enlarged cross-sectional view when cut along the line Y-Y of FIG. 103.

### DESCRIPTION OF EMBODIMENTS

In the following, embodiments of the present application are described with reference to the accompanying drawings.

In reducing a space for mounting electronic component (part) such as an HDD, it is desired to provide a space in consideration of sufficient cooling performance and mounting a reliably fixing unit as well as accurately guiding the electronic component.

### Exterior

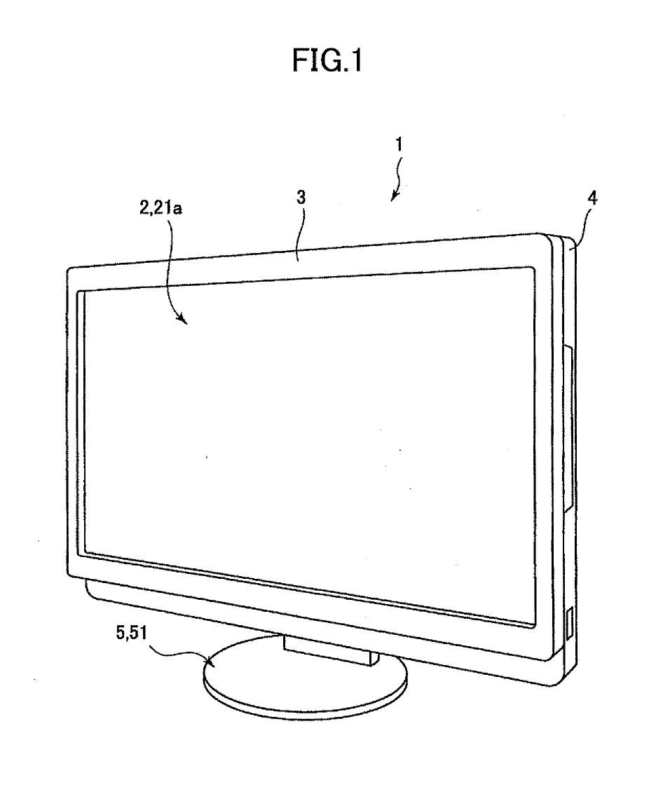

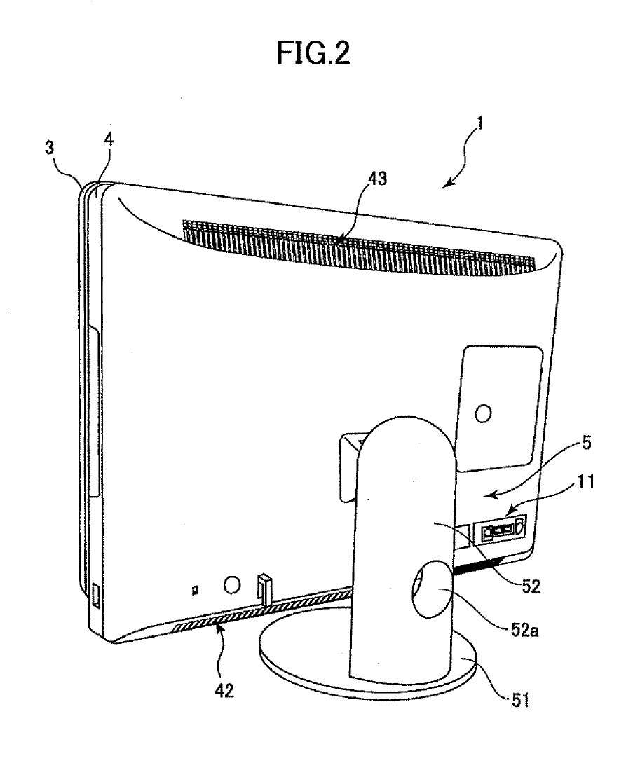

FIG. 1 is an external perspective view of an electronic device 1 according to a first embodiment when obliquely viewed from the front side of the electronic device. Further, FIG. 2 is an external perspective view of the electronic device 1 of FIG. 1 when obliquely viewed from the rear side of the electronic device.

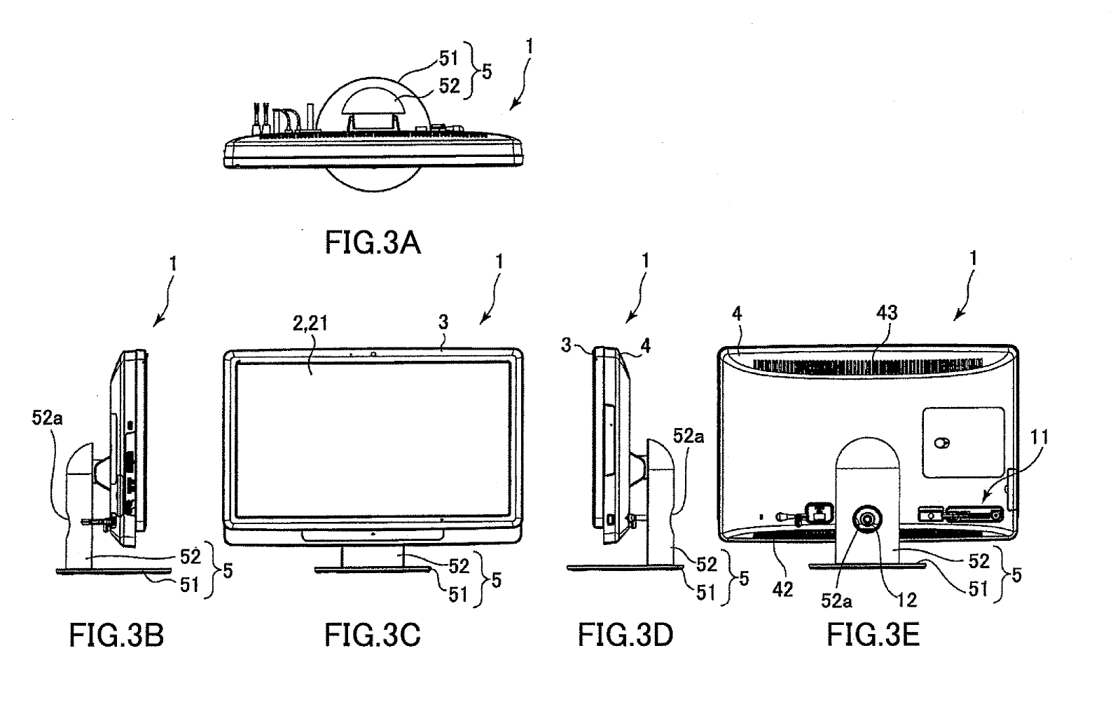

Further, FIGS. 3A through 3E are views of the electronic device 1 of FIGS. 1 and 2 when viewed from corresponding directions. More specifically, FIG. 3A is a top view; FIG. 3B is a left side view; FIG. 3C is a front view; FIG. 3D is a right side view; and FIG. 3E is a rear view.

The electronic device 1 includes an image display panel 2 having a front surface where an image display screen 21a for displaying images is formed. The image display panel 2 has a rectangular plate shape including a front surface where the image display screen 21a is formed and a rear surface disposed opposite to the front surface.

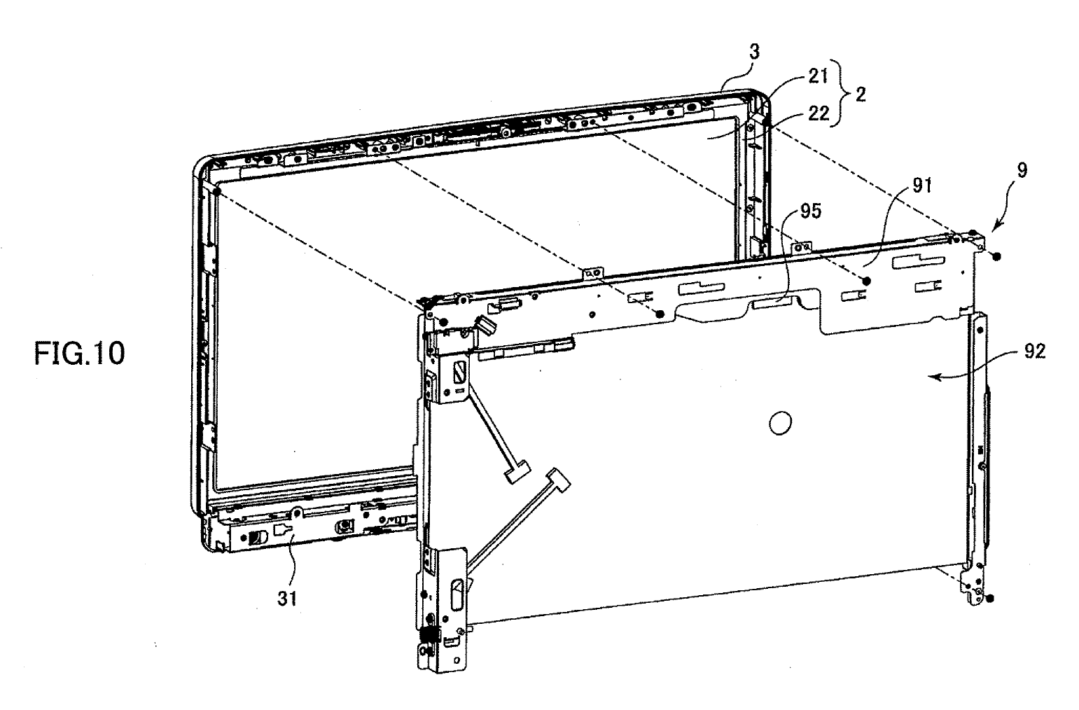

The image display panel 2 further includes an image display plate 21 having a front surface including the image display screen 21a and a frame body 22 supporting the image display plate 21 by circumferentially surrounding the image display plate 21 (see FIG. 10).

The image display panel 2 is contained (accommodated) in a chassis including a front cover 3 and a rear cover 4 in a manner such that the image display screen 21a is exposed. The front cover 3 circumferentially surrounds a peripheral boarder (rim) of a front surface of the image display panel 2.

The front cover 3 is a cover member having a frame shape and supports the frame body 22 circumferentially surrounding the image display panel 2, so that the image display screen 21a on the front surface of the image display plate 21 surrounded by the frame body 22 is exposed.

The front cover 3 has a size protruding from the peripheral border (circumference) of the image display panel 2, and, by using the protruded part, electronic components and the like are mounted on the rear surface side of the image display panel 2 and the rear cover 4 is fixed to the front cover 3 with screws.

Further, the rear cover 4 forms an inner space between the rear cover 4 and the image display panel 2 and extends along the rear surface of the formed inner space, so that the rear cover 4 along with the front cover 3 defines the exterior form (shape) of the electronic device 1.

The electronic device 1 includes a function of a personal computer and a function of a television set, and various connectors 11 and a cable connection terminal 12 for a television antenna are located (placed) on the rear cover 4 side. A cable for the television antenna may be connected to the cable connection terminal 12 via a hole 52a formed on a supporting pole 52 described below. Further, air inlets 42 are formed on the lower part of the rear cover 4 to introduce air for cooling, and air outlets 43 are formed on the upper part of the rear cover 4 to exhaust air.

The electronic device 1 is supported by a supporting stand 5 in a manner such that the image display screen 21a is in a standing state. The supporting stand 5 includes a stand 51 having a circular shape and the supporting pole 52 standing on the stand 51, so that the rear surface side of the electronic device 1 is supported by the supporting pole 52.

As described above, the hole 52a is formed on the supporting pole 52. The supporting pole 52 rotatably supports the electronic device 1, so that the direction of the electronic device 1 changes between a state where the image display screen 21a faces in the horizontal direction and a state where the image display screen 21a faces obliquely upward.

### Component Mounting Structure

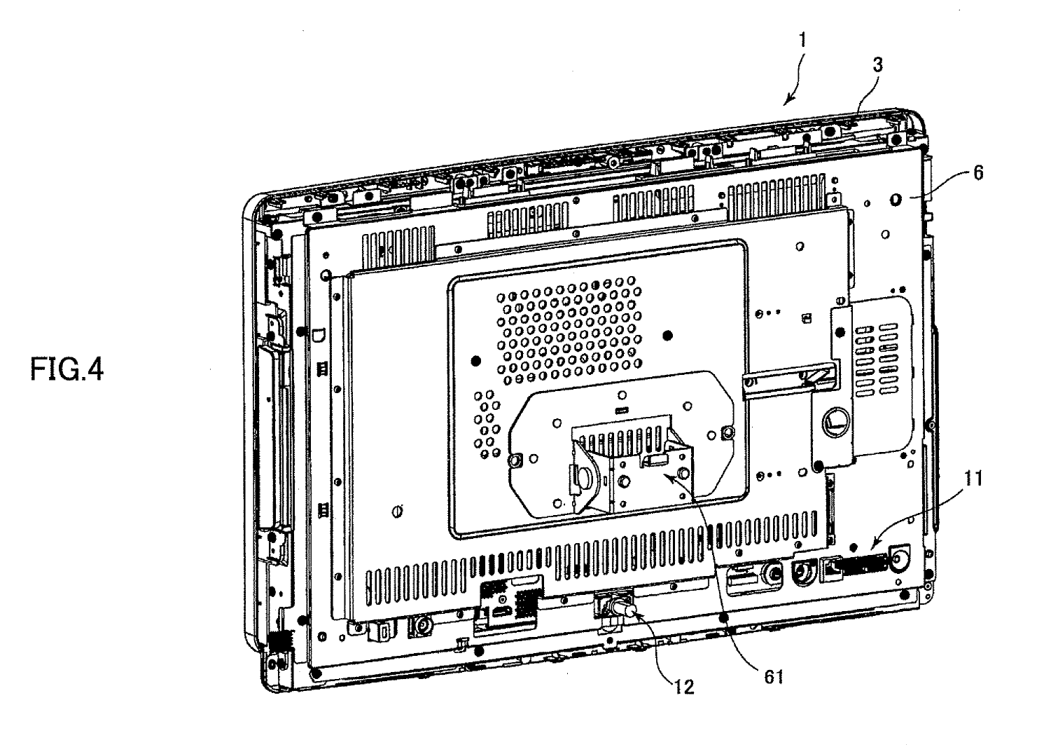

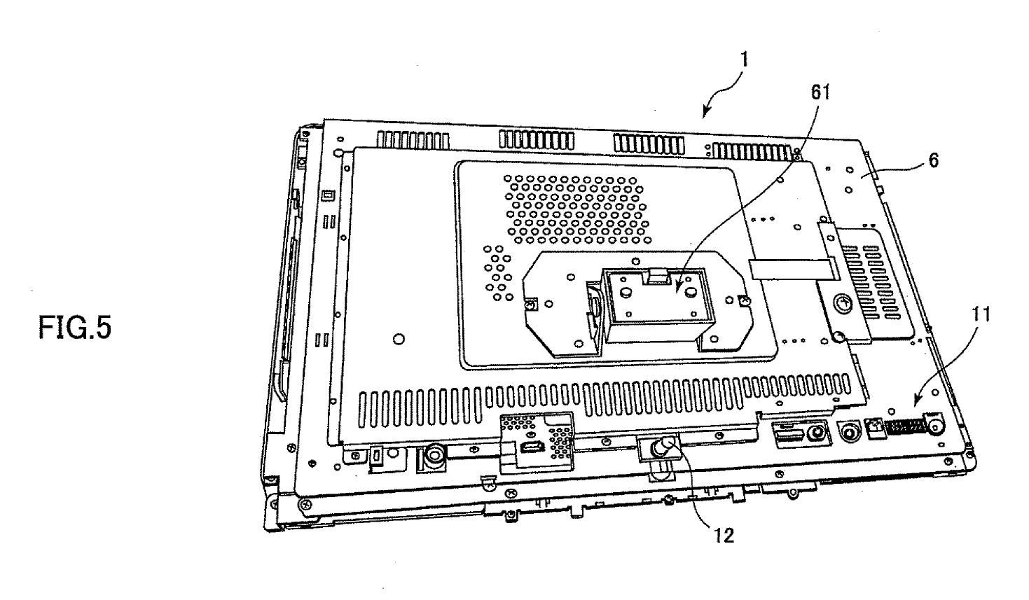

FIGS. 4 and 5 are perspective views of the electronic device 1 of FIGS. 1 through 3 when a supporting stand 5 and the rear cover 4 are removed when obliquely viewed from the corresponding rear sides.

Here, there is provided a rear shield plate 6 extending across the inner surface of the (removed) rear cover 4 and broadly covering various electronic components and the like mounted on the electronic device 1. Due to the rear shield plate 6, the electronic components and the like disposed inside the rear shield plate 6 are shielded. Further, a supporting part 61 is provided in a center part of the rear shield plate 6 so as to be supported by the supporting stand 5.

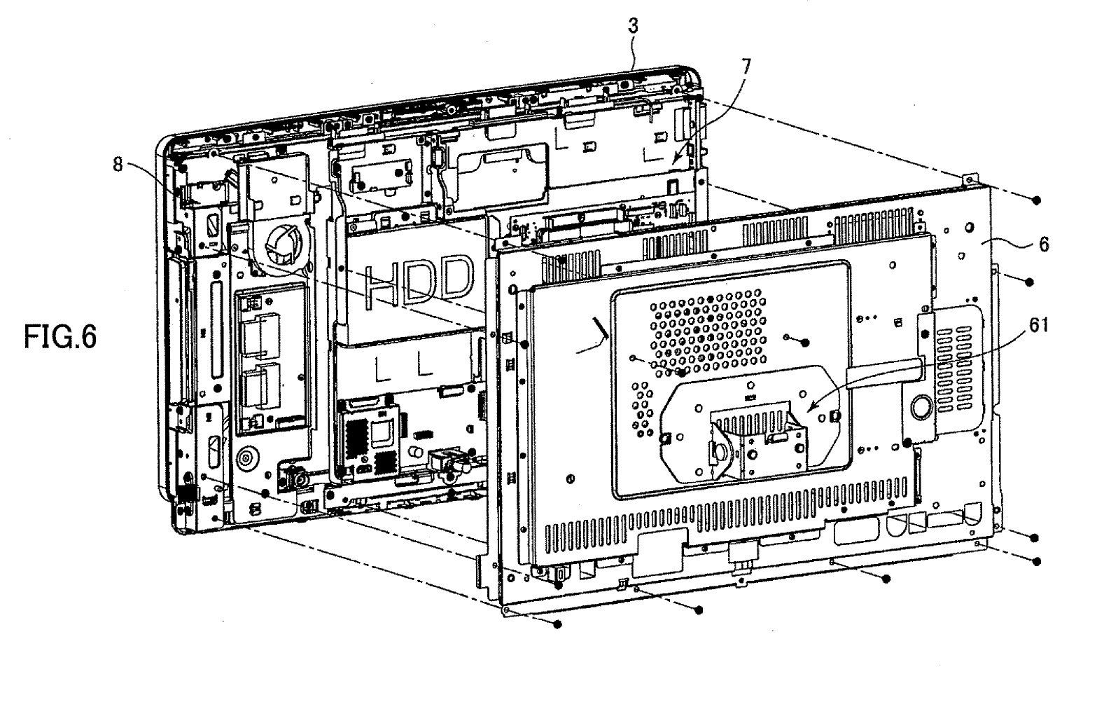

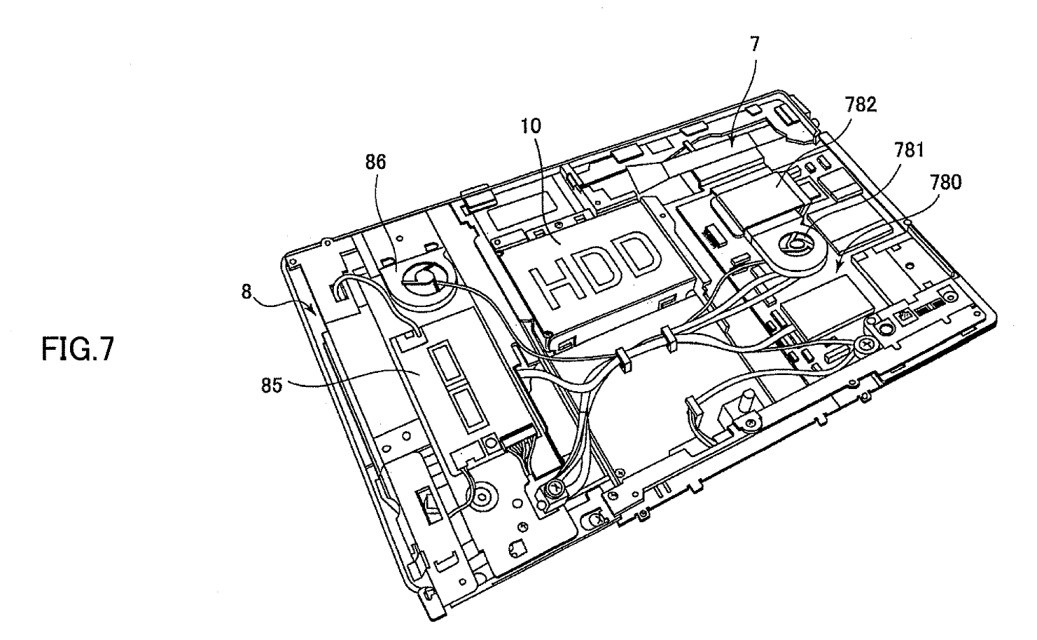

FIG. 6 is an exploded view of the electronic device 1 when the rear shield plate 6 is further removed in the state illustrated in FIGS. 4 and 5. Further, FIG. 7 is a perspective view of the electronic device 1 when the rear shield plate 6 is further removed in the state illustrated in FIGS. 4 and 5 when obliquely viewed from the rear surface side.

As illustrated in FIG. 6, the rear shield plate 6 is fixed with screws. When the rear shield plate 6 is removed by removing the screws, two holders 7 and 8 on which various electronic components are mounted are exposed on the inner side of the rear shield plate 6.

Before details of the holders 7 and 8 are described, the configuration of the electronic device 1 is more discussed by further breaking down the electronic device 1.

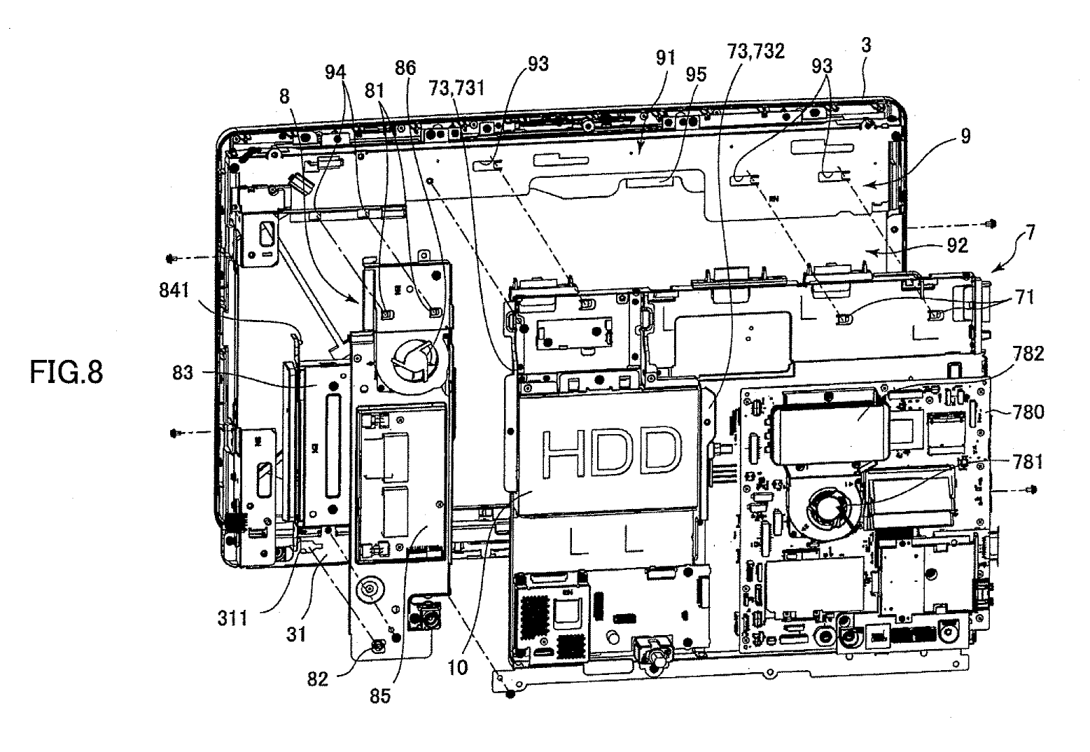

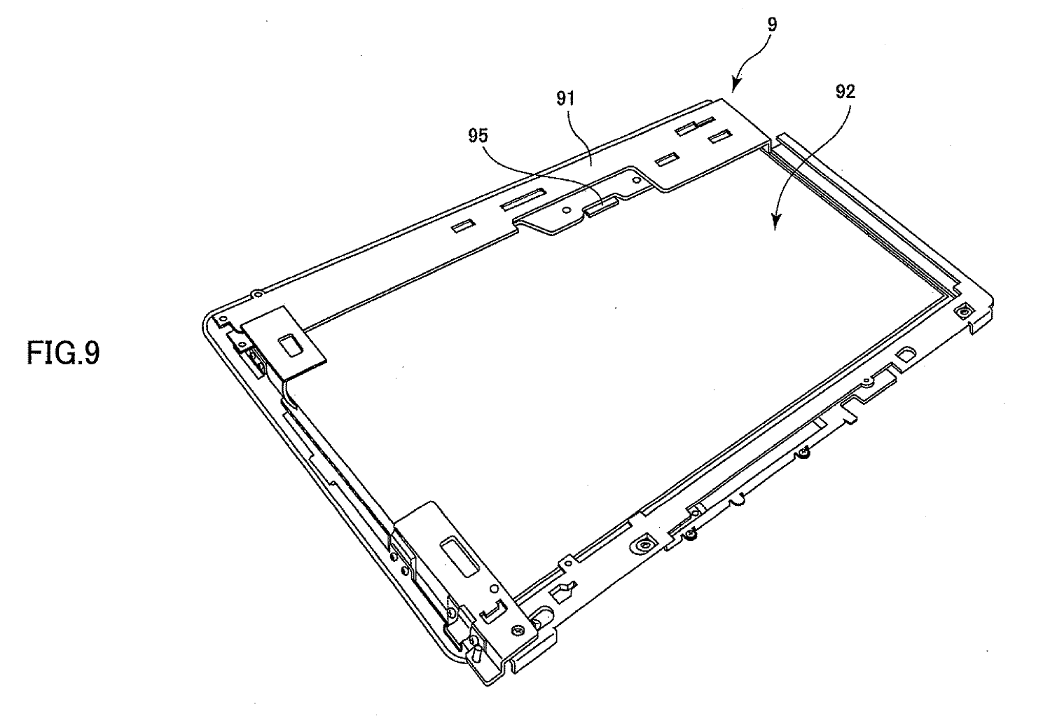

FIG. 8 is an exploded perspective view of the electronic device 1 when the two holders 7 and 8 are further removed in the states as illustrated in FIGS. 6 and 7. FIG. 9 is a perspective view of the inner side of the electronic device 1 when the holders 7 and 8 are removed when obliquely viewed from the rear surface side. On the inner side (i.e., the image display panel 2 side) of the two holders 7 and 8, there is a fixed supporting member 9.

The supporting member 9 includes a supporting part 91 and a shielding part 92. The supporting part 91 extends in the horizontal (right and left) direction along the upper end of the image display panel 2. The shielding part 92 widely spreads on the rear surface side of the image display panel 2. The supporting part 91 supports the holders 7 and 8. The shielding part 92 mainly provides shielding between the image display panel 2 and the electronic components on the holders 7 and 8.

As illustrated in FIG. 9, the supporting part 91 overlaps with the shielding part 92, so that a space is formed between the supporting part 91 and the shielding part 92. In the space between the supporting part 91 and the shielding part 92, variable circuits (not explicitly shown) including a driving circuit to drive the image display panel 2 are provided (mounted).

FIG. 10 is an exploded perspective view of the electronic device 1 when the supporting member 9 is further removed in the states illustrated in FIGS. 8 and 9.

As illustrated in FIG. 10, the supporting member 9 is fixed to the rear surface of the front cover 3 with screws.

Further, FIG. 10 illustrates the rear surface of the image display panel 2. As described above, the image display panel 2 includes the image display plate 21 and the frame body 22. The frame body 22 supports the image display plate 21 by circumferentially surrounding the image display plate 21 and the circumference of the image display plate 21.

The image display plate 21 includes the image display screen 21a on the front surface of the image display plate 21. The front cover 3 has the rear surface which is in contact with the frame body 22 of the image display panel 2 to support the image display panel 2, so that the front surface of the image display plate 21 (i.e., the image display screen 21a) is exposed forward (see FIG. 1).

Further, as illustrated in FIG. 3, the front cover 3 includes a supporting arm 31 at the lower part of the front cover 3. The supporting arm 31 extends in the horizontal direction along the lower end of the image display panel 2. Along with the supporting member 9, the supporting arm 31 supports the holders 7 and 8 (see, for example, FIG. 8).

With reference to FIGS. 6 through 8 and other new figures, the holders 7 and 8 are described.

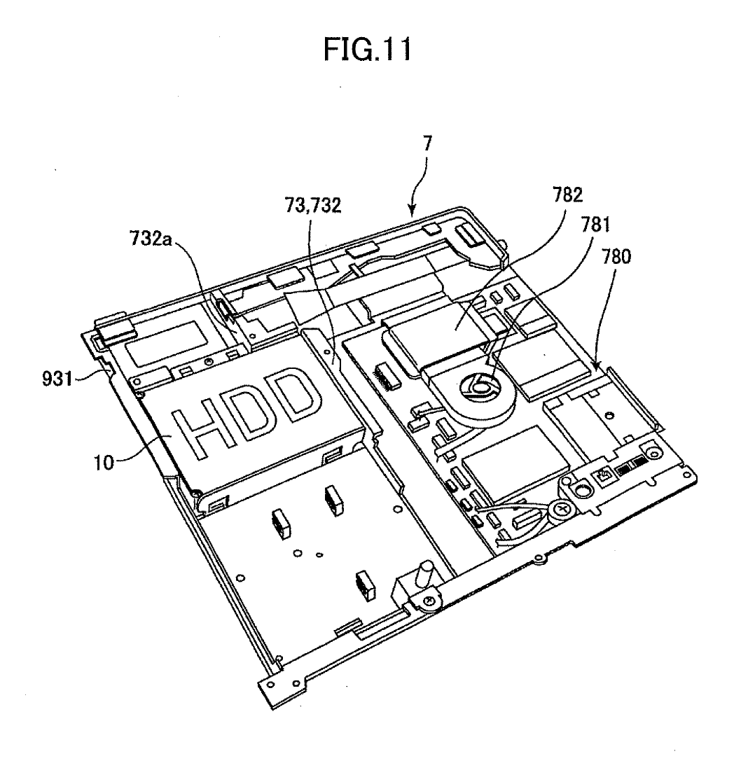

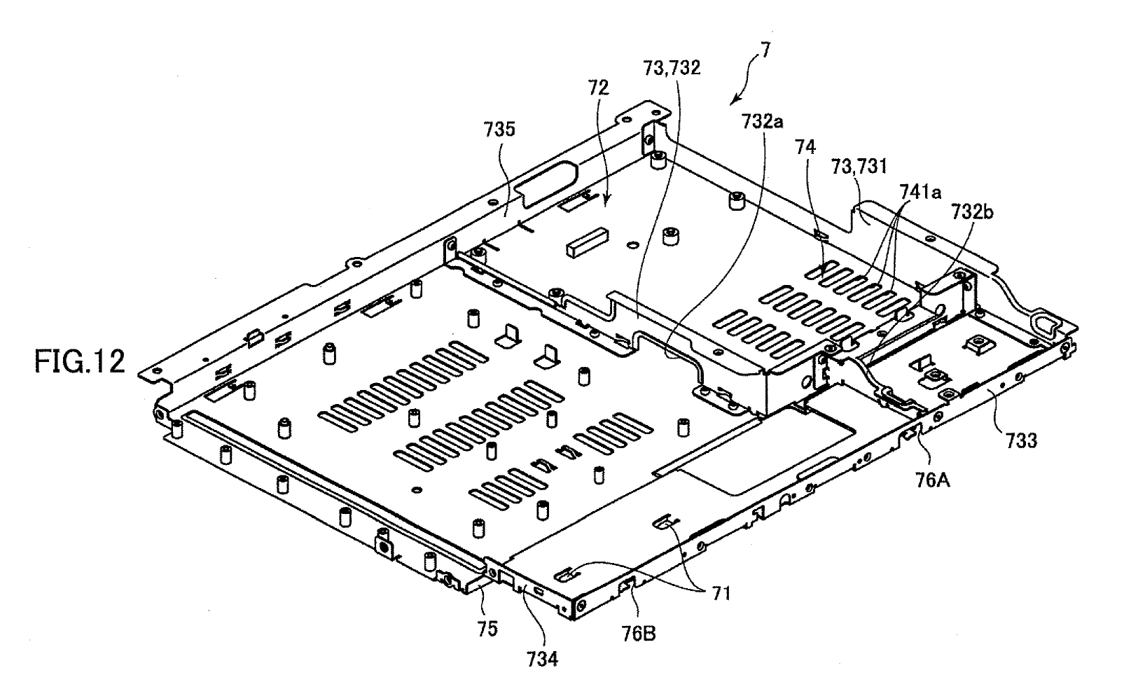

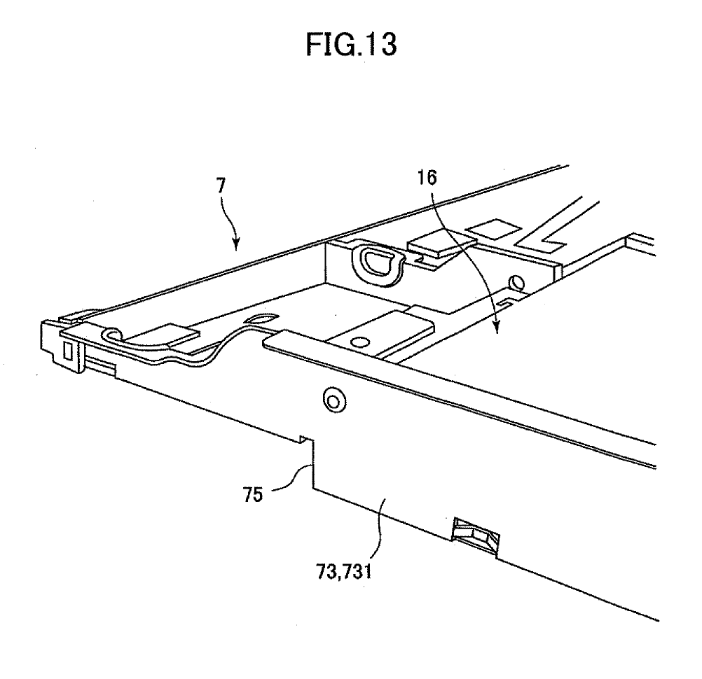

FIG. 11 is a perspective view of the holder 7 which is one of the holders 7 and 8 and where electronic components are mounted. FIG. 12 is a perspective view of the holder 7 alone when the electronic components are removed from the holder 7. Further, FIG. 13 is an enlarged perspective view of a part of a side surface of the holder 7.

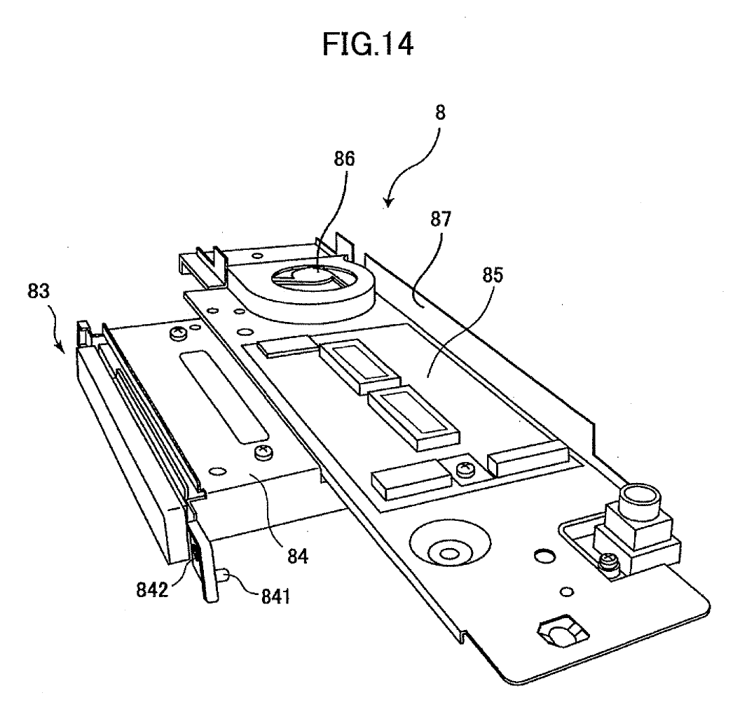

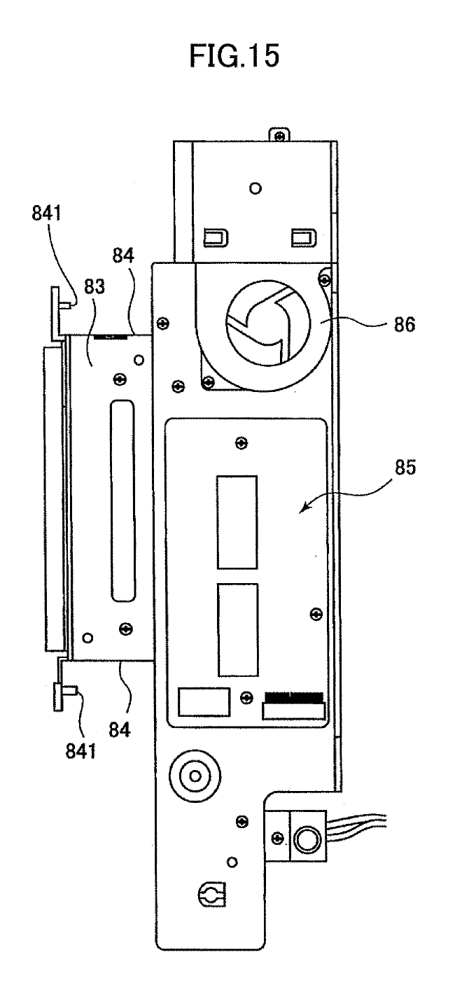

Further, FIG. 14 is a perspective view of the holder 8. FIG. 15 is a top view of the surface of the side (rear-cover-side surface) illustrated in FIGS. 8 and 14 of the holder 8.

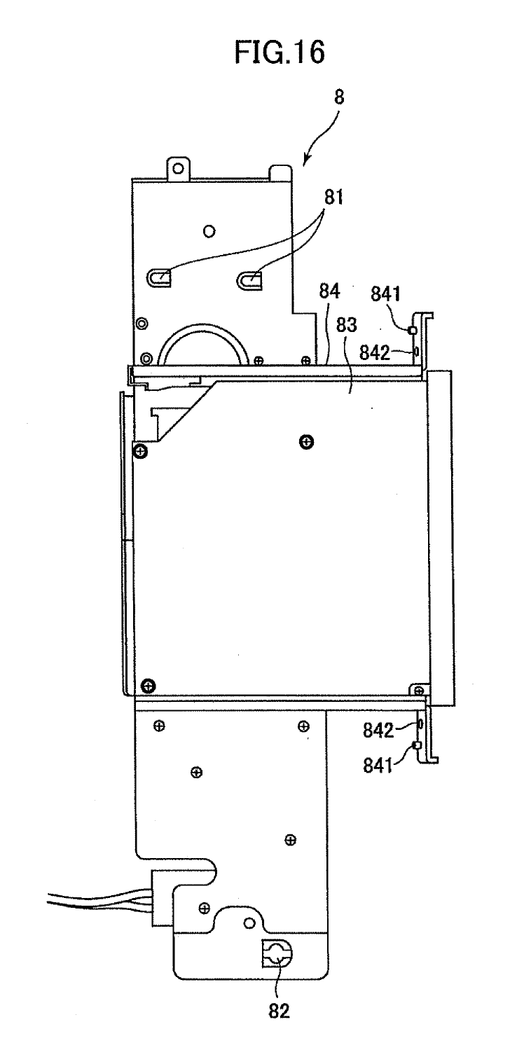

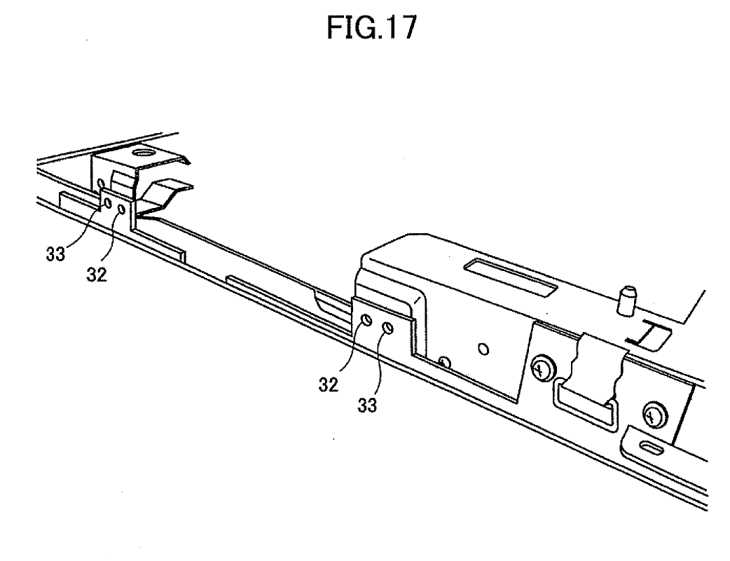

FIG. 16 is a top view of the surface of the image display panel side of the holder 8 illustrated in FIG. 15. Further, FIG. 17 is a perspective view of one side surface of the supporting member 9 (the side surface on the side where the holder 8 is fixed).

On the inner side of the rear shield plate 6, the two holders 7 and 8 are arranged side by side along the image display panel 2. Further, as illustrated in FIG. 8, each of the two holders 7 and 8 is fixed to the supporting member 9 and the supporting arm 31 at the lower end of the front cover 3.

As illustrated in FIG. 8, the holder 7 which is one of the holders 7 and 8 includes plural latching pieces 71 which are formed by cutting and standing (rising) toward the supporting member 9 side. On the other hand, the supporting member 9 includes latching holes 93 formed at the positions corresponding to the positions of the latching pieces 71 when the holder 7 is supported by (fixed to) the supporting member 9. Therefore, when the holder 7 is supported by supporting member 9, the holder 7 is placed on the supporting member 9, so that the latching pieces 71 are inserted into the corresponding latching holes 93.

Then, the holder 7 is slid in the right direction of FIG. 8, so that the holder 7 is in contact with the inner surface of the supporting member 9 on the right side of FIG. 8. Then, the latching pieces 71 protrude to the rear side (image display panel 2 side) of the supporting part 91, so that the holder 7 is latched by the supporting member 9. Similar latch mechanisms are also provided (employed) on the side of the supporting arm 31 extending along the lower end of the front cover 3.

However, the latch mechanisms are not shown in the figures. Therefore, the description thereof is omitted. The holder 7 having been latched as described above is further fixed with screws. Here, by not only using screws but also (additionally) using the latching mechanism (latching means), it may become possible to reduce the number of screws to fix the holder to the supporting member.

The above latching mechanism is also employed when the holder 8 is fixed. Namely, the holder 8 also includes plural latching pieces 81 which are formed by cutting and standing (rising) toward the supporting member 9 side. The holder 8 further includes a latching protrusion 82 which protrudes toward the supporting arm 31 side. On the other hand, the supporting member 9 includes latching holes 94 formed at the positions corresponding to the positions of the latching pieces 81 when the holder 8 is supported by (fixed to) the supporting member 9.

Also, the supporting arm 31 includes a latching hole 311 formed at the position corresponding to the position of the latching protrusion 82 when the holder 8 is supported by (fixed to) the supporting arm 31. The holder 8 is placed on the supporting member 9 and the supporting arm 31, in a manner such that the latching pieces 81 are inserted into the corresponding latching holes 94 and the latching protrusion 82 is inserted into the latching hole 311. Then the holder 8 is slid in the right direction of FIG. 8.

Then, the latching pieces 81 protrude to the rear side (image display panel 2 side) of the supporting part 91 and the latching protrusion 82 protrude to the rear side of the supporting arm 31, so that the holder 8 is latched by the supporting member 9 and the supporting arm 31. The holder 8 having been latched as described above is further fixed with screws. In this case as well, by not only using screws but also (additionally) using the latching mechanism (latching means), it may become possible to reduce the number of screws to fix the holder to the supporting member.

The holder 8 mounts (holds) an Optical Disk Drive unit (hereinafter simplified as an “ODD”) 83 via a supporting bracket 84 as illustrated in FIG. 16, for example. The ODD 83 is a device that includes an optical disk that is a kind of a recording medium and that is operated by rotary driving the optical disk to write data into the optical disk (in case of a writable optical disk) and read data from the optical disk.

As illustrated in FIG. 16, for example, the supporting bracket 84 includes a protrusion 841 protruding inward and a hole 842 formed at a position adjacent to the protrusion 841 at each of the right and left sides extended from the ODD 83.

On the other hand, as illustrated in FIG. 17, the front cover 3 includes holes 33 and screw holes 32 formed at positions adjacent to the corresponding holes 33 on the side surface of the front cover 3 (left side surface side in FIG. 8). As described with reference with FIG. 8, the holder 8 is slid in the right direction of FIG. 8 while the latching pieces 81 and the latching protrusion 82 are inserted in the latching holes 94 and the latching hole 311, respectively.

In this case, the latching pieces 81 and the latching protrusion 82 protrude to the rear sides of the supporting part 91 of the supporting member 9 and the supporting arm 31, respectively. In the sliding of the holder 8, in the side surface of the front cover 3, the protrusions 841 of the holder 8 are inserted in the corresponding holes 33, and the holes 842 and the corresponding screw holes 32 of the front cover 3 are in communication with each other. By doing this, the (relative) position of the holder 8 is determined. Then, the holder 8 is fixed with screws.

The description of a method of assembling the holders 7 and 8 is finished. Next, structures (configurations) of the holders 7 and 8 are described.

The holder 7 is equipped with a Hard Disk Drive (HDD) 10. The HDD 10 is a device including a hard disk to which data are magnetically written and from which the data are read and a motor to rotate the hard disk, so that data are written into and read from the hard disk while the hard disk is rotated. The holder 7 is further equipped with a main board 780. On the main board 780, various electronic components and a cooling mechanism (cooling means) including, for example, a fan 781 and a cooling member 782 are mounted. Further, a Large Scale Integration (LSI) (not shown) integrating a Central Processing Unit (CPU) for executing a program are mounted between the main board 780 and the cooling member 782.

The CPU is one of the heat-generating components and is heated while being operated. The heat generated by the CPU is absorbed by the cooling member 782 and then transferred to air by air flow generated by the fan 781. Then the heated air is exhausted through the air outlets 43 formed on the upper part of the rear cover 4 (see FIG. 2).

The holder 7 is made of a metal plated and is manufactured by a sheet-metal processing. Further, as illustrated in FIG. 12, the holder 7 includes a base part (holder base part) 72 extending along the image display panel 2 and a beam (rim, rib) part 73 standing on the base part 72 and extending in the longitudinal direction. The beam part 73 includes a first beam part 731 and a second beam part 732.

The first beam part 731 is formed on an end of the base part 72, so as that the first beam part 731 extends along the end of the base part 72 in the vertical direction. The second beam part 732 is formed on and fixed to the vertical line passing through a mid point of the horizontal direction of the base part 72, and extends in the vertical direction similar to the first beam part 731.

In the region defined between the first beam part 731 and the second beam part 732, there is provided an HDD container 74 where the HDD 10 (see FIGS. 7 and 8) is contained (accommodated, or mounted). The HDD container 74 includes plural holes 741a to promote cooling of the HDD 10 contained in the HDD container 74. More details are described below.

Further, as illustrated in FIG. 13, a step part 75 is formed on the holder 7. Here, as illustrated in FIG. 9, a supporting part 91 of the supporting member 9 extends along the upper end of the image display panel 2. On the rear side of the supporting part 91, a circuit to drive the image display panel 2 is mounted.

Therefore, the part of the supporting member 9 having the supporting part 91 is thicker than any other part of the supporting member 9. Therefore, by forming the step part 75 on the holder 7, by deeply forming a part lower than the supporting part 91, and by positioning the HDD container 74 in the deeply formed part, thickness of the entire device is adjusted to be thinner.

On the second beam part 732, an opening 732a is formed so as to pass cables (see FIG. 12). The second beam part 732 extends to a part of the holder 7, the part being placed on the supporting part 91 of the supporting member 9 and being formed thinner in a thickness direction. In a part 732b which is a part of the second beam part 732 and is an extended part disposed above the supporting part 91, a beam having different steps in the lateral (horizontal) direction is formed.

This is to avoid the interference with a cable 95 connected to the circuit to drive the image display panel 2 and mounted on the supporting member 9. Besides the first beam part 731 and the second beam part 732, the holder 7 further includes beam parts 733, 734, and 735 which are formed by bending along the peripheral border of the base part 72.

The beam part 733 formed along the upper end (peripheral border) of the base part 72 includes opening parts 76A and 76B to pass cables passing (relevant to) the base part 72 and the beam part 733. Those opening parts 76A and 76B are described below.

By doing this, the strength of the holder 7 is strengthened by the formed beam parts 731 through 735 (especially by the two beam parts 731 and 732 extending in the vertical direction).

The other holder 8 also has a beam part 87 extending in the vertical direction as illustrated in, for example, FIG. 14. Due to the beam part 87, the strength of the holder 8 is also strengthened.

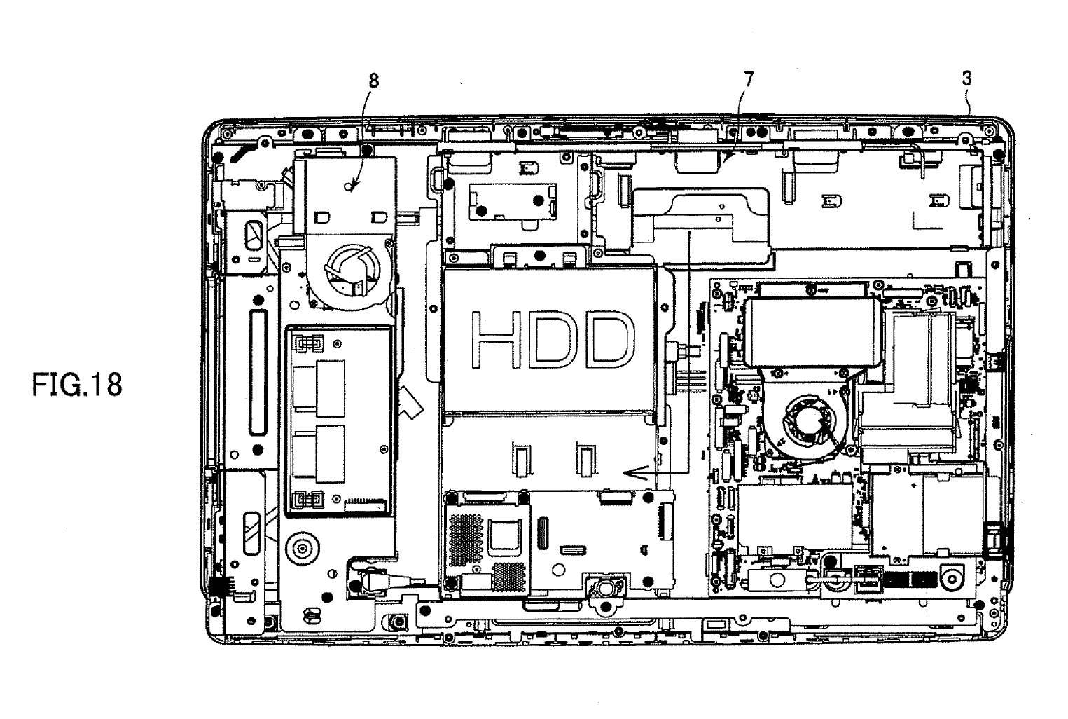

FIG. 18 is a top view of the electronic device 1 to which the two holders 7 and 8 are fixed. In this embodiment, the two holders 7 and 8 having the configurations described above are arranged side by side and fixed to the supporting member 9 and the supporting arm 31 (see FIG. 8). By fixing the holders 7 and 8 in this way, the rigidity (stiffness) of the entire device is strengthened (increased).

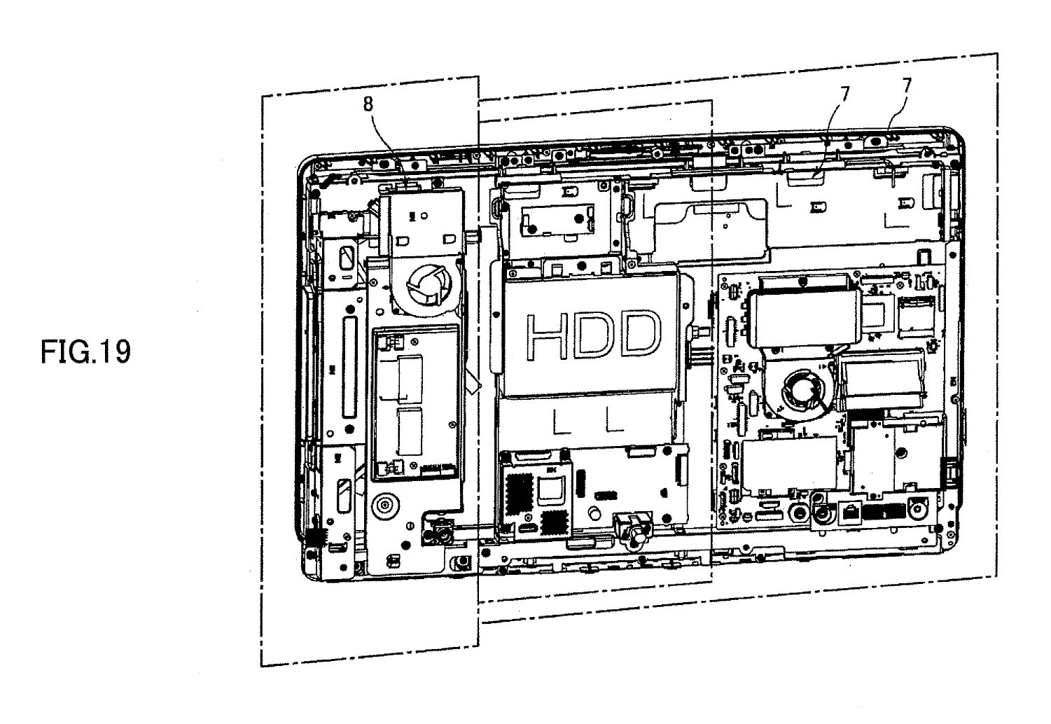

FIG. 19 illustrates a modified example of the electronic device corresponding to FIG. 18.

In this embodiment, a case is described where there are two holders. However, in the modified example of FIG. 19, the holder 7 is further divided into two holders and the beam parts are further formed in the generated ends of the divided holders. By doing this, it may become possible to further improve the strength (i.e., the rigidity of the entire device).

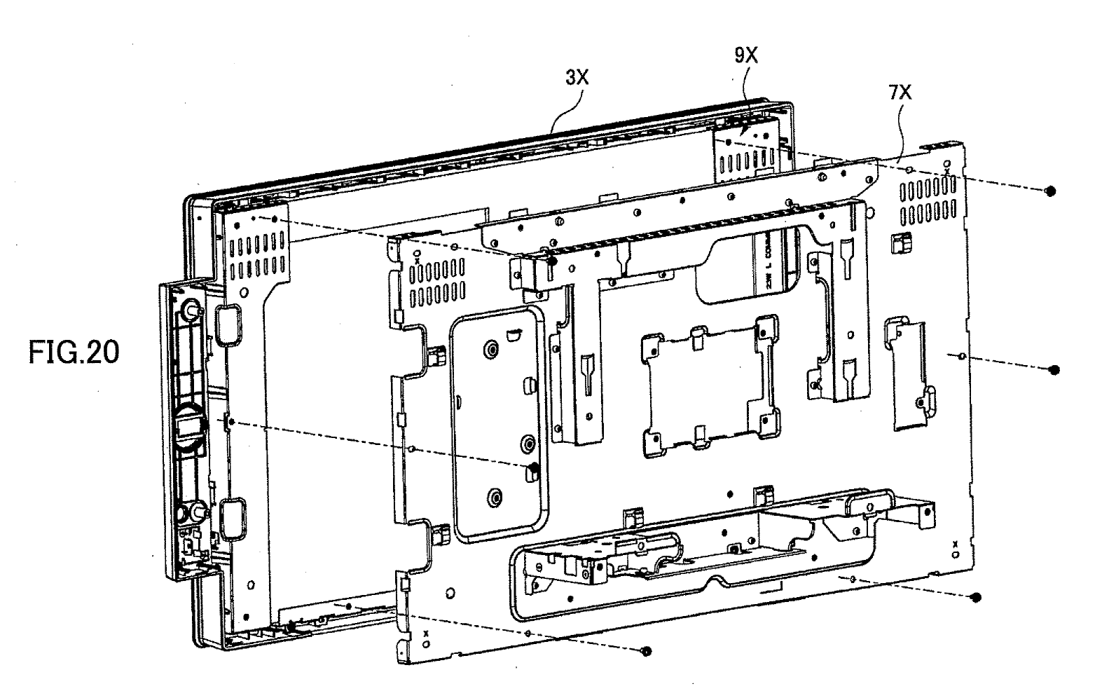

FIG. 20 is an exploded perspective view of an electronic device where the holders are removed as a comparative example of this embodiment.

Here, in order to indicate (clarify) the corresponding relationship between this comparative example and this embodiment, the same reference numerals are used to describe the same or equivalent elements even when the shape or the like may be different from each other. Further, to clarify that the reference numerals are used to describe the elements of the comparative example, a symbol “X” is suffixed to the reference numerals used in this embodiment.

As illustrated in FIG. 20, the supporting member 9X is fixed to the rear surface of the front cover 3X, and the holder 7X is fixed to the supporting member 9X with screws. On the holder 7X illustrated here, similar to the holders 2 and 8 in this embodiment, various electronic components are mounted.

However, the electronic components are not shown here. In the embodiment described above, the two holders 7 and 8 are arranged side by side. However, in the comparative example, as the holder, there is only one holder 7X which has a large area covering the entire rear surface of the front cover 3X.

The holder 7X having such a larger area is more likely to be curved or distorted in the sheet-metal processing. Also, unlike this embodiment, it may be difficult to accurately form such beam parts 731 through 735 and the step part 75 in the holder 7X of the comparative example.

Therefore, when it is intended to have the same strength of the holder 7X of the comparative example as the strength of the holder in this embodiment, it may be desired to use thicker plate material, which may increase cost and weight and may make it difficult to assemble the device (product).

In the embodiment as described above, plural holders 7 and 8 having the beam parts are formed. Further, due to the beam parts and the like, the structural strength (rigidness) may be improved (increased).

Further, the holders 7 and 8 are arranged side by side and fixed in the device. Therefore, even when the holders 7 and 8 are made of relatively thin plate material, it may become possible to provide sufficient strength in the structure. Further, by fixing the holders 7 and 8 to the device, the stiffness of the entire device may be enhanced (improved).

Next, a second embodiment is described.

In the figures illustrating the second embodiment, the same reference numerals are used to describe the elements corresponding to the elements in the first embodiment. Further, to clarify that the reference numerals are used to describe the elements in the second embodiment, a symbol “_2” is suffixed to the reference numerals used in the first embodiment. Further, the repeated description of the elements may be omitted.

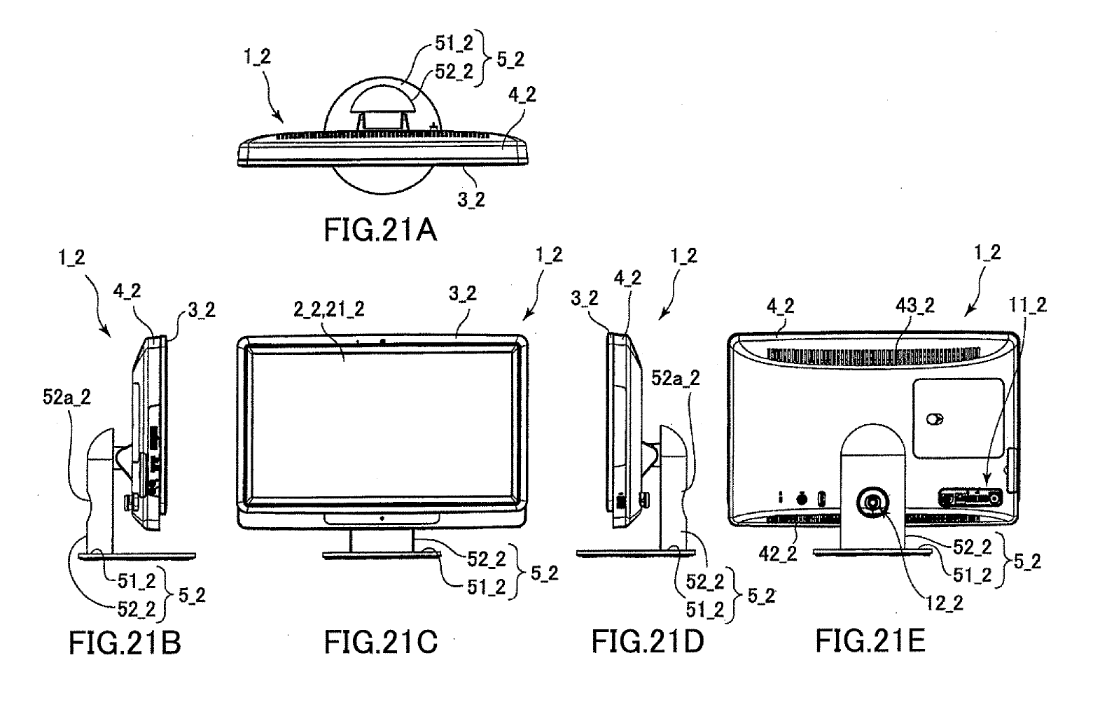

FIGS. 21A through 21E are views of an electronic device according to the second embodiment when viewed from corresponding directions. Specifically, FIG. 20A is a top view; FIG. 20B is a left side view; FIG. 20C is a front view; FIG. 20D is a right side view; and FIG. 20E is a rear view.

An electronic device 1_2 in this second embodiment may be smaller than the electronic device 1 in the first embodiment (see, for example, FIGS. 1 through 3).

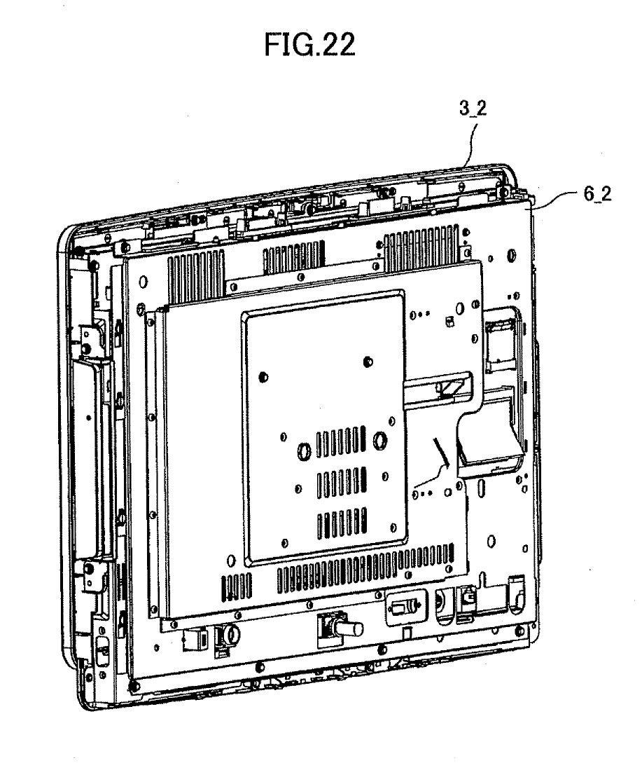

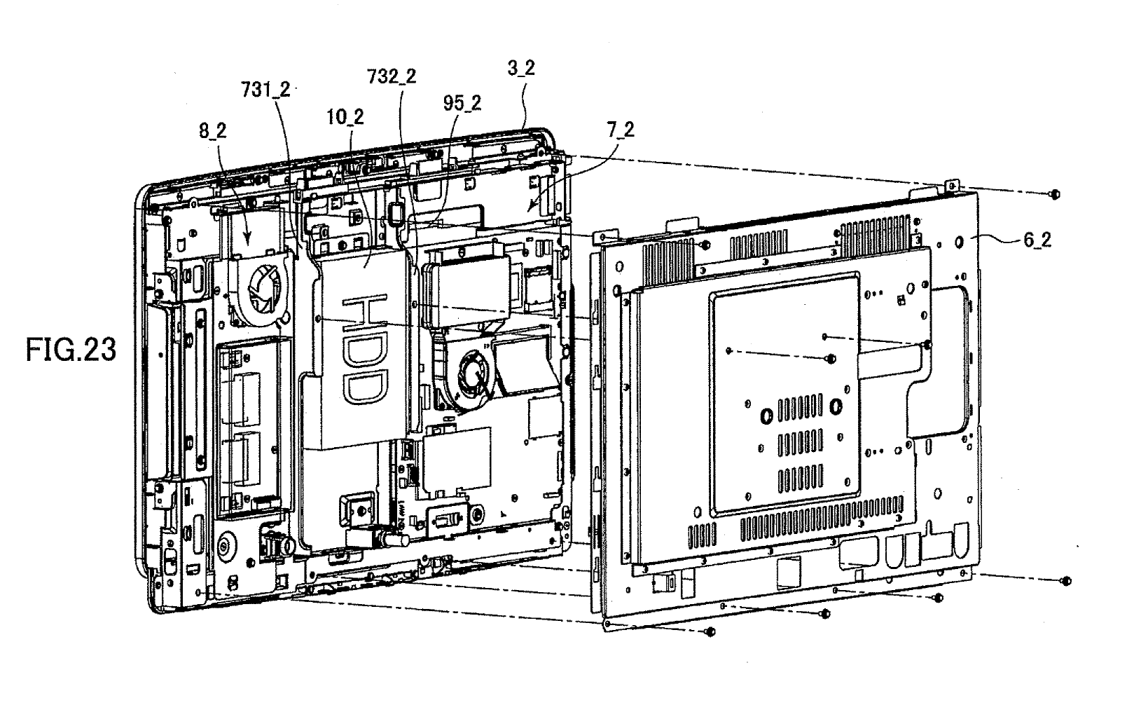

FIG. 22 is a perspective view of the electronic device 1_2 according to the second embodiment when a supporting stand 5_2 and a rear cover 4_2 are removed when obliquely viewed from a side on the rear side. Further, FIG. 23 is an exploded perspective view of the electronic device 1_2 when a rear shield plate 6_2 is further removed in the state of FIG. 22.

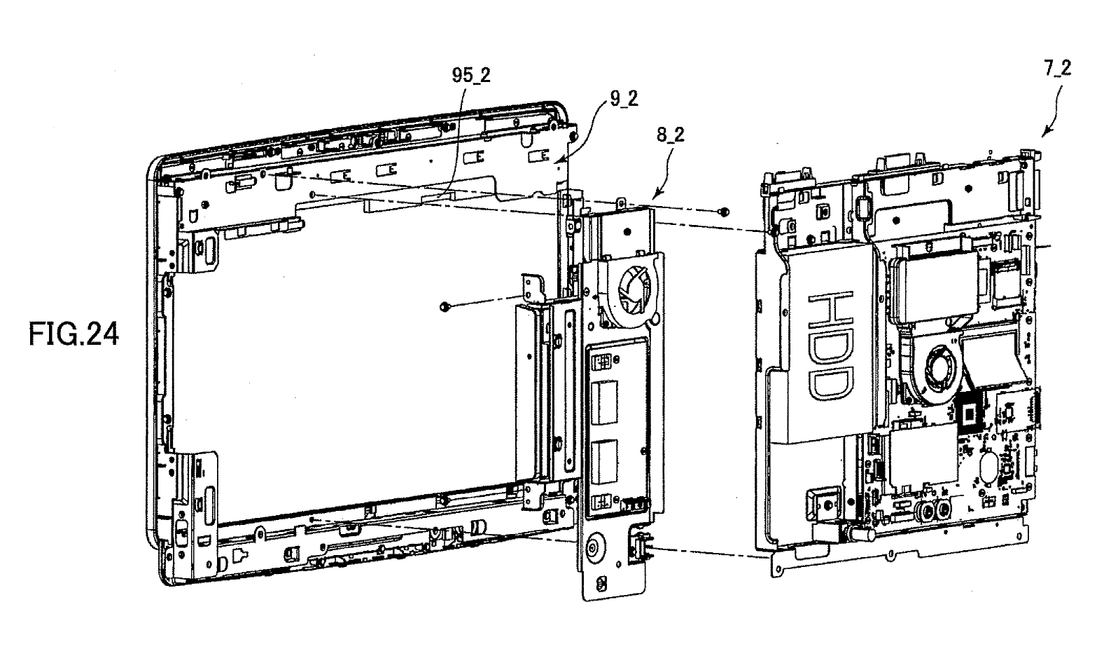

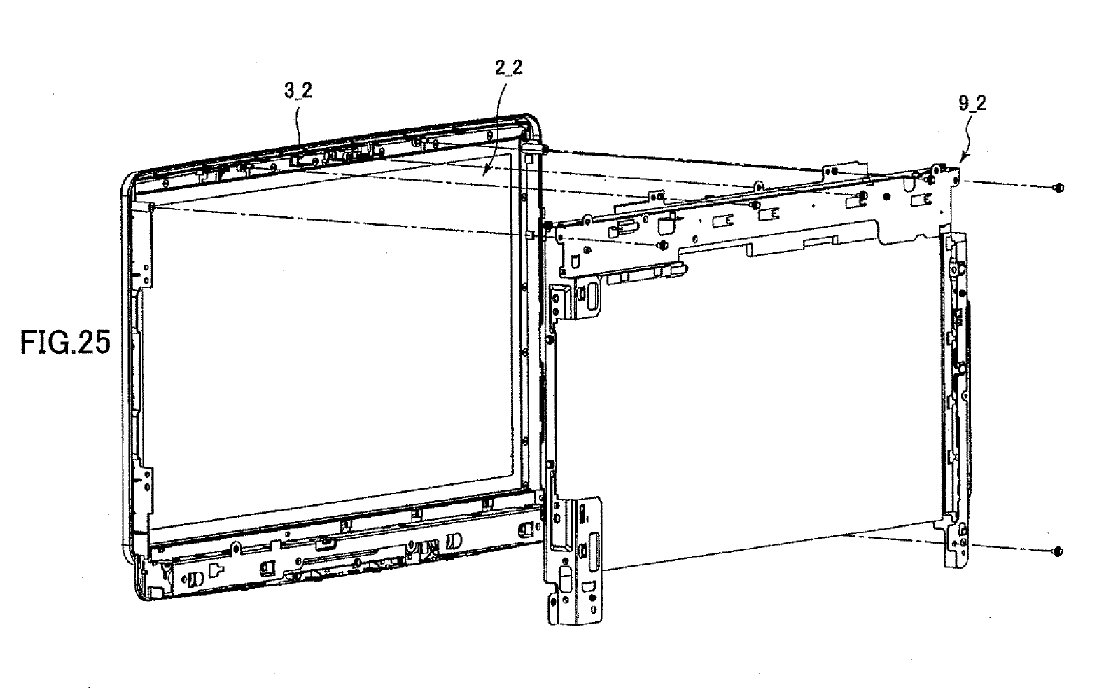

Further, FIG. 24 is an exploded perspective view of the electronic device 1_2 when two holders are further removed in the state of FIG. 23. Further, FIG. 25 is an exploded perspective view of the electronic device 1_2 when a supporting member 9_2 is removed in the state of FIG. 24. FIGS. 22 through 25 correspond to FIGS. 4, 6, 8, and 10 in the first embodiment.

The main differences between the first embodiment and the second embodiment are that an HDD 10_2 is disposed in a manner that the longitudinal direction of the HDD 10_2 is in the vertical direction of the electronic device 1_2 (i.e., in a vertically long manner) and that the second beam (rim) part 732_2 linearly extends in the vertical direction. In the case of the second embodiment, a connector 95_2 is disposed on the right side. Therefore, if the second beam part 732_2 is linearly extended, the second beam part 732_2 does not interfere with the connector 95_2.

Further, the linearly extended second beam part 732_2 may contribute to the improvement of the structural strength. Therefore, the second beam part 732_2 is linearly extended. Further, as described above, the electronic device 1_2 in the second embodiment is smaller than the electronic device 1 in the first embodiment. Therefore, due to the limited space in the electronic device 1_2 in the second embodiment, the HDD 10_2 is disposed in a vertically long manner.

As illustrated in FIG. 24, similar to the first embodiment, holders 7_2 and 8_2 include the respective beam (rim) parts. Also, the holders 7_2 and 8_2 are arranged side by side and fixed in the electronic device 1_2. As described above, by employing the structure where plural holders 7_2 and 8_2 are arranged side by side, it may become possible to obtain sufficient (structural) strength even when the holders 7_2 and 8_2 are made (formed) of a thinner plate material.

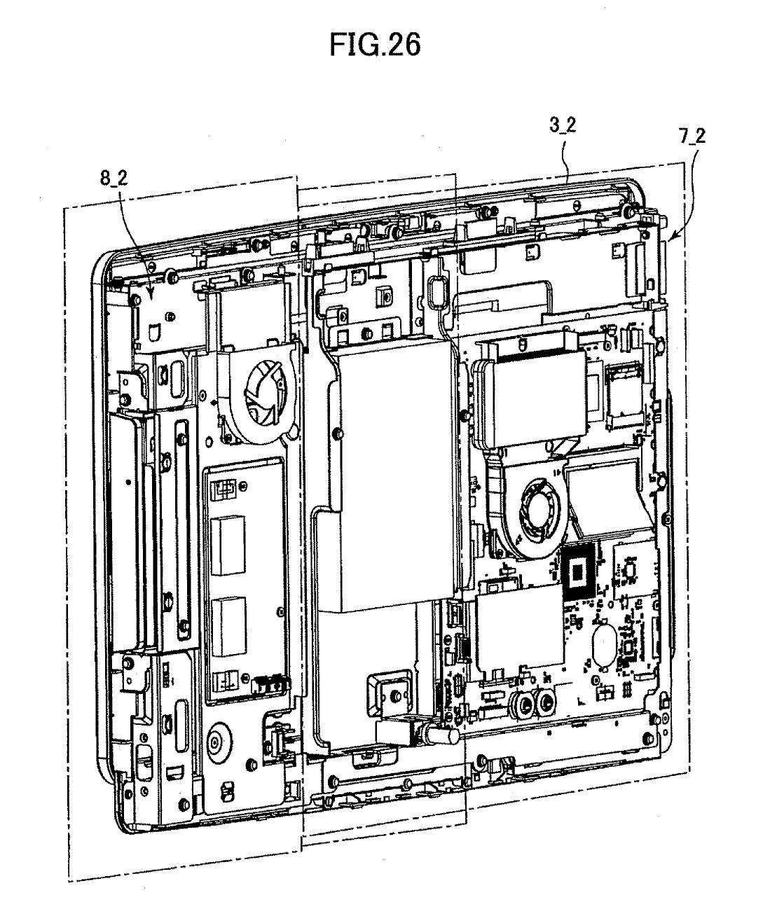

FIG. 26 illustrates a modified example of the second embodiment and corresponds to FIG. 19 of the first embodiment.

Namely, similar to the first embodiment, there are two holders in the second embodiment. In the modified example, however, as illustrated in a dashed-dotted line of FIG. 26, the holder 7_2 is further divided (separated) into two holders and, for example, the beam (rim) parts are further formed along the end generated by the division. By doing this, the (structural) strength may further be improved (increased).

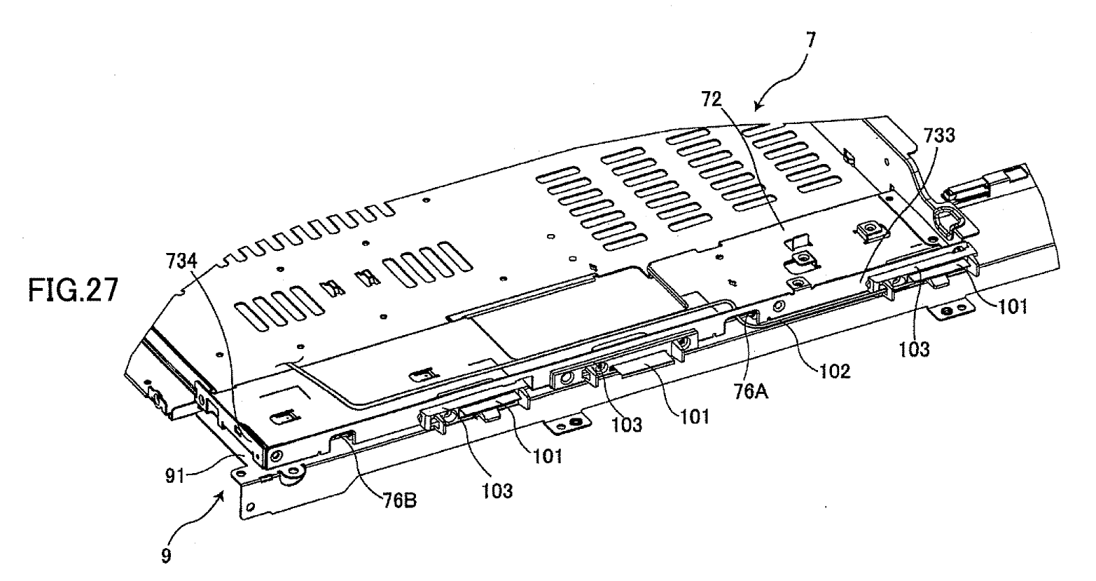

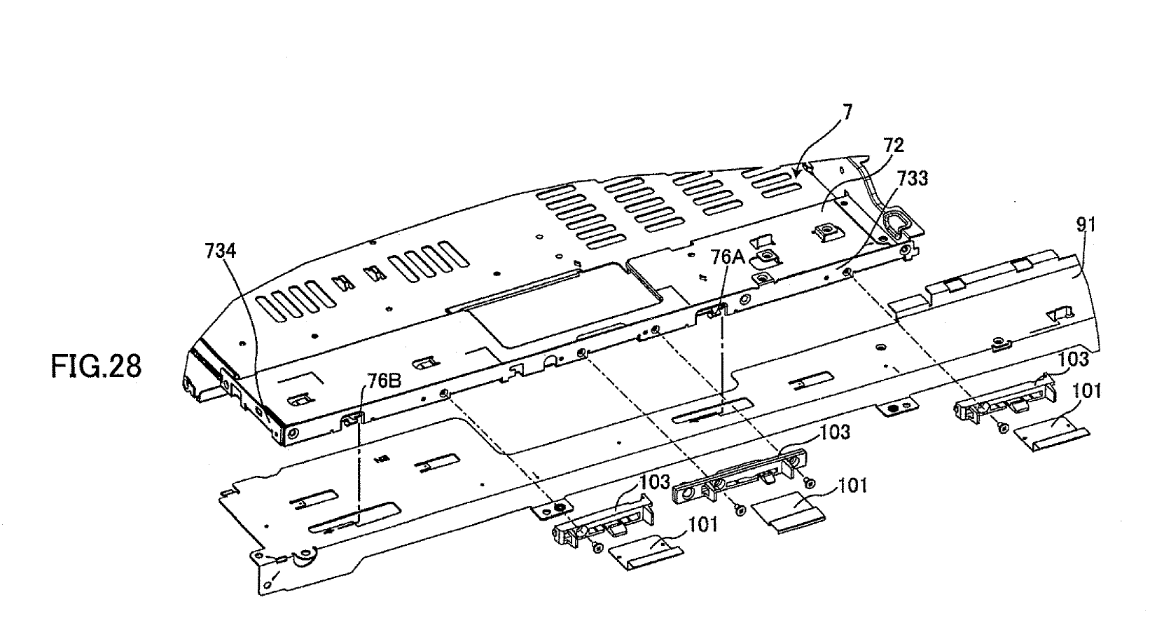

FIG. 27 is a perspective view of an upper end part of the holder 7 disposed on the supporting part 91 of the supporting member 9 of FIG. 8. Further, FIG. 28 is an exploded perspective view of the part illustrated in FIG. 27.

Here, there are three antennas 101 fixed to the beam part 733 via (with) respective antenna holders 103. A cable 102 is connected to each of the antennas 101, and extends through the opening part 76A or 76B and on the upper surface of the base part 72 of the holder 7 (i.e., a surface facing the rear cover 4 side in FIG. 1).

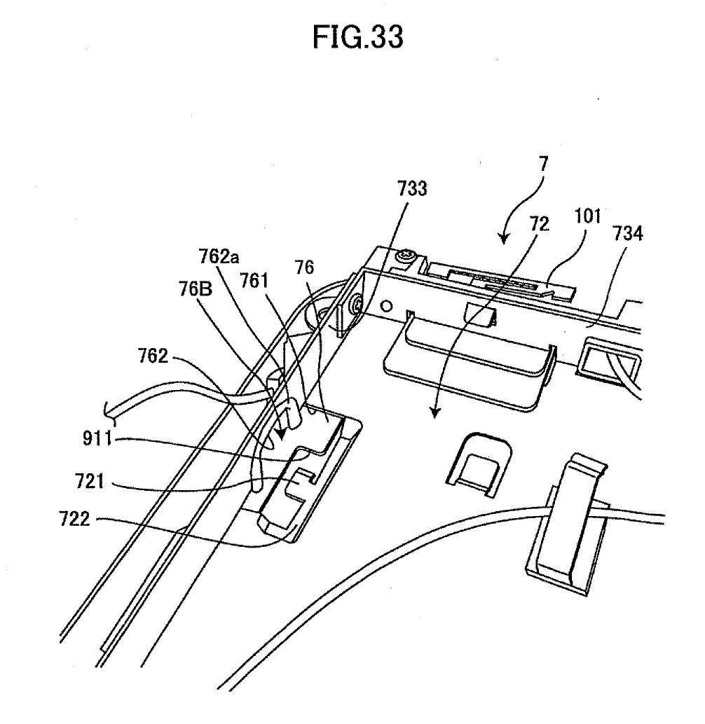

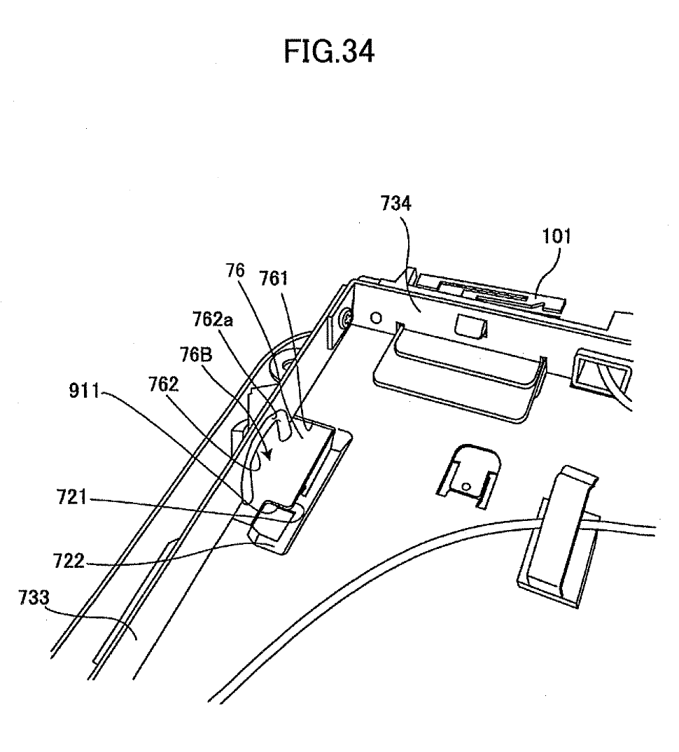

Here, a case is illustrated where there are three antennas 101. However, for example, another antenna 101 may also be fixed to the other beam part 734 (see FIG. 12) connected to the beam part 733 at a corner (see FIGS. 33 and 34). However, it is not always desired to fix all the antennas described above. Namely, the above case is illustrated to indicate that the antenna(s) 101 may be fixed (installed) in various portions. Therefore, in the following, a case may be exemplarily described where one antenna connected to the cable 102 is provided.

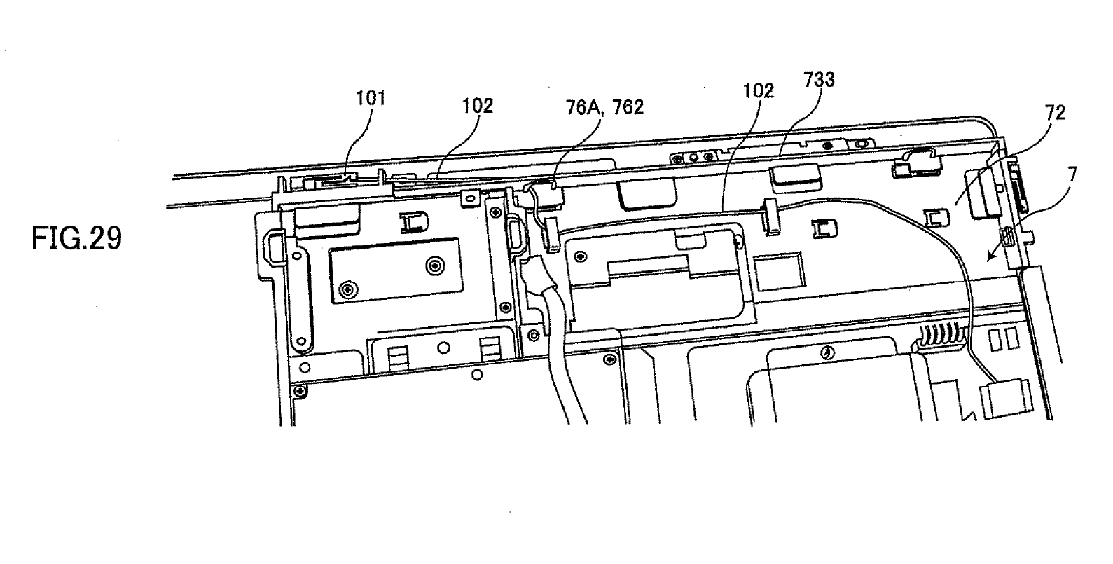

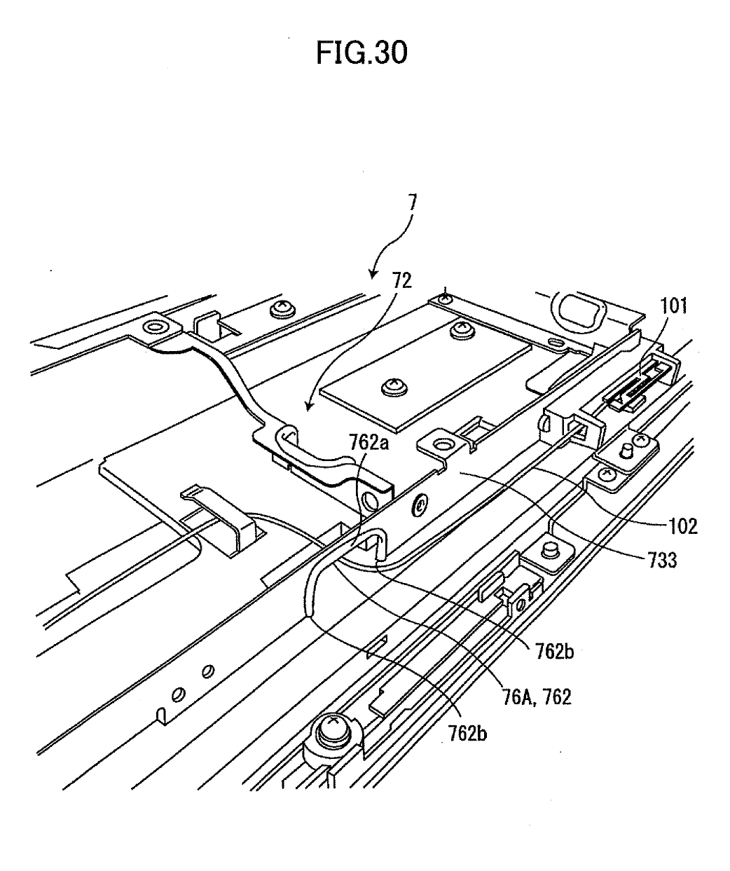

FIG. 29 is a perspective view of a part of the upper right corner of the holder 7 on the supporting member 9 (upper left corner in the state of FIG. 1). Further, FIG. 30 is a perspective view of the part of the holder 7 when viewed from an outer side (upper side of FIG. 1) of the holder 7.

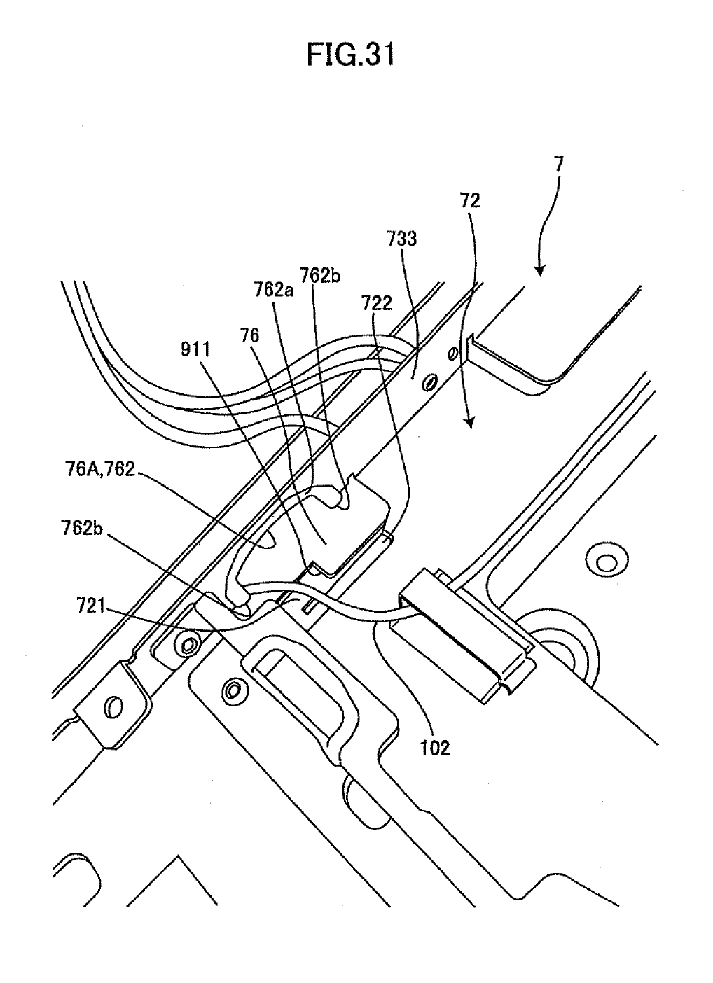

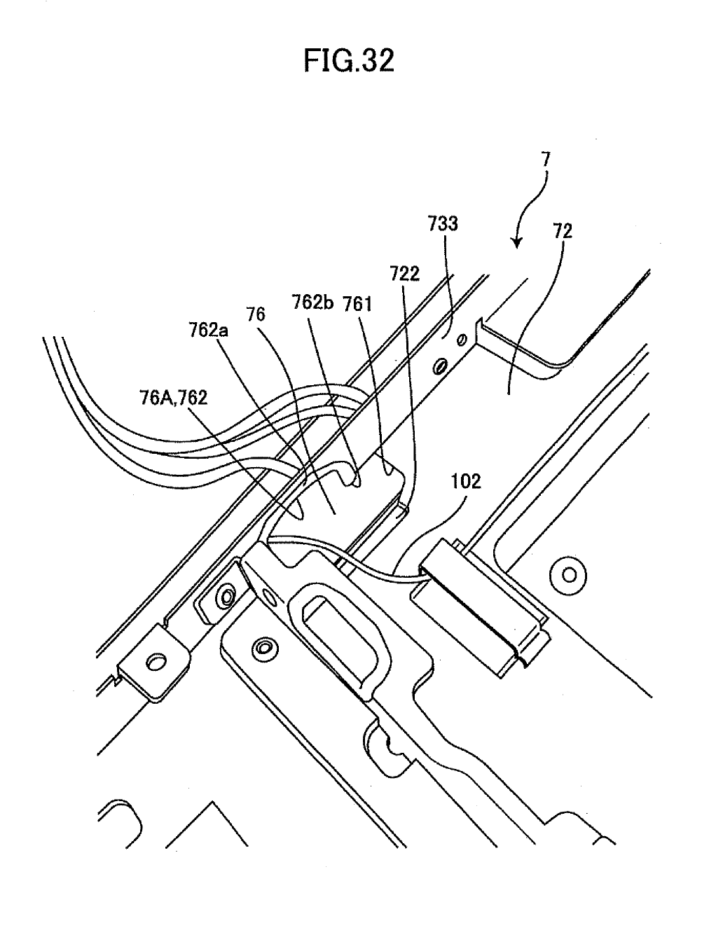

FIG. 31 is an enlarged perspective view of a partial region of the part of FIG. 29 when the holder 7 is disposed at a “mounting position” described below. FIG. 32 is an enlarged perspective view of the partial region of FIG. 31 when the holder 7 is disposed at a “supporting position” also described below.

As described above, the antenna 101 is provided on the outer surface of the beam part 733 extending horizontally (in the right and left direction) on the upper end of the holder 7. The cable 102 is connected to the antenna 101. The cable 102 runs through the opening part 76A and on the upper surface of the base part 72 of the holder 7 (i.e., a surface facing the rear cover 4 side in FIG. 1), and is connected to an electronic component (not shown) for radio communications using the antenna 101.

Here, in this embodiment, the holder 7, the base part 72, and the beam part 733 correspond (refer) to a sheet-metal member, a tabular base part, and a standing wall part, respectively. Further, the upper surface of the holder 7 illustrated in FIG. 27 (i.e., a surface facing the rear cover 4 in FIG. 1) corresponds (refers) to a first surface. The beam part 733 (standing wall part) is folded from the tabular base part 72 to the first surface side and extends along the edge (end) (here, the upper edge (end)) of the tabular base part 72.

Here, the opening part 76A is formed in the boarder region between the base part 72 and the beam part 733 (standing wall part), the border region including a part of the base part 72 and a part of the beam part 733 (standing wall part). Namely, the opening part 76A includes a first opening region 761 and a second opening region 762 (see FIG. 32).

The first opening region 761 passes (penetrates) through the upper surface (first surface) of the base part 72 illustrated in FIGS. 27 through 30 and a second surface which is defined as the surface opposite to the upper surface (first surface). The second opening region 762 passes (penetrates) through the front and rear surfaces of the beam part 733 (standing wall part) and is in communication with the first opening region 761. Namely, the first opening region 761 and the second opening region 762 are formed as a single opening which is the opening part 76A.

Just under the first opening region 761 expanded on the base part 7 side of the opening part 76A, there appears the upper surface of the supporting part 91 of the supporting member 9 (the surface on the rear cover 4 side of FIG. 1) (see also, for example FIG. 8), the supporting part 91 supporting the second surface (the rear surface opposite to the upper surface in FIGS. 27 through 32) of the holder 7.

Namely, in the opening part 76A, the second opening region 762 formed on the beam part 733 (standing wall part) has an opening defined by an opening end 762a (defining a part of the second opening region 762) and an upper surface of the supporting part 91. Further, the opening end 762a has two opening end edge parts 762b. The opening end edge parts 762b have a shape of entering into the first opening region 761 toward the supporting part 91.

Further, an edge removal process by the plastic deformation is performed on all the opening end 762a from one of the opening end edge parts 762b to the other of the opening end edge parts 762b. Due to the edge removal process, it may become possible to prevent the damage to the cable 102 by the opening end 762a even when the cable 102 is in contact with the opening end 762a.

The supporting part 91 of the supporting member 9 (see FIG. 8) is one example of a supporting member in an embodiment. Namely, the supporting part 91 includes the upper surface (first surface) and the second surface which is the rear surface opposite to the upper surface, and supports the holder 7 in a manner that the second surface of the holder 7 is placed on the upper surface (first surface) of the supporting part 91.

When the holder 7 is assembled to the supporting part 91, for example, as illustrated in FIG. 8, the holder 7 is placed on the supporting part 91 in a manner that the latching pieces 71 are entered into the corresponding latching holes 93. Then the holder 7 is slid in the right direction of FIG. 8, so that the latching pieces 71 protrude to the rear surface side of the supporting part 91 (image display panel 2 side) and the holder 7 is latched with the supporting part 91. Then the holder 7 is fixed with screws.

Here, the “mounting position” refers to a position in a state where the holder 7 is placed (disposed) on the supporting member 9 in a manner that the latching pieces 71 of the holder 7 are inserted (engaged) into the corresponding latching holes 93 of the supporting member 9.

Further, the “supporting position” refers to a position in a state where, after the holder 7 is placed (disposed) on the supporting member 9 in the “mounting position”, the holder 7 is slid and latched with the supporting member 9 so that the latching pieces 71 are entered into the rear surface of the supporting part 91 of the supporting member 9.

Here, the supporting part 91 of the supporting member 9 includes a notch part 911 communicating between the first surface (the surface on the side where the holder 7 is placed) and the second surface (the rear surface of the first surface) of the supporting part 91 and disposed at an overlapping position with the first opening region 761 when the holder 7 is in the “mounting position”.

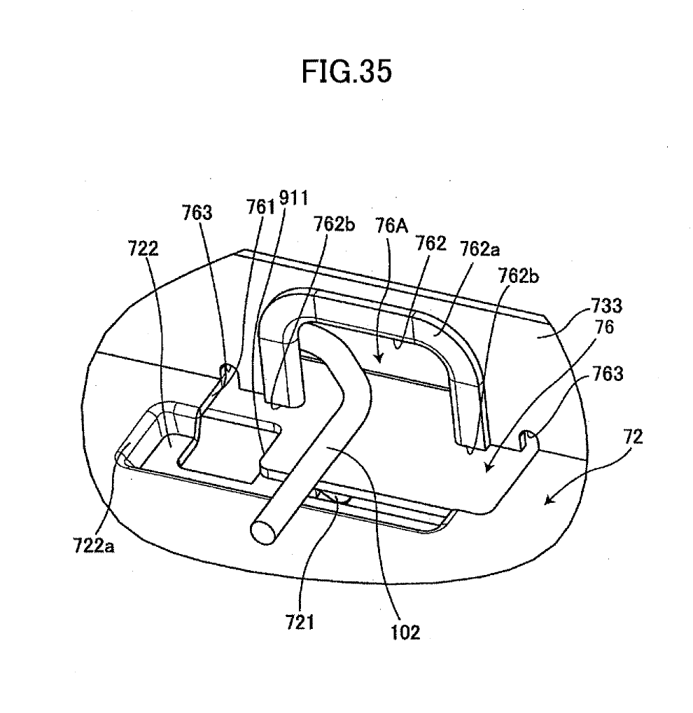

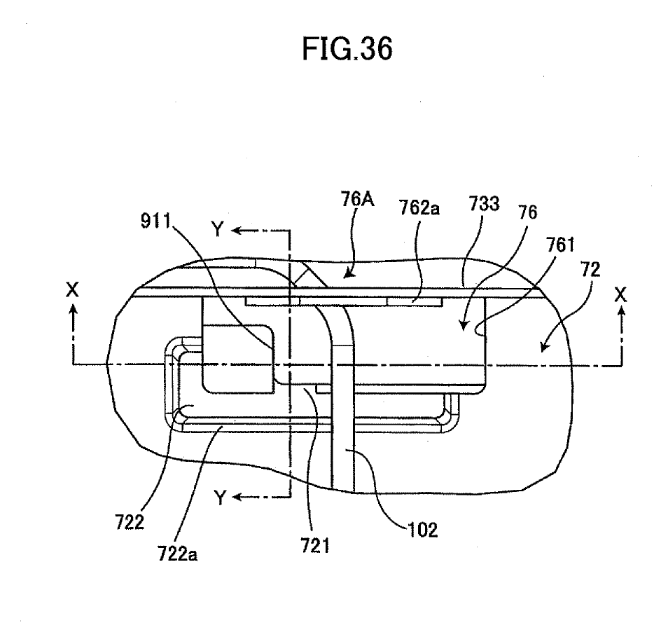

On the other hand, the holder 7 includes a lingua part 721 having a shape protruding to the notch part 911 of the first opening region 761 when the holder 7 is in the mounting position. The base part 72 of the holder 7 includes a dent part 722 formed at a position where the cable 102 runs to the first opening region 761. The dent part 722 is a region where, along with the convex on the second surface side of the holder 7, the first surface side of the holder 7 is further concaved toward the first opening region 761. An edge part 722a (FIGS. 35 and 36) formed by being concave to the dent part 722 has a rounded shape. Due to the shape, it may become possible to prevent the damage to the cable 102 by the edge part 722a. Here, the lingua part 721 protrudes from the dent part 722 to the first opening region 761.

In the state of the mounting position of FIG. 31, the lingua part 721 is disposed at a position corresponding to the notch part 911 of the supporting part 91. When the holder 7 is slid and it is in the state of the supporting position of FIG. 32, the lingua part 721 is entered on the rear surface (the second surface) of the supporting part 91 so as to apply a force to the supporting part 91 to press the second surface of the holder 7.

By doing this, it may become possible to reduce the gap between the opening end edge parts 762b entering into the first opening region 761 and the supporting part 91 and of the opening end 762a defining the second opening region 762 so as to form a sufficiently narrow gap. Therefore, it may become possible to prevent the cable 102 from being entered into the gap and damaged.

FIGS. 33 and 34 are partial perspective views illustrating a structure of the other opening part 76B formed on the beam part 733 of the holder 7 (see FIGS. 12 and 27). FIG. 33 illustrates a state where the holder 7 is in the mounting position, and FIG. 34 illustrates a state where the holder 7 is slid to the supporting position.

The structure of the surrounding of the opening part 76B is the same as the structure of the surrounding of the opening part 76A described above. Therefore, the same reference numerals are used to describe the same elements of the opening part 76A and herein the repeated description thereof are omitted.

The opening part 76A through which the cable 102 passes are described in more detail.

FIG. 35 is an enlarged perspective view of the opening part 76A when viewed from an inner surface side of the beam part 733 of the holder 7. FIG. 36 is a top view of the opening part 76A when viewed from the rear cover 4 side (see FIG. 1).

Further, FIGS. 35 and 36 illustrate the state where the holder 7 has been (fully) slid to the supporting position.

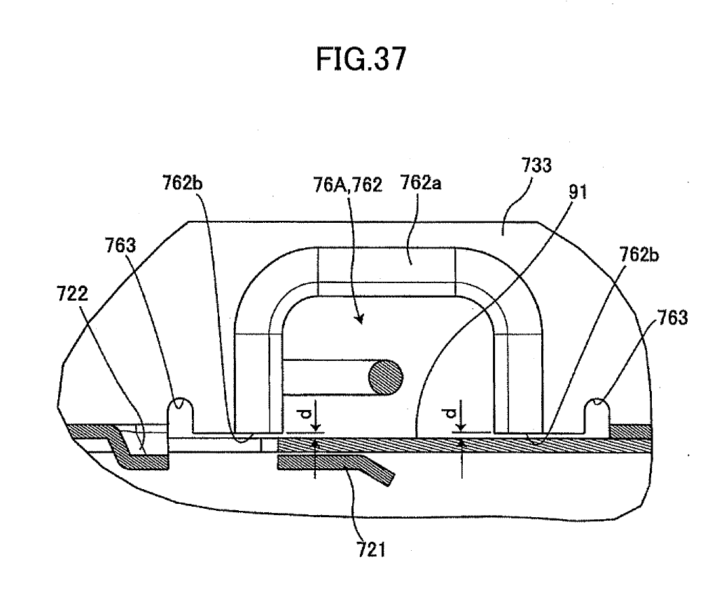

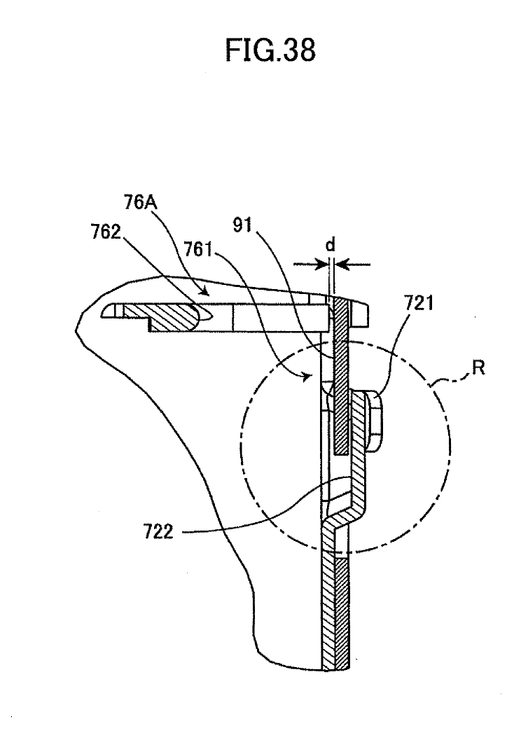

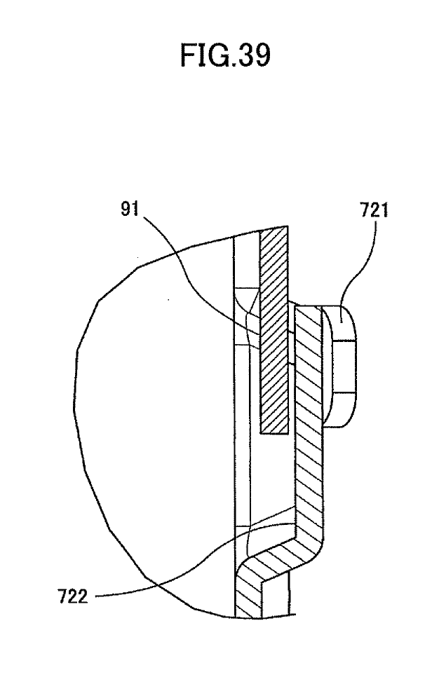

Further, FIG. 37 is a cross-sectional view when cut along the X-X line of FIG. 36. FIG. 38 is a cross-sectional view when cut along the Y-Y line of FIG. 36. Further, FIG. 39 is an enlarged view of the part of a circle R of FIG. 38.

In the second opening region 762 formed on the second opening region 762, an opening defined by the opening end 762a and the upper surface (first surface) of the supporting part 91 of the supporting member 9 is formed. However, on the holder 7, the second opening region 762 and the first opening region 761 formed on the base part 72 collectively form a single opening part 76. Namely, the beam part 733 is formed by be folded at the position where the opening part 76 is divided into two, so that the opening part 76 is divided into the first opening region 761 and the second opening region 762.

In regions of the second opening region 762 connected to the beam part 733, there is formed a pair of escape parts 763. Due to the pair of the escape parts 763, the opening end edge parts 762b of the opening end 762a are formed so as to protrude in the opening part 76A.

Therefore, when the beam part 733 is formed by folding, the opening end edge parts 762b are entered into the first opening region 761. When the holder 7 is slid into the supporting position, the lingua part 721 is entered on the rear surface (second surface) side of the supporting part 91, so that a force is applied to the supporting part 91 to push up the supporting part 91. Therefore, the gap between the opening end edge parts 762b of the opening end 762a and the supporting part 91 may be maintained to be a sufficiently narrow gap.

As a result, it may become possible to prevent the cable 102 from being damaged by the edge of the opening end edge parts 762b of the opening end 762a. Further, as described above, the edge removal process is performed on the opening end 762a defining the second opening region 762.

Further, a rounding process is performed on the edge part 722a connected to the dent part 722 of the base part 72 of the holder 7 so that the edge part 722a is rounded. As described above, this part is also designed to prevent the cable 102 from being damaged.

Here, the description of the embodiment is temporarily interrupted, and a comparative example is described.

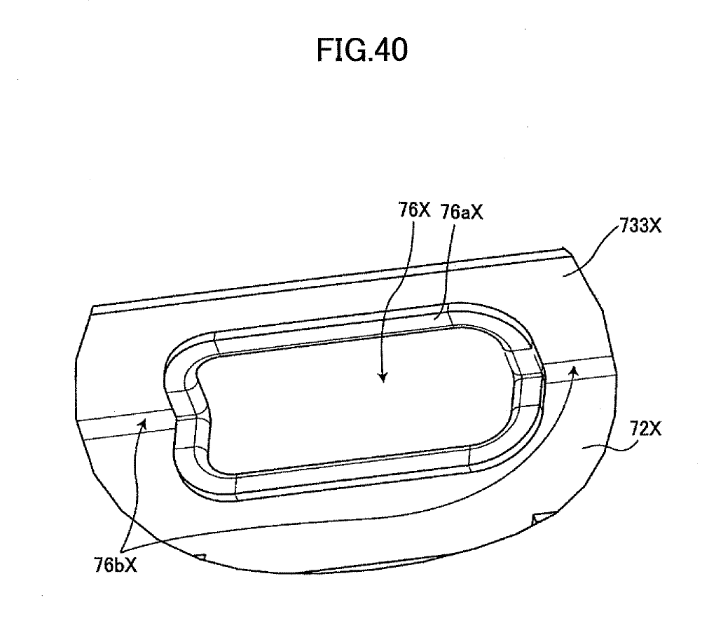

FIG. 40 illustrates one comparative example.

Here, an opening part 76X is formed by performing a punching process along with the edge removal process by the plastic deformation on a sheet plate member. Then, a base part 72X and a beam part 733X are formed by folding the sheet plate member at a position where the opening part 76X is divided into two parts.

In this case, however, a folding part 76bX between the base part 72X and the beam part 733X is more likely to have a much larger curvature value (radius R). As a result, for example, even when an electronic component having a cubic body is to be placed (mounted) on a position near the beam part 733X, such placement may not be possible due to the curvature, and the electronic component may have to be placed at a position separated from the beam part 733X.

In this case, wasteful space may be generated and the electronic parts may not be directly supported by the beam part 733X and additional supporting member(s) may have to be used. As a result, the number of parts may be increased and the structure may be complicated.

Further, in this case, it may be difficult to fold in an accurate angle between the beam part 733X and the base part 72X, as the fold angle may widely vary. This also may make it difficult to accurately place (mount) electronic components. For example, when the antenna 101 as illustrated in FIGS. 27 and 28 is mounted on the beam part 733X, the attachment (installation) angle of the antenna 101 may vary, thereby making it difficult to maintain the performance of the antennas 101 at a constant level.

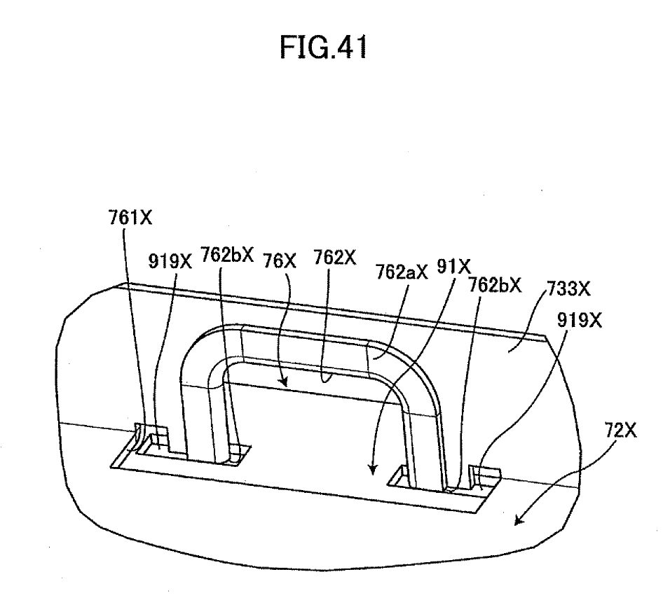

FIG. 41 illustrates another comparative example.

In FIG. 41, an opening part 76X is formed. The opening part 76X includes a first opening region 761X on the base part 72X side and a second opening region 762X on the beam part 733X side. An opening end 762a defining the second opening region 762X is formed by performing the edge removal process by the plastic deformation.

Here, a supporting member 91X on which the base part 72X is placed has openings 919X formed at positions corresponding to opening end edge parts 762bX of an opening end 762aX, so that the opening end edge parts 762bX are entered into the corresponding openings 919X.

In this case, the beam part 733X may be formed so as to sharply rise with an extremely small radius (curvature) from the base part 72X, and the rising (standing) angle between the beam part 733X and the base part 72X may be accurately determined. Therefore, there may be no problem in placing (mounting) an electronic component.

However, in the comparative example of FIG. 41, edges are formed on the end of the first opening region 761X formed on the base part 72X and the end of the openings 919X formed on the supporting member 91X. Due to the edges, a cable passing through the edged portions may be damaged.

The above described embodiment may resolve not only the problem of the placement of components due to the folding manner of the beam part but also the problem that the passing cable may be damaged.

### HDD Unit Fixing Structure

Next, a fixing structure of fixing the HDD unit to the holder 7 is described. Here, the Hard Disk Drive (HDD) includes a Hard Disk (HD) that data are magnetically written and stored into and read from and a motor to rotate the HD. In the HD, while the HD is rotated by the motor, data are written into and read from the HD.

Here, a comparative example is described first.

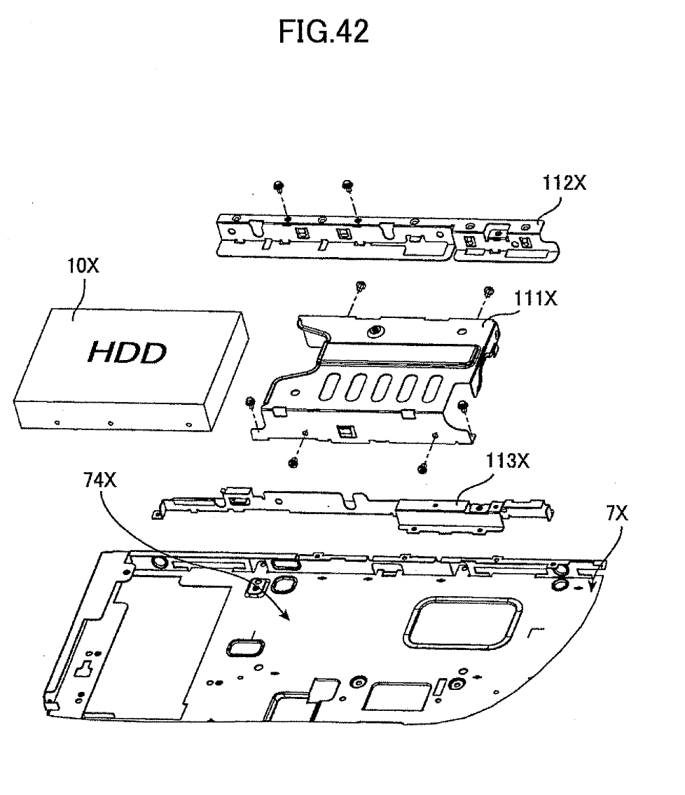

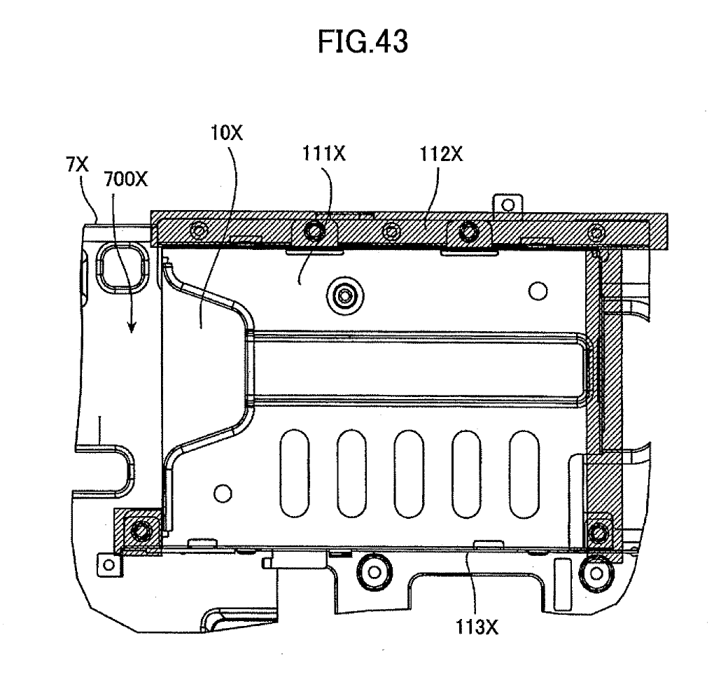

FIG. 42 is an exploded perspective view of an HDD unit fixing structure of the comparative example. Further, FIG. 43 is a top view of a state when the HDD unit of FIG. 42 is mounted (assembled).

Here, an HDD 10X is contained (accommodated, installed) in an HDD container 74X of the holder 7 in a manner that the upper, right, and left surfaces of the HDD 10X are contained (accommodated, covered) by an HDD holder 111X and the HDD 10X is fixed to the right and left sides of HDD holder 111X with screws, and the HDD 10X is supported by a left supporting member 112X and a right supporting member 113X.

In this case, a region occupied (defined) by the HDD unit including the HDD 10X, the holder 111X, and the supporting members 112X and 113 extends so as to include hatched regions surrounding the HDD 10X in FIG. 43.

However, originally, the size of the HDD 10X is relatively large. Therefore, if it is desired to use a larger space around the HDD 10X to fix the large HDD 10X, it may become difficult to reduce the space, and moreover, the size of the device may become larger.

In this embodiment, however, by employing the fixing structure described below, it may become possible to reduce the space to fixing the HDD unit while ensuring heat transfer from the HDD 10.

Here, a fixing structure of the HDD unit in electronic device 1 according to the first embodiment in FIGS. 1 through 3 is described first. Next, a fixing structure of the HDD unit in the electronic device 1_2 according to the second embodiment in FIG. 21 is described.

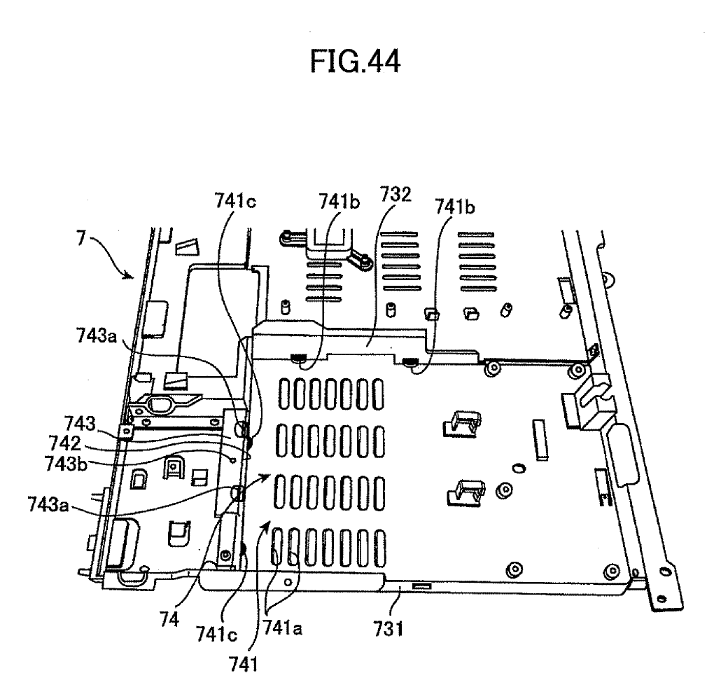

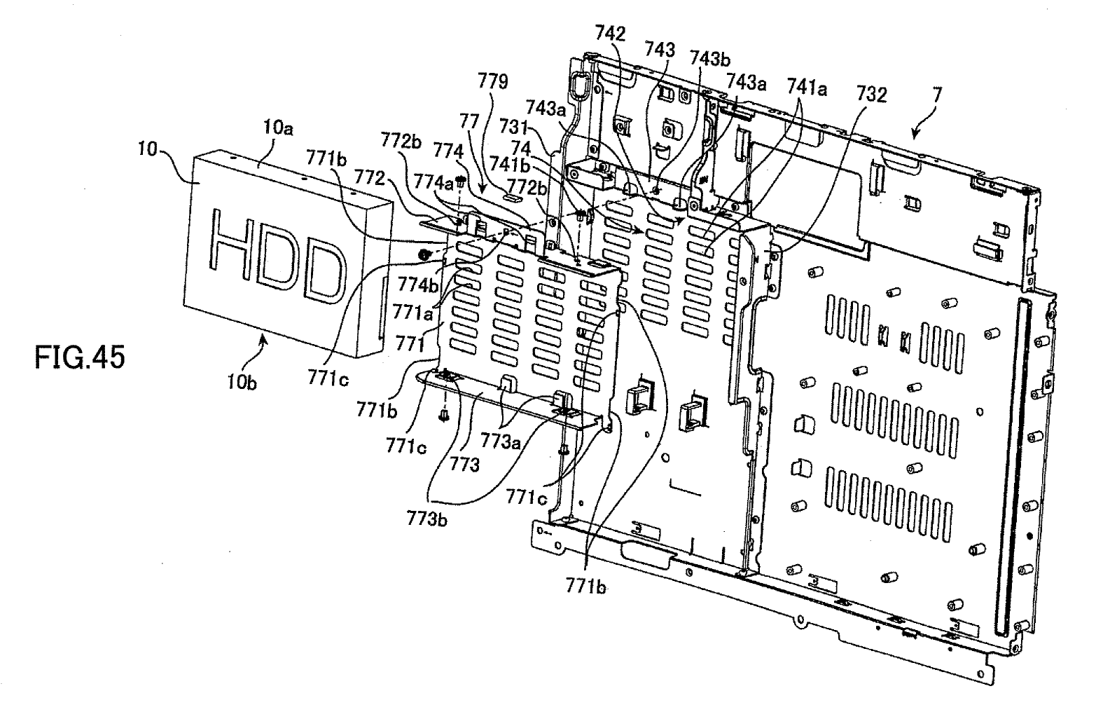

FIG. 44 is a perspective view of a part of the HDD container 74 of the holder 7 (see both FIGS. 12 and 45) of the electronic device 1 in FIGS. 1 though 3 according to the first embodiment.

The HDD container 74 of the holder 7 includes a base part 741, and beam parts 731 and 732. The beam parts 731 and 732 are standing (protruding) on the left and right sides of the base part 741 and extending in the front-back direction. The beam parts 731 and 732 correspond to examples of the left and right rims in an embodiment.

Further, the HDD container 74 corresponds to an example of a container in an embodiment. Further, the HDD 10 (see FIG. 45) to be contained in the HDD container 74 corresponds to an example of an electronic component in an embodiment.

The base part 741 includes plural openings (holes) 741a penetrating between the front surface and the rear surface of the base part 741. The openings (holes) 741a are provided for ventilation to form a smooth air flow to assist air cooing (heat transfer) of the HDD 10.

The left and right beam parts 731 and 732 include plural latch protrusions 741b protruding in the lateral direction above the base part 741 at a height position higher than the base part 741 by a height corresponding to the plate thickness of a base part 741 of a supporting plate 77 (described below, see, for example, FIG. 45) to be fixed to the HDD 10 to support the HDD 10. The operation of the latch protrusions 741b is described below.

Further, the HDD container 74 includes a front wall 742 standing (extending in the height direction) on the front side of the base part 741 and extending in the right and left direction. The front wall 742 also includes two latch protrusions 741c protruding in the lateral direction above the base part 741 at the height position higher than the base part 741 by the height corresponding to the plate thickness of the base part 741 of the supporting plate 77.

Further, the HDD container 74 includes a table part 743 connected (fixed) to the front wall 742 and extended (formed) in parallel to the base part 741 and toward to the front side of the base part 741. The table part 743 includes two cut-and-raised pieces (guide protrusions) 743a. The cut-and-raised pieces 743a correspond to an example of a guide rib in an embodiment. Further, the table part 743 includes a screw hole 743b.

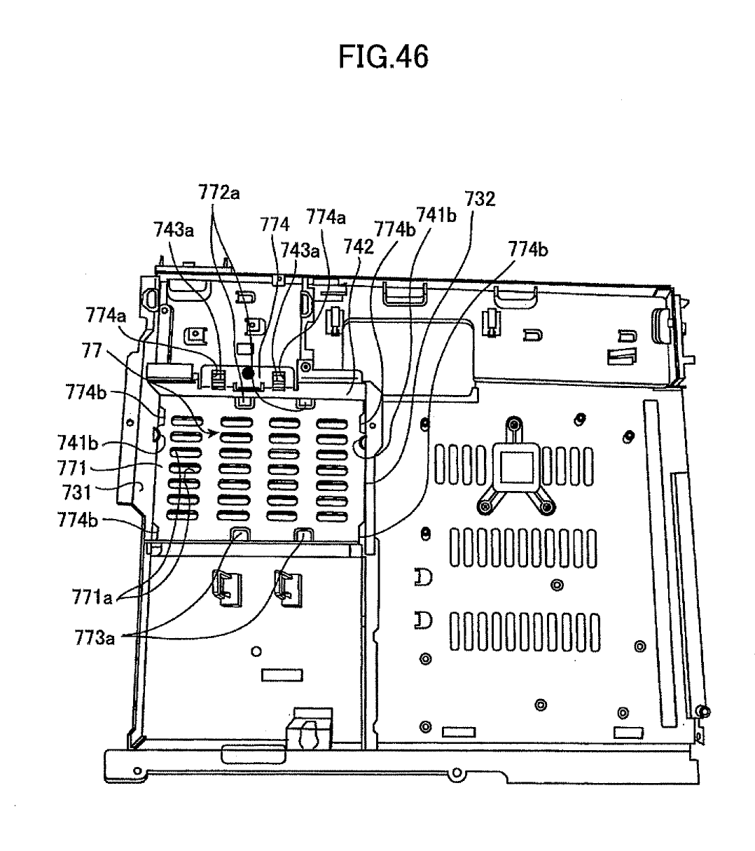

FIG. 45 is an exploded perspective view of the holder 7, the supporting plate 77, and the HDD 10. FIG. 46 is a perspective view of the HDD container 74 of the holder 7 when only the supporting plate 77 without the HDD 10 is accommodated (contained) in the HDD container 74.

The HDD 10 is fixed to the supporting plate 77 with screws. The HDD unit where the HDD 10 is assembled on the supporting plate 77 is contained in the HDD container 74 of the holder 7.

The supporting plate 77 includes a base part 771 extending along the lower (bottom) surface of the HDD 10, a front wall part (standing part) 772, a rear wall part 773, and a flange part 774. The front wall part 772 and the rear wall part 773 are formed by folding the front part and the rear part of the base part 771, so as to stand along a front wall 10a and a rear wall 10b, respectively, of the HDD 10.

Further, when being contained in the HDD container 74, the front wall part 772 is disposed to stand along the front wall 742 of the of the HDD container 74 of the holder 7. Further, the flange part 774 is folded from the front wall part 772 in the front direction so as to be parallel to the base part 771, and is placed on the table part 743 of the HDD container 74 when being contained in the HDD container 74 of the HDD unit 10.

The base part 771 of the supporting plate 77 includes plural openings 771a penetrating between the front and rear surfaces of the base part 771. The openings 771a are in communication with the openings (holes) 741a of the base part 741 of the HDD container 74 when the HDD unit including the supporting plate 77 is contained in the HDD container 74.

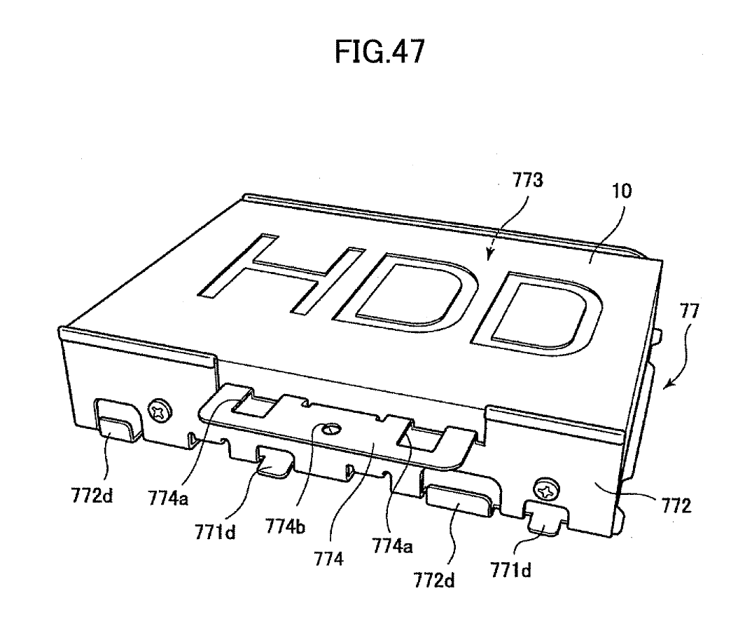

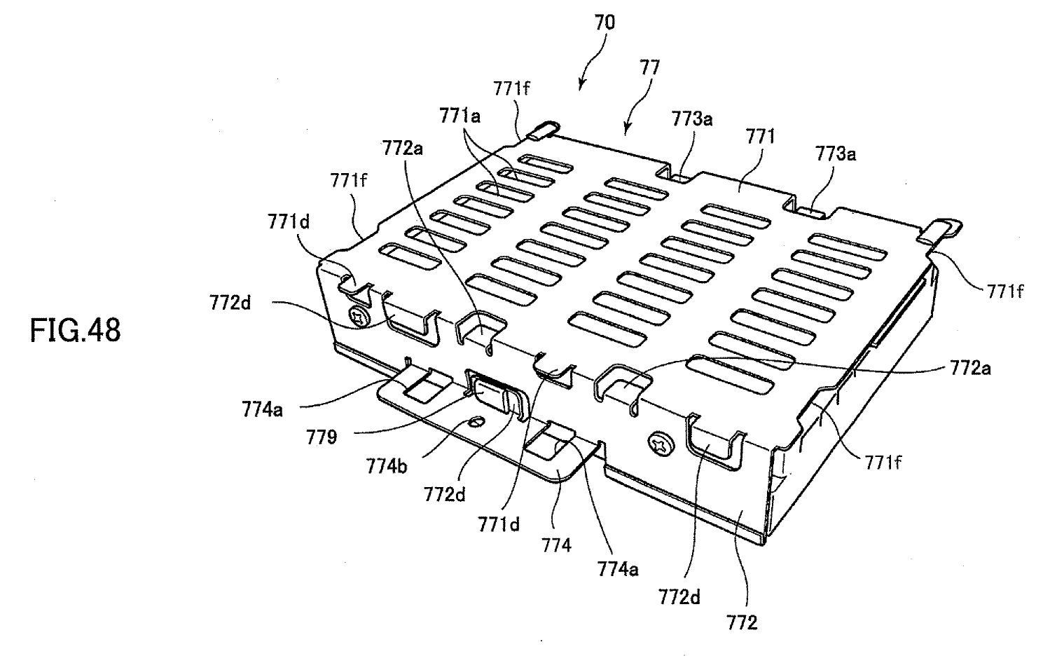

Further, the front wall part 772 and the rear wall part 773 includes cut-and-raised pieces 772a and 773a, respectively, protruding above the base part 771 at a position slightly higher than (floating above) the base part 771 (see FIGS. 47 and 48 for the cut-and-raised piece 772a). When supported by the supporting plate 77, the HDD 10 is supported in a manner that the lower surface (the surface opposite to the upper surface of the HDD 10 in FIG. 45) of the HDD 10 is slightly floated above the base part 771 due to the cut-and-raised piece 773a.

On the lower surface of the HDD 10, there is a lower surface of the motor to rotate the hard disk (HD) and there is a circuit board is formed and extended. Therefore, heat is generated while operating. Therefore, the HDD 10 is kept in a state where the HDD 10 is slightly floated to form a space between the lower surface of the HDD 10 and the supporting plate 77 to promote heat transfer from the lower surface of the HDD.

Further, by using the space, the base part 771 is latched with the latch protrusions 741b (see FIG. 44) of the HDD container 74. The latching mechanism using the latch protrusions 741b is described below.

The HDD 10 is fixed with screws inserted through fixing holes 772b and 773b formed on the front wall part 772 and the rear wall part 773, respectively, while the lower surface of the HDD 10 is placed on the cut-and-raised piece 773a.

Further, on both of the left and right sides of the base part 771 of the supporting plate 77, cutout sections 771b are formed. The cutout sections 771b are formed to avoid the interference with the latch protrusions 741b protruding from the first beam part 731 and the second beam part 732 above the base part 741 when the HDD unit including the supporting plate 77 is contained in the HDD container 74.

The HDD unit including the supporting plate 77 is first placed in a manner that the cutout sections 771b face the corresponding latch protrusions 741b. Here, the position where the HDD unit is placed as described above is herein called the “mounting position”. When the HDD unit is in the mounting position where the interference with the latch protrusions 741b is avoided due to the cutout sections 771b, the base part 771 is placed on the base part 741. Then, the HDD unit is slid toward the front direction.

Due to the slide, the latch protrusions 741b are placed on the base part 771 of the supporting plate 77, and the HDD unit is latched so that the HDD unit is not easily separated from the HDD container 74. As described above, the position where the HDD unit is supported in the HDD container 74 by sliding the HDD unit toward the front direction so that the base part 771 is latched with the latch protrusions 741b is herein called the “supporting position”.

When the HDD unit is slid from the mounting position to the supporting position, the latch protrusions 741c protruding from the front wall 742 of the of the HDD container 74 are also placed on lingua part 771d (see FIGS. 47 and 48) of the base part 771 of the supporting plate 77 and latch the base part 771.

Further, on each of the left and right ends of the base part 771 of the supporting plate 77, there is formed a swollen part 771c. The swollen parts 771c are formed at positions where the supporting plate 77 is in contact with the latch protrusions 741b when moved to the supporting position. Further, the swollen parts 771c are formed by a drawing process so as to be swollen on the latch protrusion 741b side.

Due to the formed swollen parts 771c, when the HDD unit is moved from the mounting position to the supporting position, the base part 771 of the supporting plate 77 may be tightly latched with the latch protrusions 741b. Further, the openings 771a formed on the base part 771 of the supporting plate 77 are overlapped with the holes 741a of the base part 741 when the HDD unit is moved from the mounting position to the supporting position, so that the openings 771a and the corresponding holes are communicated with each other.

Further, a gasket 779 is attached to the outer well of the front wall part 772, (see FIG. 48 but illustrated in a exploded manner). The gasket 779 may be contracted due to the collision with the front wall 742 of the HDD container 74 when the HDD unit is slid (moved) from the mounting position to the supporting position so as to reduce the impact to the HDD 10 in the sliding.

Further, the gasket 779 has electrical conductivity to ensure (reinforce) the electrical grounding to the holder 7 of the HDD unit. Further, on the front wall part 772 of the supporting plate 77, there are plural regions where the gasket 779 is attached to. Therefore, depending on the necessity, one or more gaskets may be adhered to the front wall part 772.

Further, the flange part 774 includes two rectangular holes (guide openings) 774a and a one fixing hole 774b. The rectangular holes 774a are formed so that the corresponding cut-and-raised pieces 743a are entered into the rectangular holes 774a. The fixing hole 774b is formed for fixing with a screw. After the cut-and-raised pieces 743a enter into the corresponding rectangular holes 774a, the cut-and-raised pieces 743a serve as guides the HDD unit when the HDD unit is placed to the mounting position by, for example, moving and rotating the HDD unit and when the HDD unit is slid from the mounting position to the supporting position.

When the HDD unit is slid from the mounting position to the moving position, the fixing hole 774b on the flange part 774 is overlapped with the screw hole 743b formed on the table part 743 of the HDD container 74. The supporting plate 77 is fixed to the holder 7 with a screw penetrating into the fixing hole 774b and screwing into the screw hole 743b.

FIG. 47 is a perspective view of the HDD unit including the HDD to which the supporting plate 77 is fixed when viewed from an upper side of the HDD. Further, FIG. 48 is a perspective view of the HDD unit when viewed from the base part 741 of the supporting plate 77.

The supporting plate 77 is fixed to the HDD 10 with screws screwed into the front wall part 772 and the rear wall part 773 of the supporting plate 77. As illustrated in FIG. 48, on the base part 771 of the supporting plate 77, there are formed plural openings 771a for assisting (improving) the air cooling of the HDD 10. Further, on each of the left and right ends of the base part 771, cutout sections 771f are formed to avoid the interference with the latch protrusions 741b (see FIGS. 44 through 46) formed on the HDD container 74 when the HDD is contained in the HDD container 74.

Further, at a border part between the base part 771 and the front wall part 772, there is a formed the lingua part 771d extending in the front direction. The lingua part 771d is latched with the latch protrusions 741c (FIG. 44) protruding from the front wall 742 of the HDD container 74 to the base part 771 when the HDD unit is slid from the mounting position to the supporting position. Further, in FIG. 48, there are illustrated the cut-and-raised pieces 772a and the cut-and-raised pieces 773a which are used to maintain the lower surface of the HDD 10 to be separated from the base part 771.

Further, on the front wall part 772 of the supporting plate 77, there are formed three gasket attachment parts 772d to which the gasket 779 may be attached. However, in this case, the gasket 779 is attached to the center gasket attachment part 772d only.

Further, on the flange part 774 expanding from the front wall 742 in the front direction, as described above, there are formed two rectangular holes 774a in which the corresponding cut-and-raised pieces 743a formed on the table part 743 of the HDD container 74 are entered. Further, on the flange part 774, there is also formed the fixing hole 774b which is to be in communication with the screw hole 743b so that the screw is entered into the fixing hole 774b and the screw hole 743b when the HDD unit is slid to the supporting position.

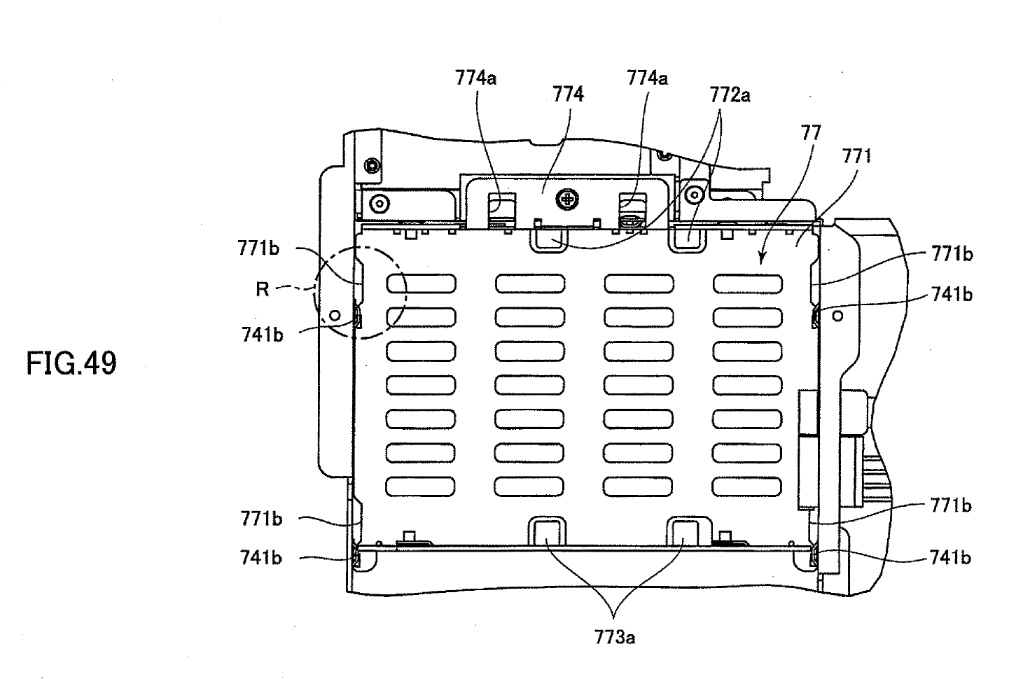

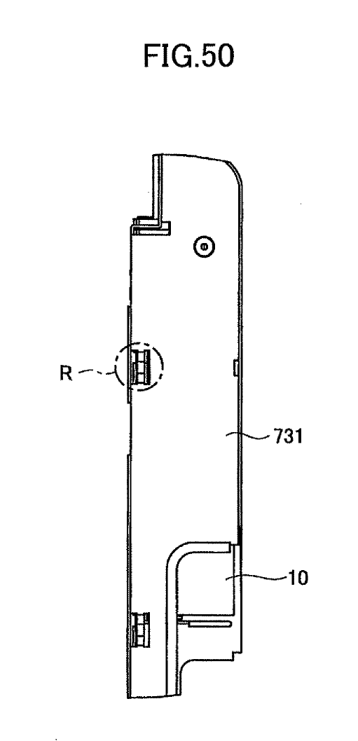

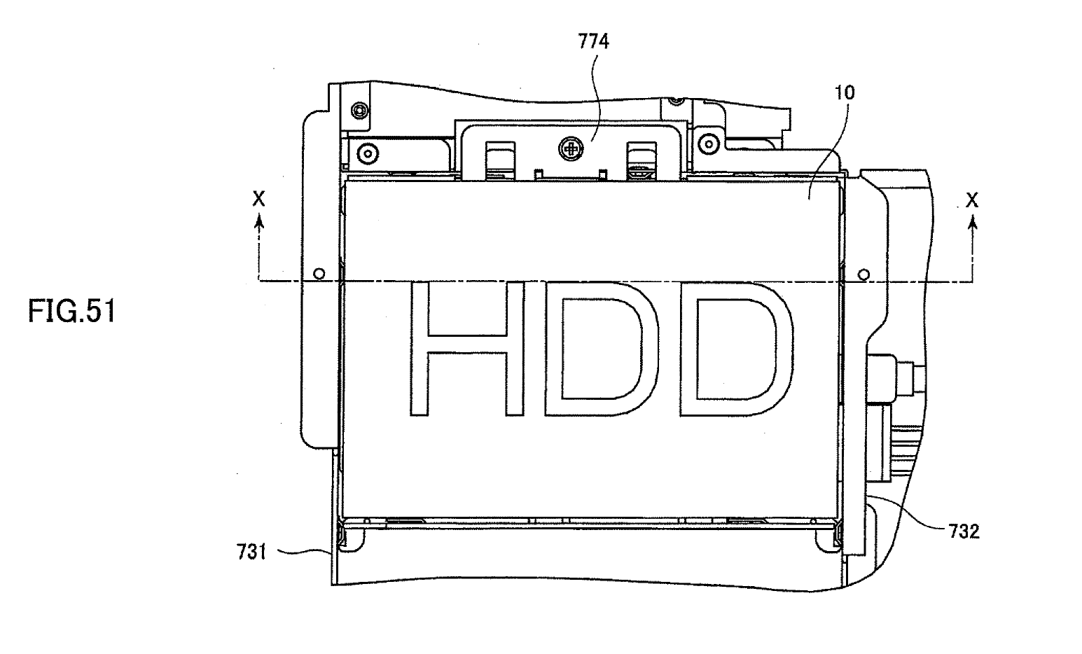

FIG. 49 is a top view illustrating a state where the supporting plate from which the HDD is removed is contained (accommodated) in the supporting position of the HDD container. FIGS. 50 and 51 are a left side view and a top view, respectively, in a state where the supporting plate with HDD (i.e., the HDD unit) is contained in the supporting position of the HDD container of the holder.

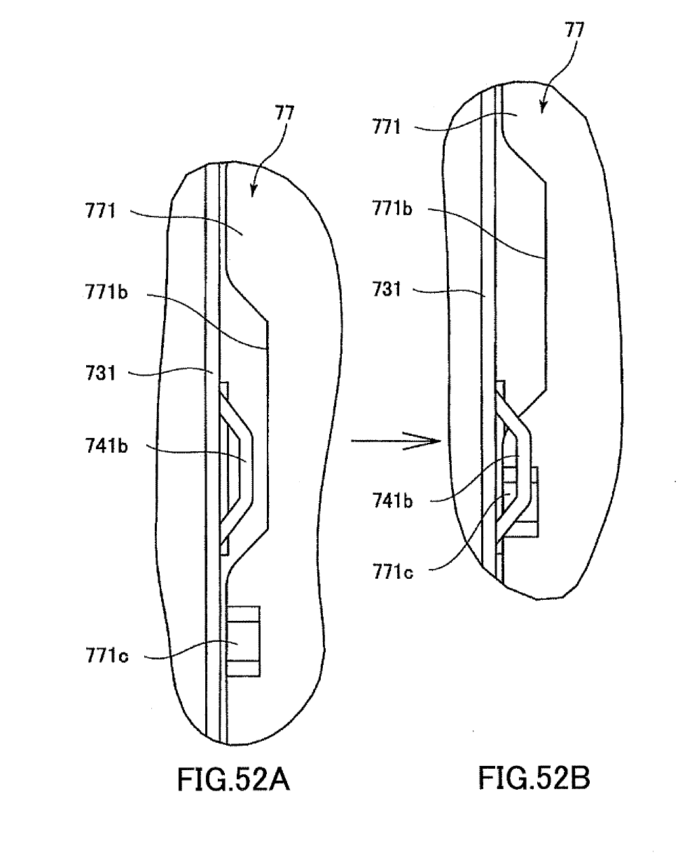

FIG. 52A is an enlarged views of a part of a circle R of FIG. 49 in a state where the supporting plate 77 is placed at the mounting position. FIG. 52B is an enlarged views of a part of a circle R of FIG. 49 in a state where the supporting plate 77 is slid to the supporting position.

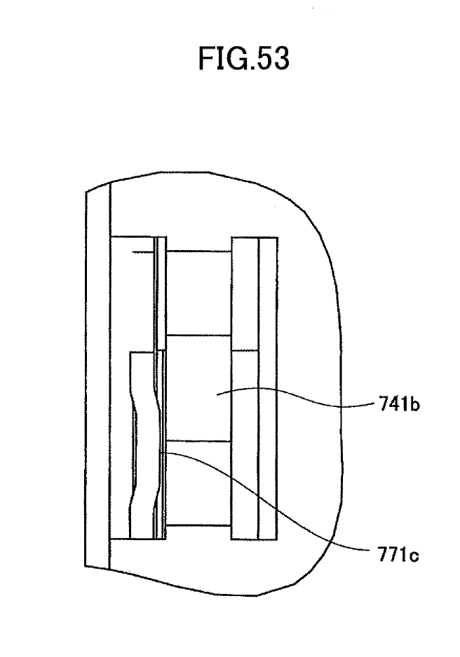

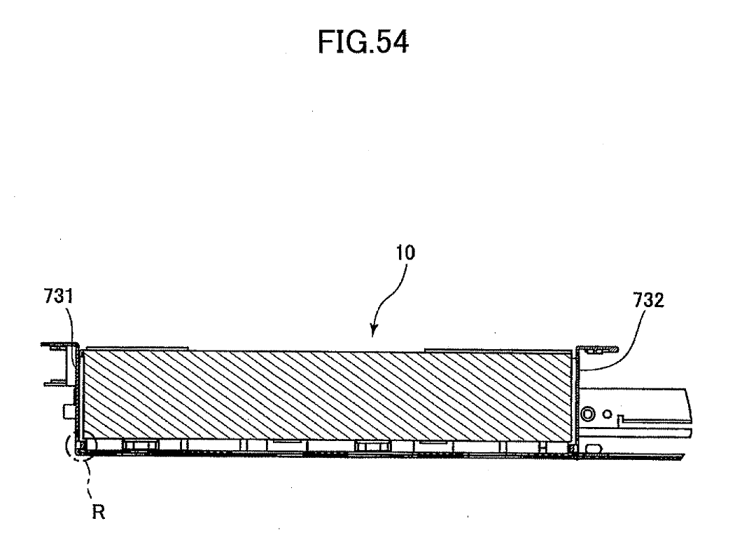

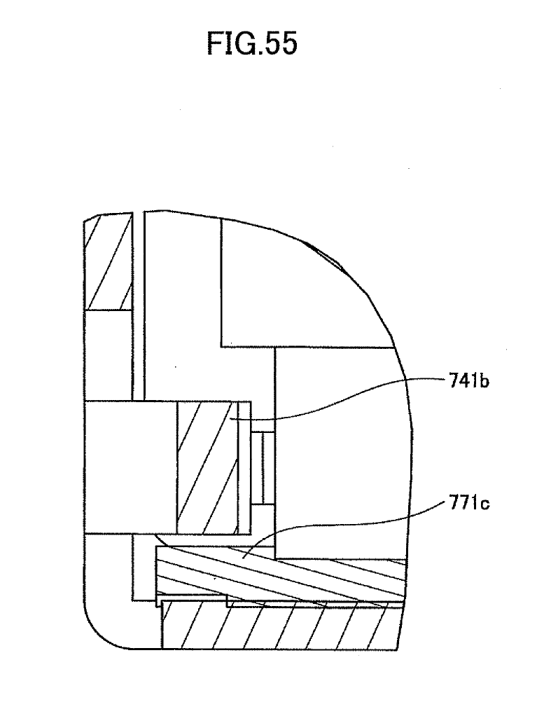

Further, FIG. 53 is an enlarged view of a part of a circle R of FIG. 50. The circle R of FIG. 50 indicates the same part indicated by the circle R of FIG. 49. FIG. 53 is a side view of the state illustrated in FIG. 52B. Further, FIG. 54 is a cross-sectional view when cut along the line X-X of FIG. 51. FIG. 55 is an enlarged view of a part of a circle R of FIG. 54. Namely, FIG. 55 illustrates a cross-section of the same part as illustrated by the circle R of FIG. 49 and the circle of R of FIG. 50.

When the supporting plate 77 is in the mounting position, as illustrated in FIG. 52A, the latch protrusion 741b protruding from the first beam part 731 of the holder is entered in the cutout section 771b of the supporting plate 77, so as to avoid the interference between the base part 771 and the latch protrusion 741b.

When the supporting plate 77 is slid from the mounting position to the supporting position, as illustrated in FIGS. 52B, 53, and 55, the position of the latch protrusion 741b is shifted from the position corresponding to the position of the cutout section 771b, and the latch protrusion 741b latches the base part 771. Here, the base part 771 includes the swollen parts 771c, and the base part 771 may be tightly latched with the latch protrusion 741b.

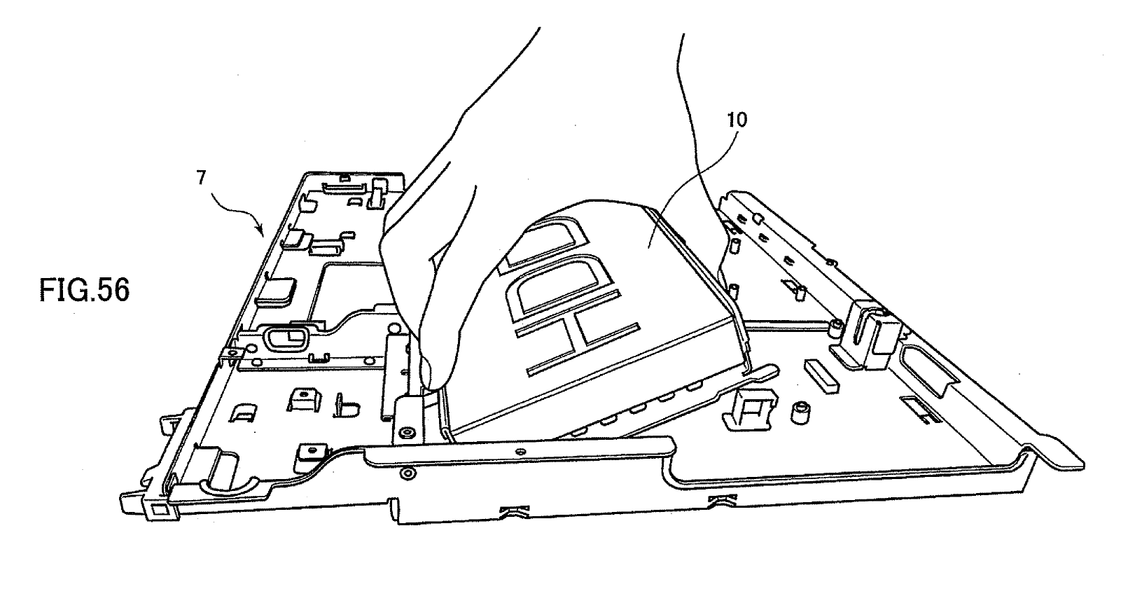

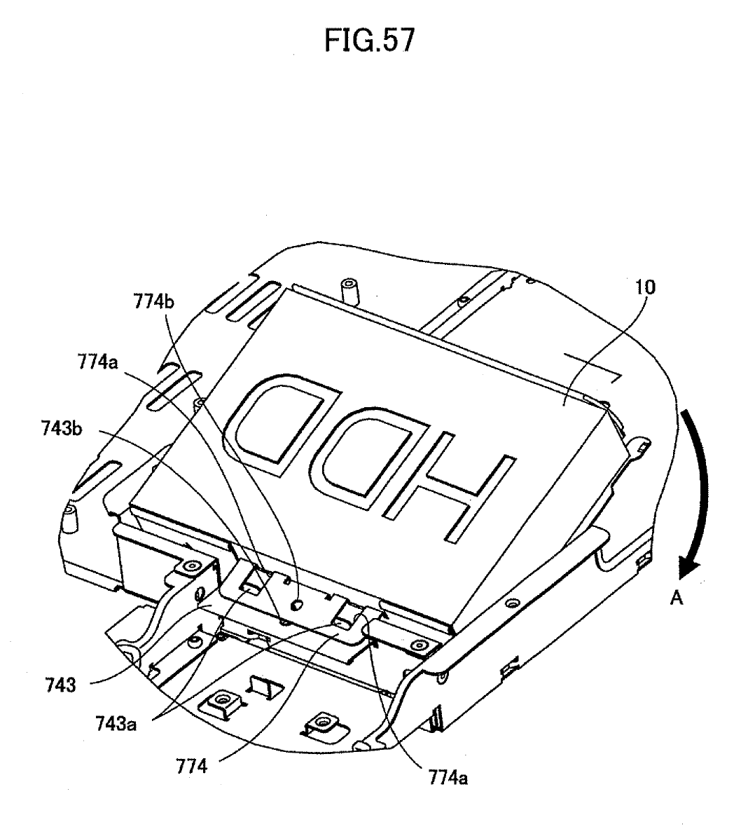

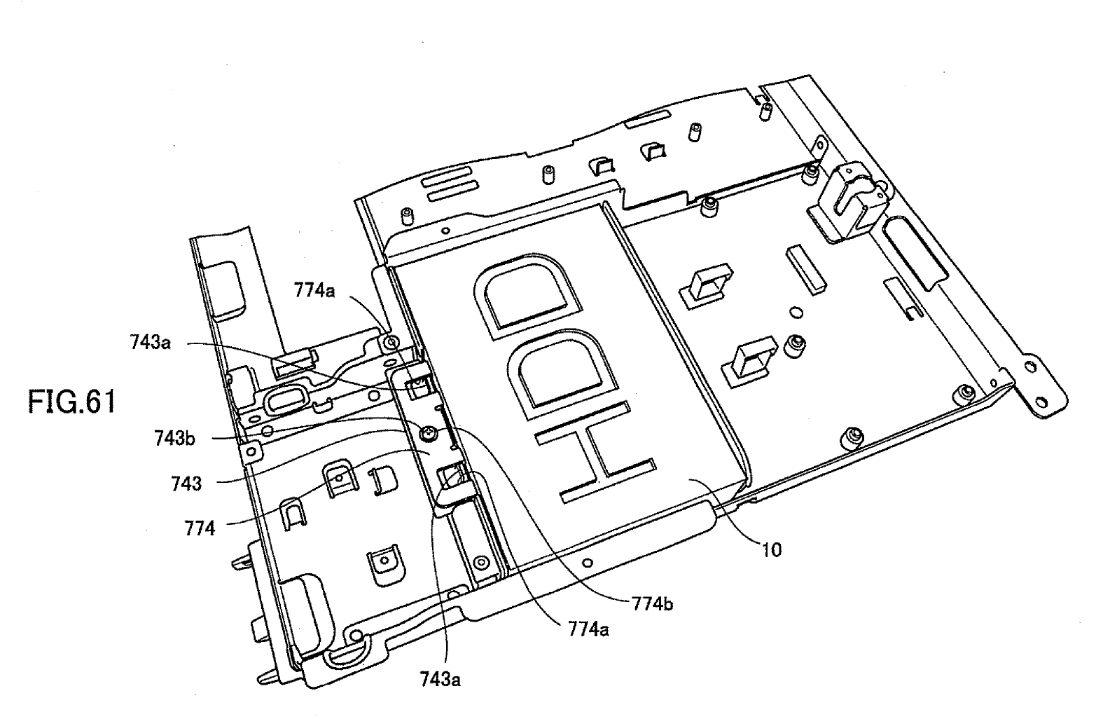

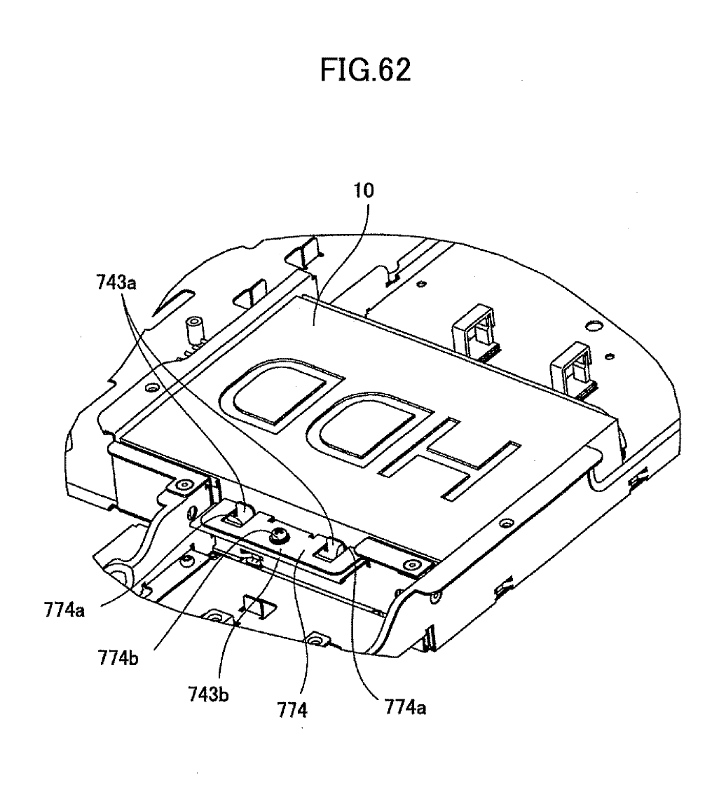

FIGS. 56 through 62 illustrate a procedure of containing the HDD unit in the HDD container 74. FIGS. 56 and 57 are views illustrating an initial process in the procedure of containing the HDD unit in the HDD container 74. Here, the HDD unit is handled (operated) by a hand of an operator. While the front side of the HDD unit is obliquely lowered, as illustrated in FIG. 57, the cut-and-raised pieces 743a formed by cutting parts of the table part 743 and raising the cut parts are raised and entered into the respective rectangular holes 774a formed on the flange part 774.

While the cut-and-raised pieces 743a are shifted (moved) to the front end of the rectangular holes 774a, the HDD unit is rotated in the arrow A direction of FIG. 57 by setting the cut-and-raised pieces 743a as the center of the rotation.

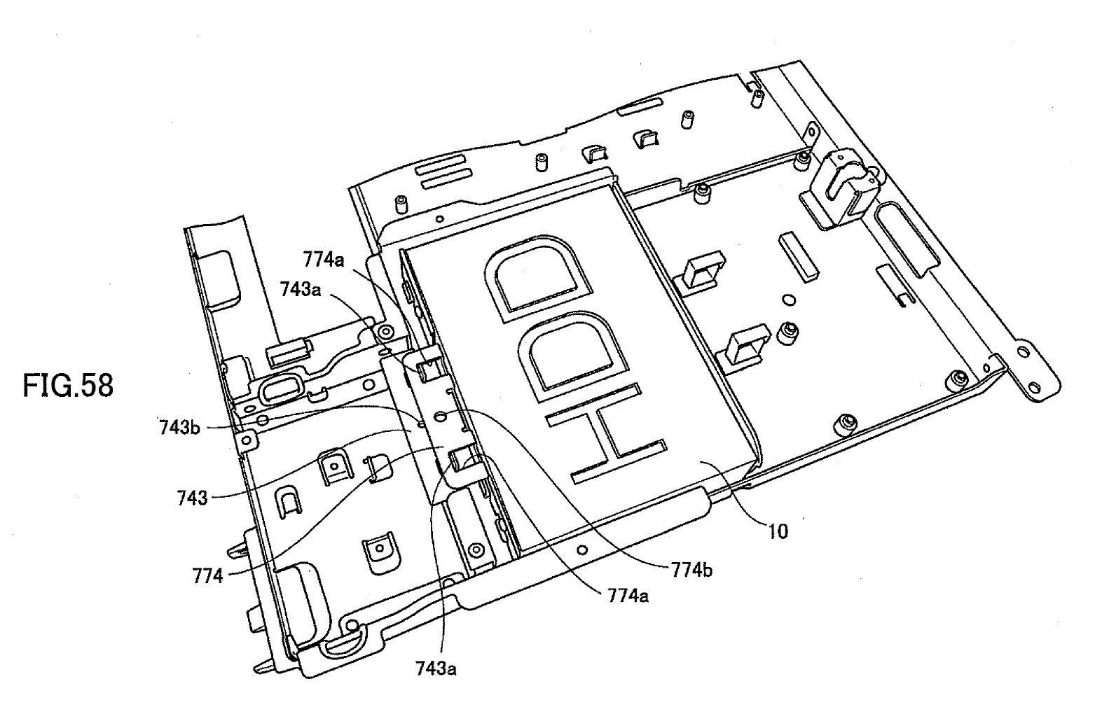

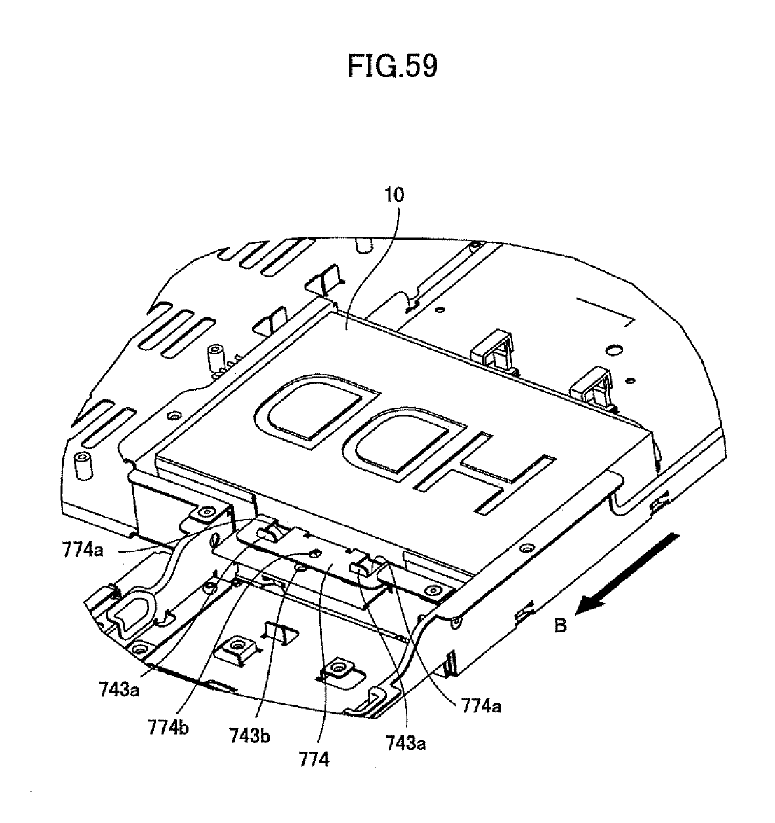

By doing this, the HDD unit is placed at the mounting position as illustrated in FIGS. 58 and 59. Therefore, the cutout sections 771b (see, for example, FIG. 49) formed on both side ends of the base part 771 of the supporting plate 77 are not interfered with the latch protrusions 741b even when the HDD unit is rotated as described above.

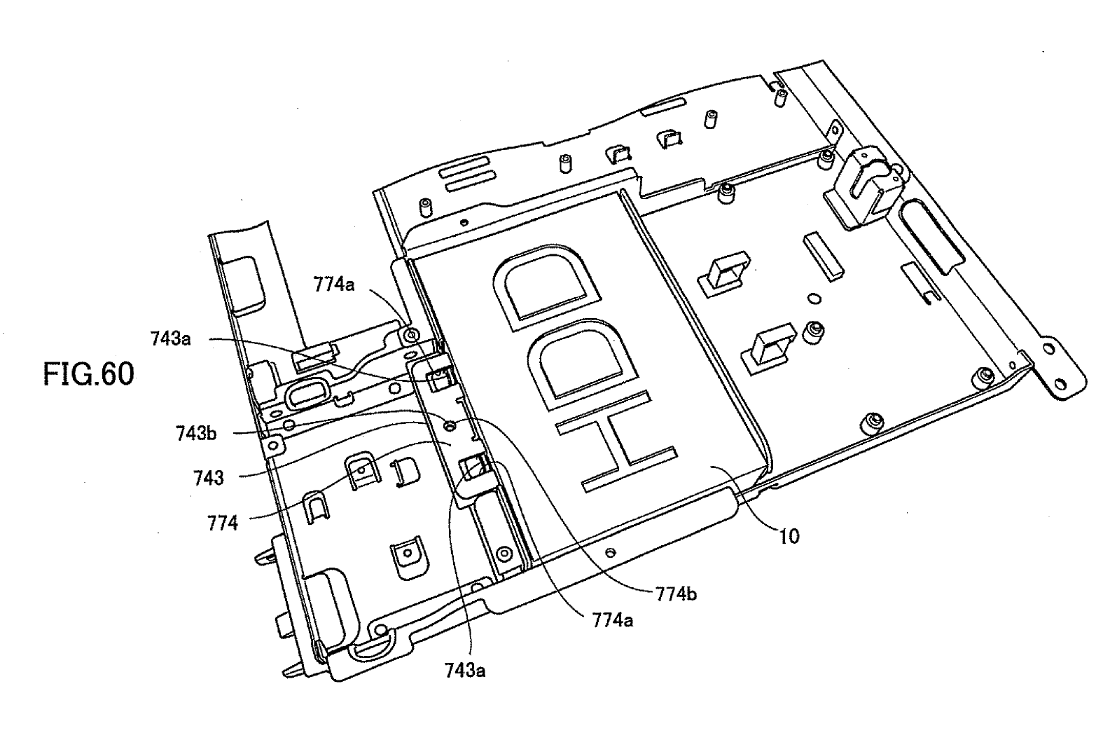

After that, the HDD unit is slid in the arrow B direction of FIG. 59 to the supporting position illustrated in FIG. 60 while being guided by the cut-and-raised pieces 743a. On this supporting position, the fixing hole 774b formed on the flange part 774 is overlapped with the screw hole 743b formed on the table part 743 as illustrated in FIG. 60. In this state of FIG. 60, the HDD unit is fixed with a screw which is entered into the fixing hole 774b and the screw hole 743b.

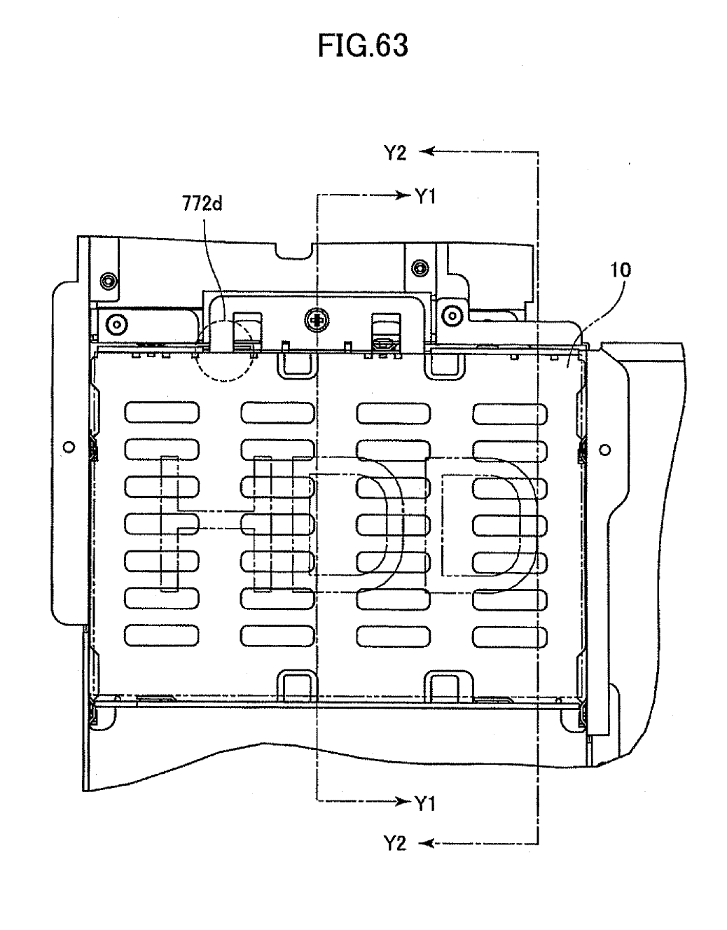

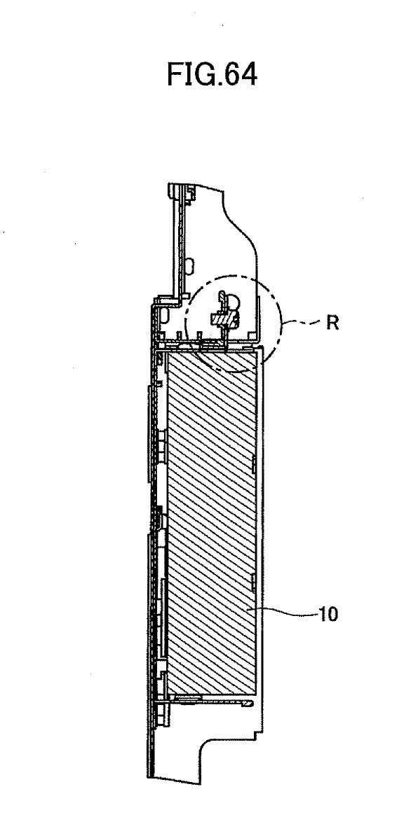

FIG. 63 is a top view of the HDD unit when being contained in the HDD container 74. However, in FIG. 63, the HDD 10 is illustrated as a transparent body except the “HDD” characters. Further, FIG. 64 is a cross-sectional view when cut along the line Y1-Y1 of FIG. 63.

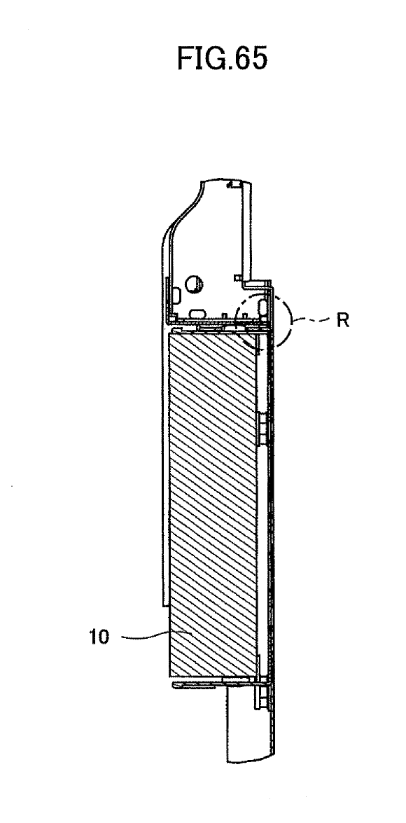

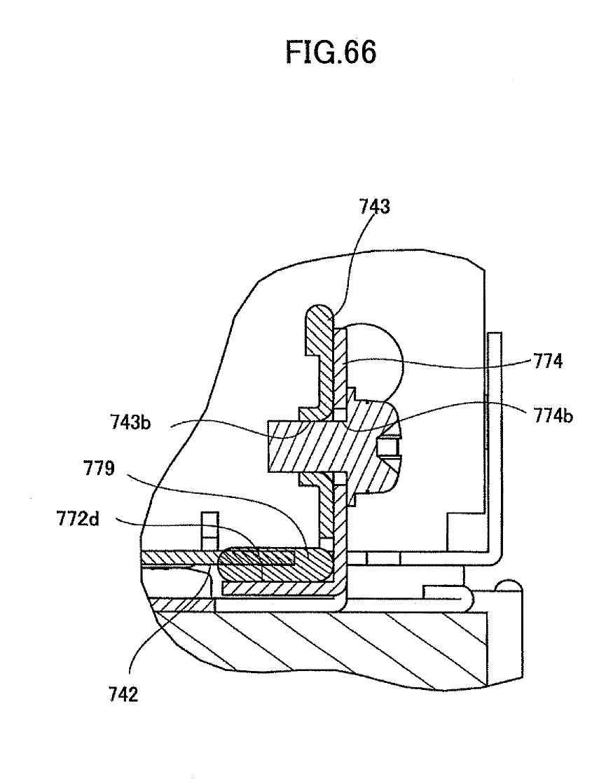

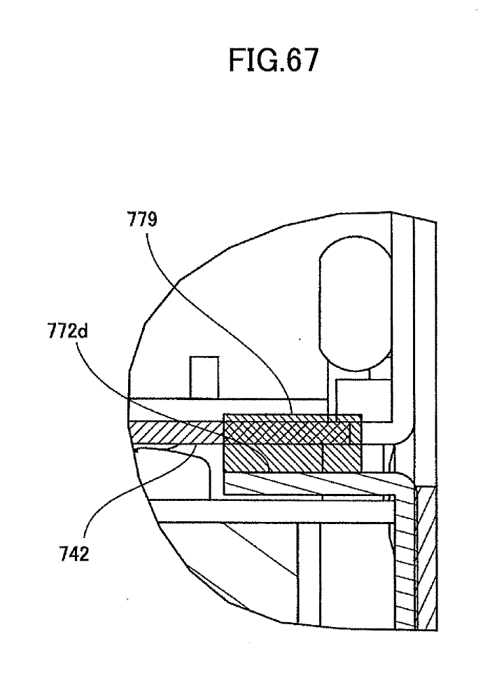

Further, FIG. 65 is a cross-sectional view when cut along the line Y2-Y2 of FIG. 63. Further, FIG. 66 is an enlarged view of a part of a circle R of FIG. 64, and FIG. 67 is an enlarged view of a part of a circle R of FIG. 65.

As illustrated in FIG. 66, the flange part 774 is disposed on (overlapped with) the table part 743, and the flange part 774 is fixed to the table part 743 with a screw penetrating the fixing hole 774b of the flange part 774 and the screw hole 743b of the table part 743. Further, in FIG. 66, only the center gasket attachment part 772d among the three gasket attachment parts 772d of FIG. 48 is illustrated, and the gasket 779 is attached to the center gasket attachment part 772d.

In FIG. 66, the gasket 779 is illustrated as being overlapped with the front wall part 772. This is because the original size (shape) of the gasket 779 before being contracted (shrunk) is illustrated for explanatory purposes. As a matter of fact, the gasket 779 is pressed to the front wall 742 and is contracted (shrunk).

In FIG. 67, the gasket attachment part 772d on the right-hand side is illustrated. In FIG. 48, the gasket 779 is not attached to this gasket attachment part 772d. However, as illustrated in FIG. 67, the supporting plate 77 (see, for example, FIG. 48) may have a configuration where the gasket 779 is attached to this gasket attachment part 772d.

Further, in the part illustrated by the circle illustrated in a dotted line of FIG. 63, there is formed (provided) the gasket attachment part 772d where the gasket 779 may be attached to.

As described above, the gasket 779 is provided to make the impact generated when the HDD unit is contained harder to transferred to the HDD and ensure the electrical ground of the HDD unit.

Next, a configuration of fixing the HDD unit in an electronic device according to a second embodiment illustrated in FIG. 21 is described. Here, in this second embodiment, the same reference numerals are basically used to describe the same elements but a suffix “_2” is herein appended to the reference numerals in the second embodiment. Further, repeated description may be omitted and differences from the elements in the first embodiment are mainly described.

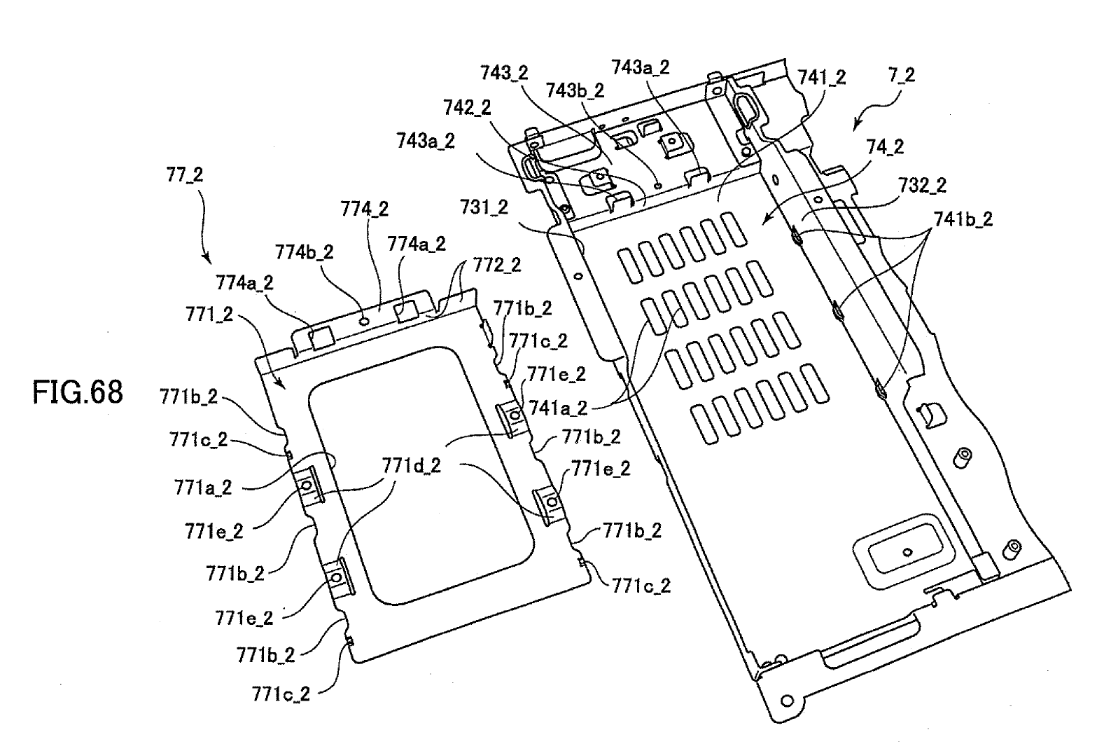

FIG. 68 is a perspective view of a part of an HDD container 74_2 of a holder 7_2 and a supporting plate 77_2 to be fixed to an HDD in an electronic device 1_2 of FIG. 21 according to the second embodiment.

The holder 7_2 includes the HDD container 74_2. The HDD container 74_2 includes a base part 741_2. On both sides of the base part 741_2, a first beam part 731_2 and a second beam part 732_2 are formed. Further, on the front side of the HDD container 74_2, there is formed a front wall 742_2, and a table part 743_2 is further formed.

On the base part 741_2, there are formed openings 741a_2 penetrating between the front and rear surfaces. Further, from each of the first beam part 731_2 and the second beam part 732_2, latch protrusions 741b_2 protrude (extend) in the lateral direction above the base part 741_2. Further, on the table part 743_2, there are formed two cut-and-raised pieces 743a_2 and one screw hole 743b_2.

Further, the supporting plate 77_2 includes a base part 771_2, a front wall part (standing part) 772_2, and a flange part 774_2. On the base part 771_2, there is formed a large opening 771a_2 penetrating between the front and rear surfaces of the base part 771_2. Further, on both end sides of the base part 771_2, there are formed cutout sections 771b_2. Further, there are formed swollen parts 771c_2 at positions near (adjacent to) the corresponding cutout sections 771b_2.

Further, on the base part 771_2, there are formed HDD mounting plates 771d_2 protruding to the side where the HDD is mounted. On the HDD mounting plates 771d_2, a fixing hole 771e_2 for screw fixing is formed.

In this embodiment, when compared with the first embodiment, the HDD is contained after the HDD is rotated at 90 degrees. This HDD is placed on the HDD mounting plates 771d_2 formed on the base part 771_2 of the supporting plate 77_2, and the lower surface of the HDD is fixed. Therefore, similar to the first embodiment, of the lower surface of the HDD is maintained at a position separated from the base part 771_2.

Further, on the flange part 774_2 of the supporting plate 77_2, there are formed two rectangular holes 774a_2 and one fixing hole 774b_2.

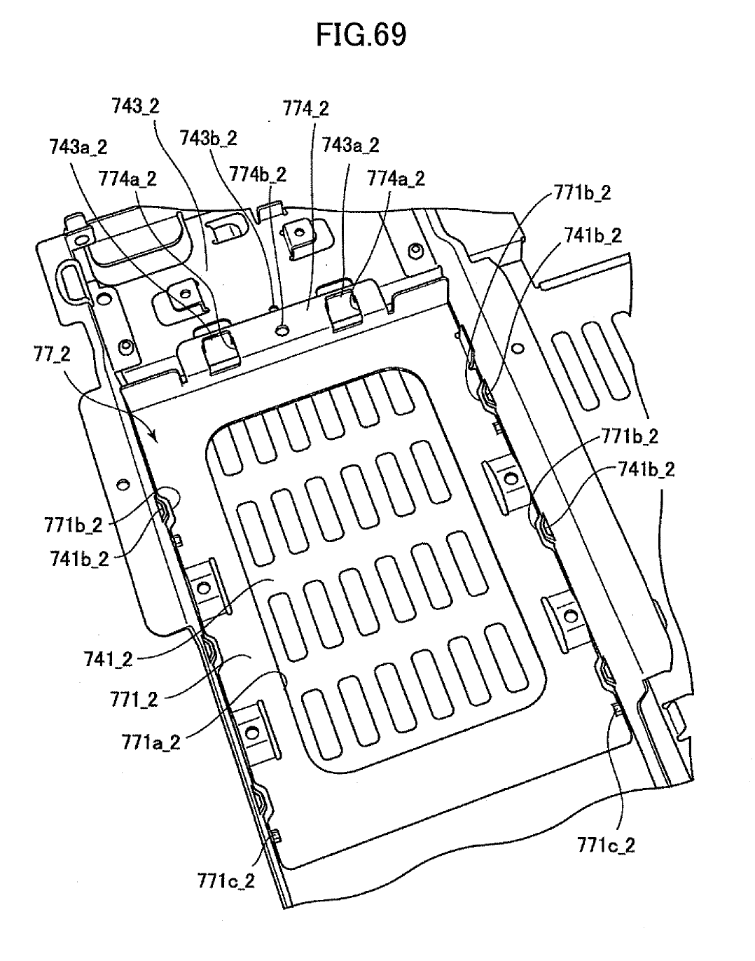

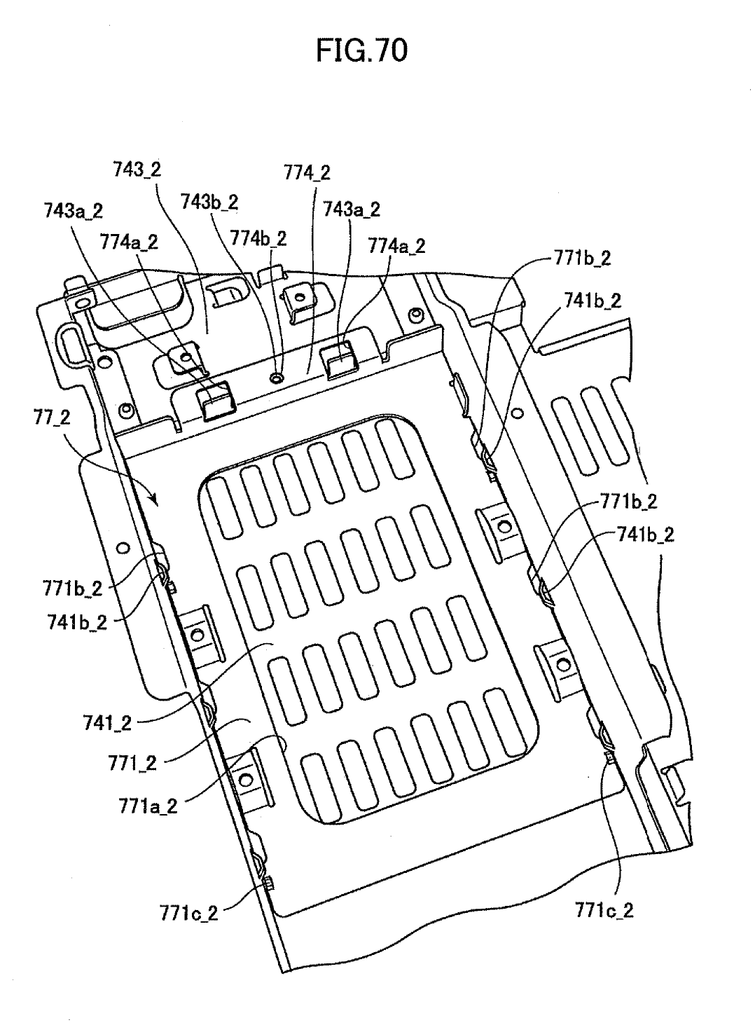

FIGS. 69 and 70 are perspective views illustrating a state where the supporting plate from which the HDD is removed is contained in the HDD container. More specifically, FIG. 69 illustrates a case where the supporting plate 77_2 is in the mounting position, and FIG. 70 illustrates a case where the supporting plate 77_2 is in the supporting position.

In the mounting position of FIG. 69, the positions of the cutout sections 771b_2 correspond to the positions of the latch protrusions 741b_2. Therefore, the base part 771_2 is placed on the base part 741_2 without being interfered with by the latch protrusions 741b_2. When the supporting plate 77_2 is slid to the supporting position illustrated in FIG. 70, the positions of the latch protrusions 741b_2 are shifted from the positions corresponding to the positions of the cutout sections 771b_2, and latch the base part 771_2 of the supporting plate 77_2

Further, concurrently, the fixing hole 774b_2 of the flange part 774_2 is overlapped with the screw hole 743b_2 of the table part 743_2. In this state, the HDD container 74_2 is fixed to the supporting plate 77_2 with a screw entering the fixing hole 774b_2 and the screw hole 743b_2.

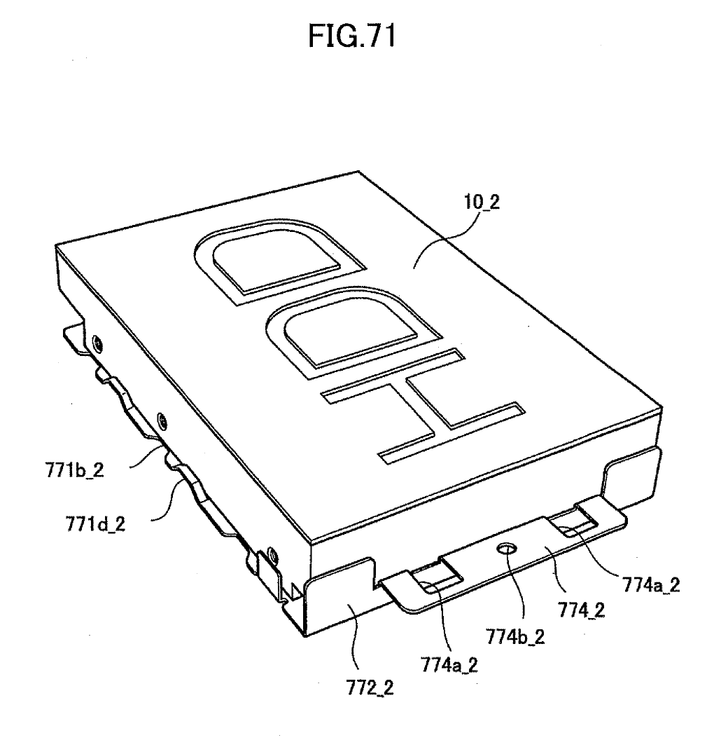

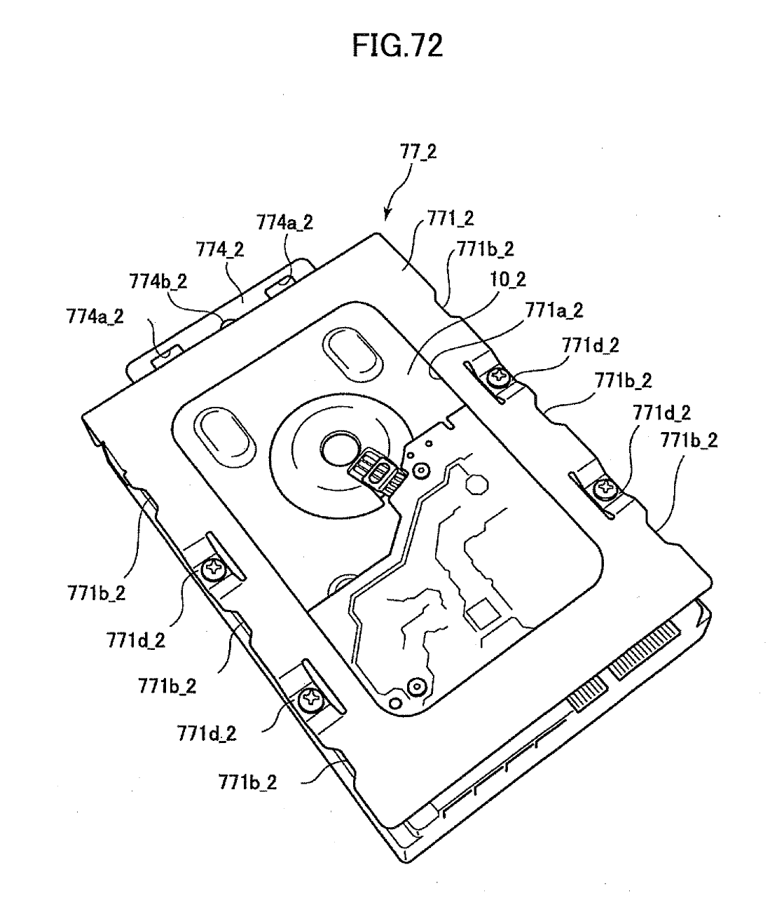

FIG. 71 is a perspective view of the HDD unit where the supporting plate is attached to the HDD when viewed from the upper surface side of the HDD. Further, FIG. 72 is a perspective view of the HDD unit when viewed from the supporting plate based part side.

In FIG. 72, the lower surface of the HDD 10_2 appears through the opening 771a_2. The supporting plate 77_2 is fixed to the HDD 10_2 with screws at the positions of the HDD mounting plates 771d_2 formed on the base part 771_2 of the supporting plate 77_2 and protruding toward the HDD side. Therefore, the lower surface of the HDD 10_2 is separated from the base part 771_2 of the supporting plate 77_2. Namely, there is a space generated between the lower surface of the HDD 10_2 and the base part 771_2 of the supporting plate 77_2.

As described above, the space is formed for promoting the air cooling of the HDD 10_2. Further, on the supporting plate 77_2, there is formed the flange part 774_2. The configuration (structure) of the flange part 774_2 is similar to the flange part 774 in the first embodiment.

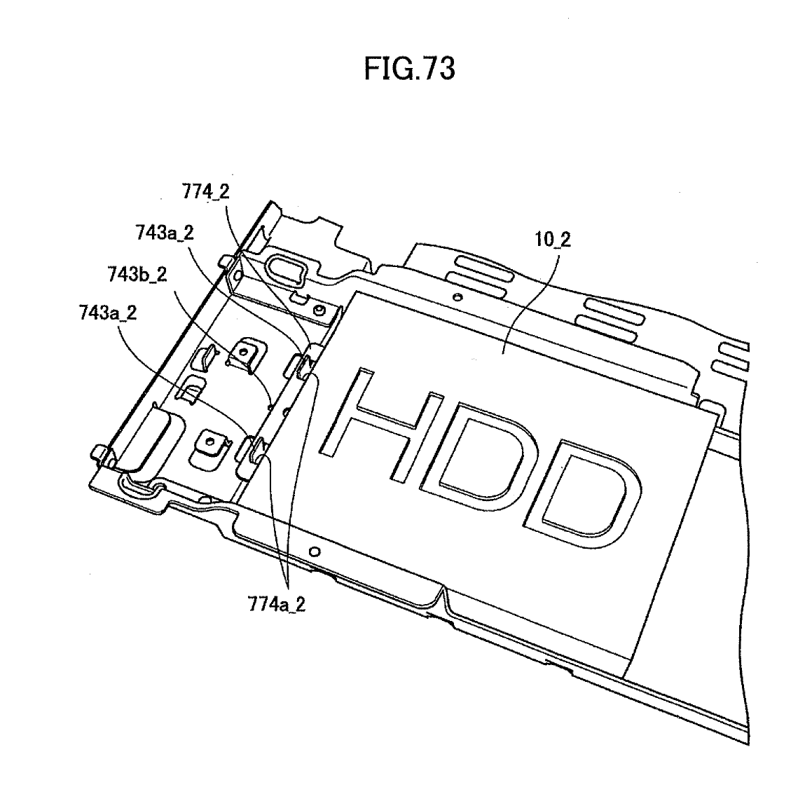

FIG. 73 is a perspective view illustrating a state where the HDD unit including the HDD 10_2 is placed at the mounting position of the HDD container. In this embodiment, unlike the first embodiment where the HDD unit is placed in the HDD container while being rotated (see FIGS. 5 and 6), in this embodiment, the HDD unit is placed while being in a horizontal attitude (position).

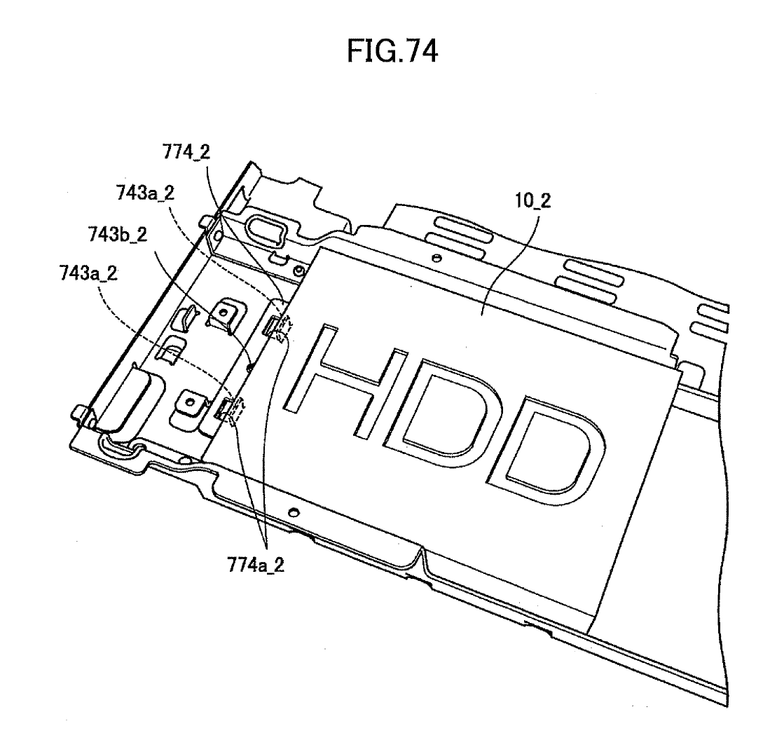

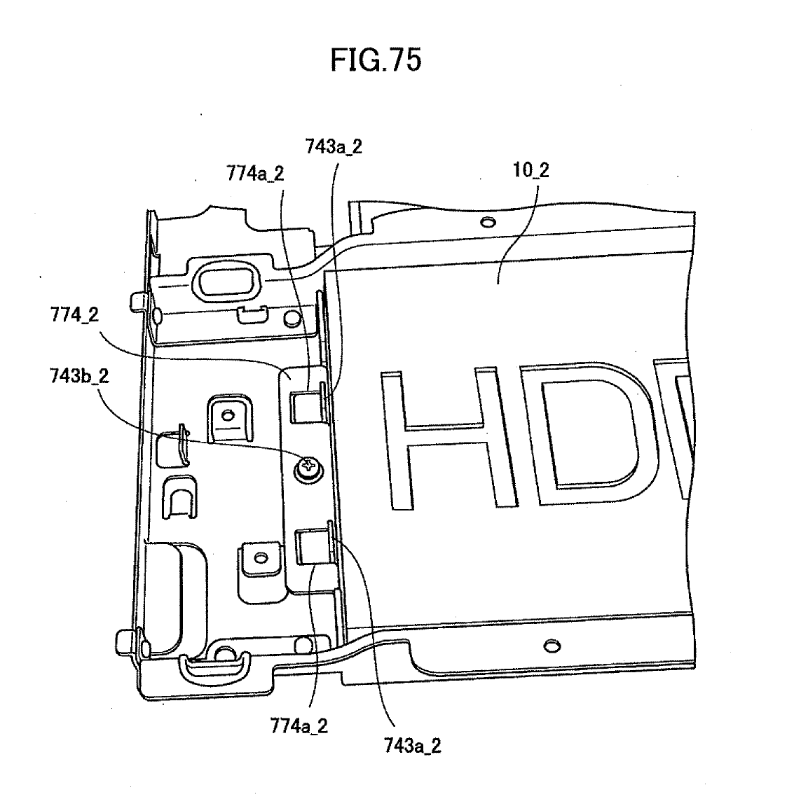

FIG. 74 is a perspective view illustrating a state where the HDD unit is moved from the mounting position in FIG. 73 to the supporting position. Further, FIG. 75 is a perspective view illustrating a state where the HDD unit is further fixed with a screw.

The configurations of the slide movement to the supporting position and the fixing with a screw are similar to those in the first embodiment.

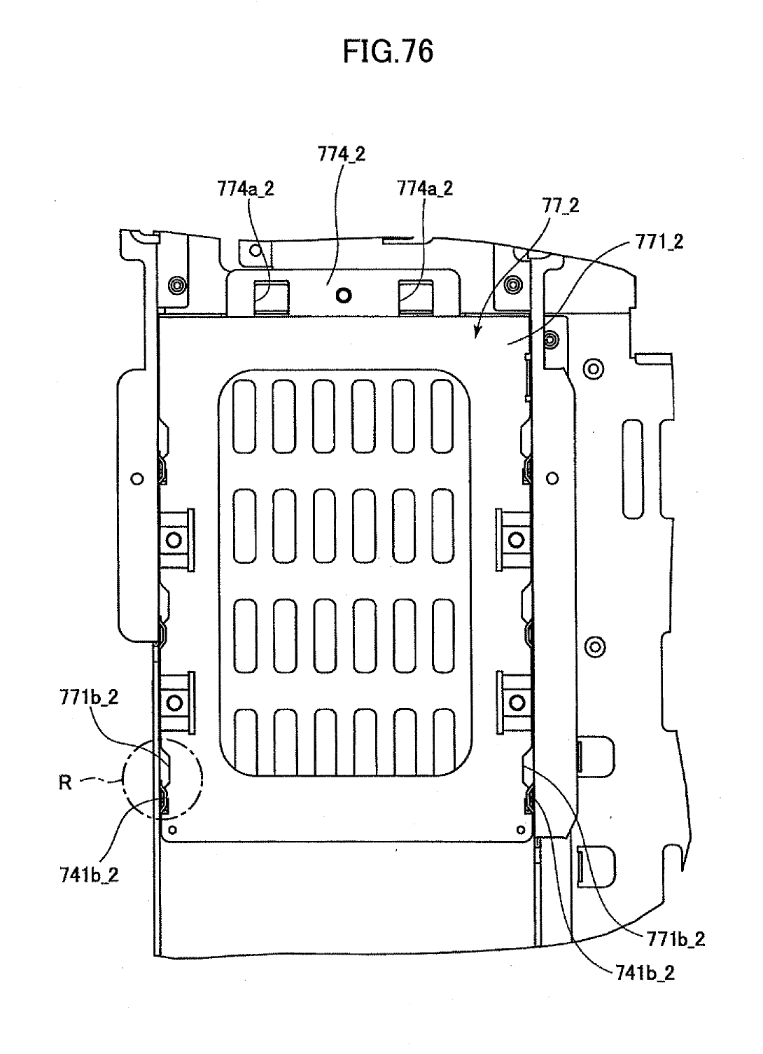

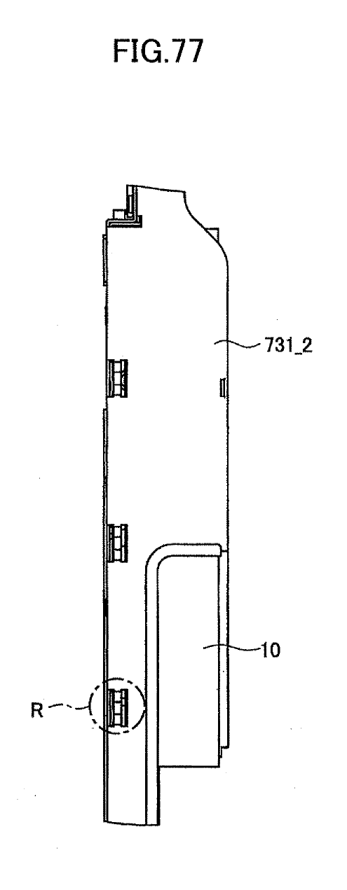

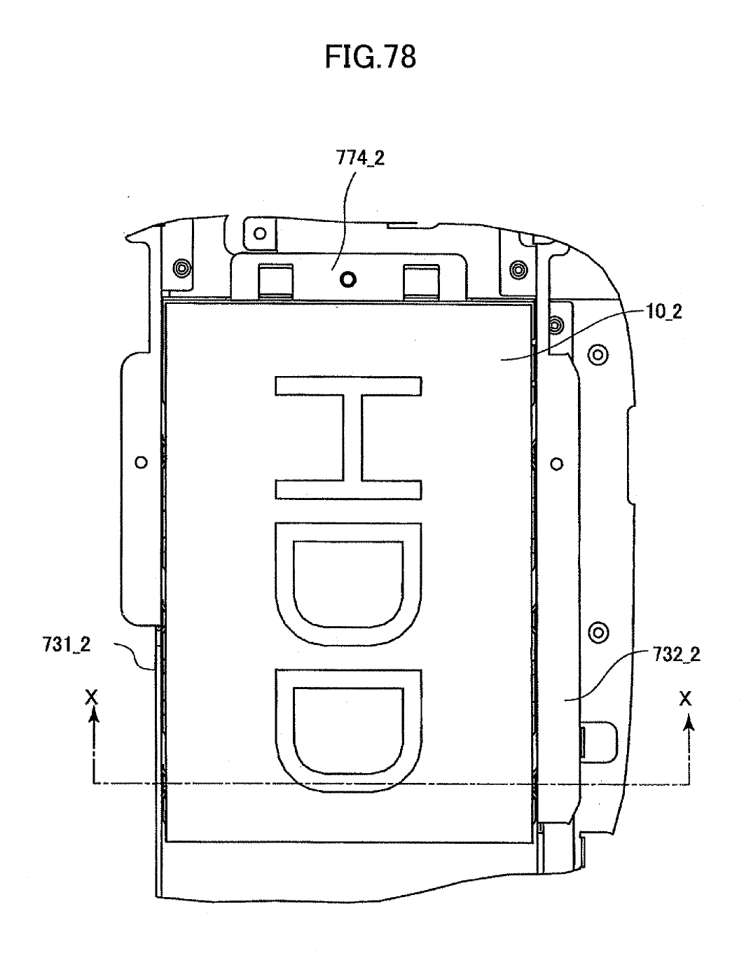

FIG. 76 is a top view illustrating a state where the supporting plate from which the HDD is removed is contained to the supporting position of the HDD container of the holder. Further, FIGS. 77 and 78 are a left side view and a top view, respectively, illustrating a state where the supporting plate having the HDD (i.e., the HDD unit) is contained to the supporting position of the HDD container of the holder.

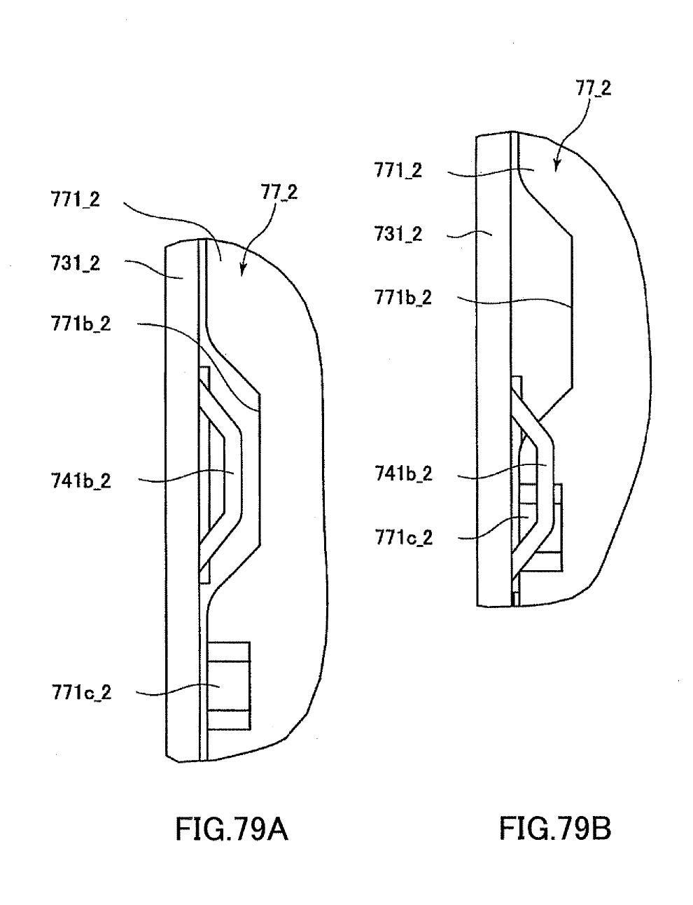

Further, FIGS. 79A and 79B are enlarged views of a part of a circle R of FIG. 49. Specifically, FIG. 79A illustrates a case where the supporting plate is in the mounting position, and FIG. 79B illustrates a case where the supporting plate is slid to the supporting position.

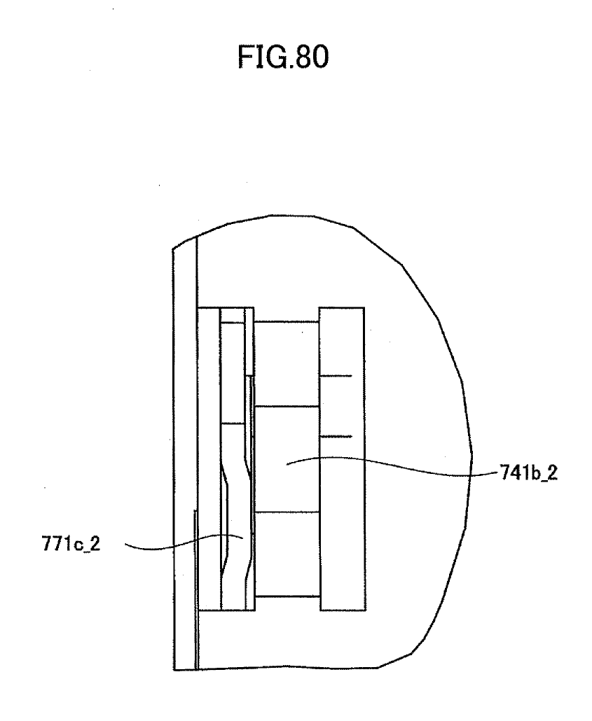

Further, FIG. 80 is an enlarged view of a part of a circle R of FIG. 77. The circle R in FIG. 77 indicates the same portion as that indicated by the circle R of FIG. 76, and FIG. 80 is a side view of a state of FIG. 79B.

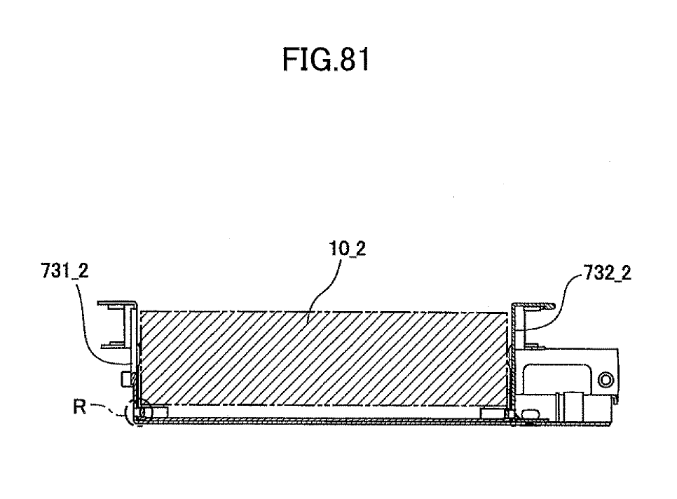

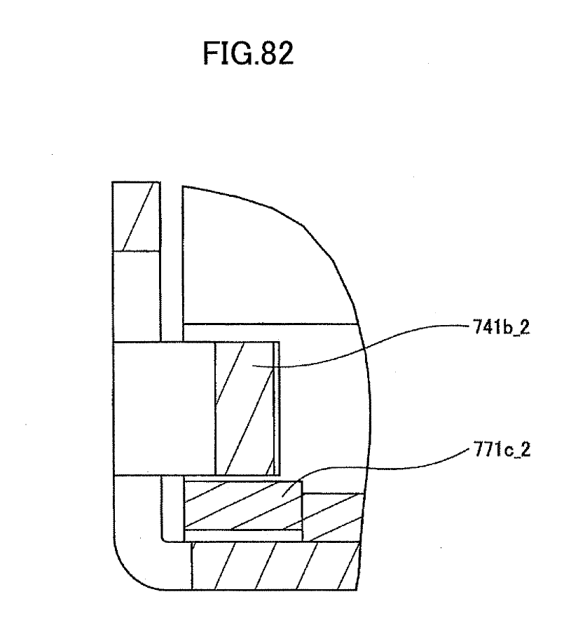

FIG. 81 is a cross-sectional view when cut along the line X-X of FIG. 78. Further, FIG. 82 is an enlarged view of a part of a circle R of FIG. 81. Namely, FIG. 82 illustrates a cross-section of the same part as illustrated by the circle R of FIG. 77.

When the supporting plate 77_2 is in the mounting position, as illustrated in FIG. 77A, the latch protrusions 741b_2 protruding from the first beam part 731_2 are entered in the corresponding cutout sections 771b_2 of the base part 771_2 of the supporting plate 77_2 to avoid the interference between the base part 771_2 and the latch protrusions 741b_2.

When the supporting plate 77_2 is slid to the supporting position, as illustrated in FIGS. 81B, 82, and 84, the positions of the latch protrusions 741b_2 are shifted from the positions corresponding to the positions of the cutout sections 771b_2, and the latch protrusions 741b_2 are interfered with and latched with the base part 771_2. Here, on the base part 771_2, there is formed a swollen part 771c_2, and the base part 771_2 is firmly latched by the latch protrusions 741b_2.

### Configuration of Image Display Panel

Next, an example configuration of the image display panel is described.

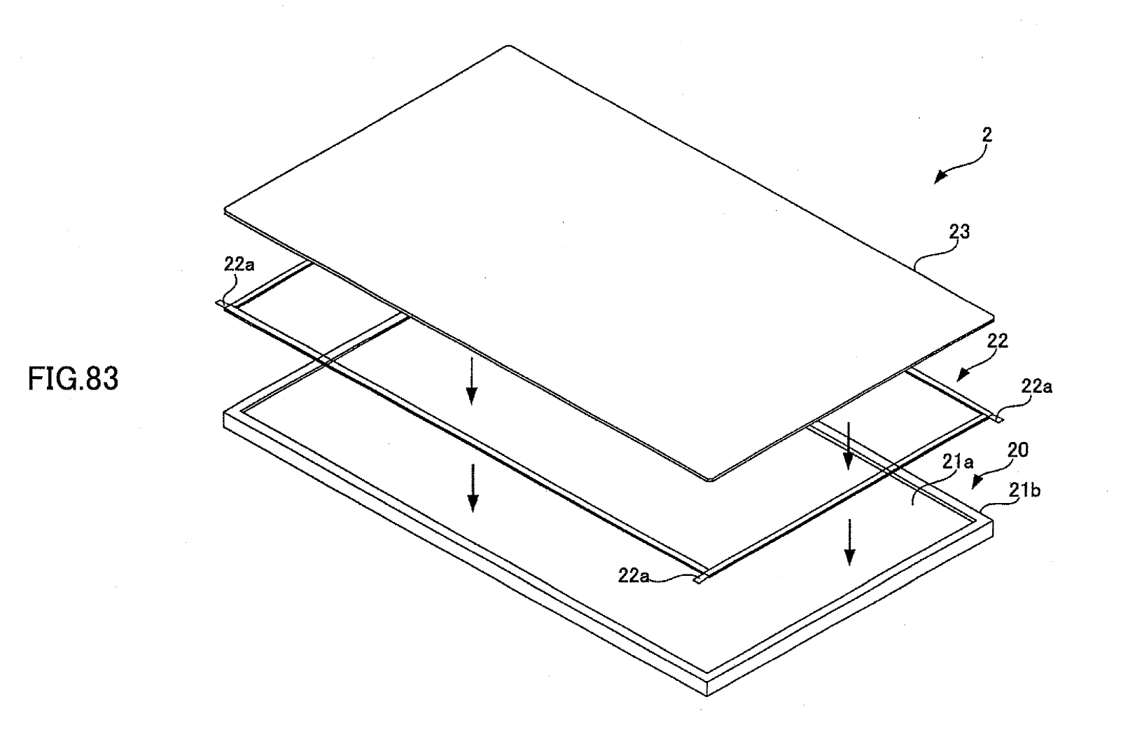

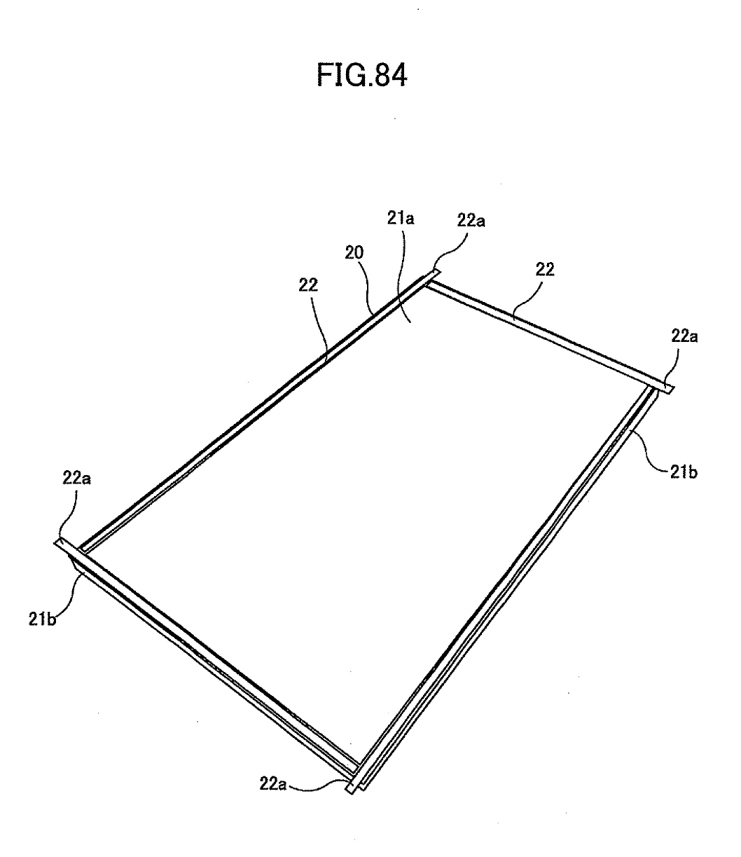

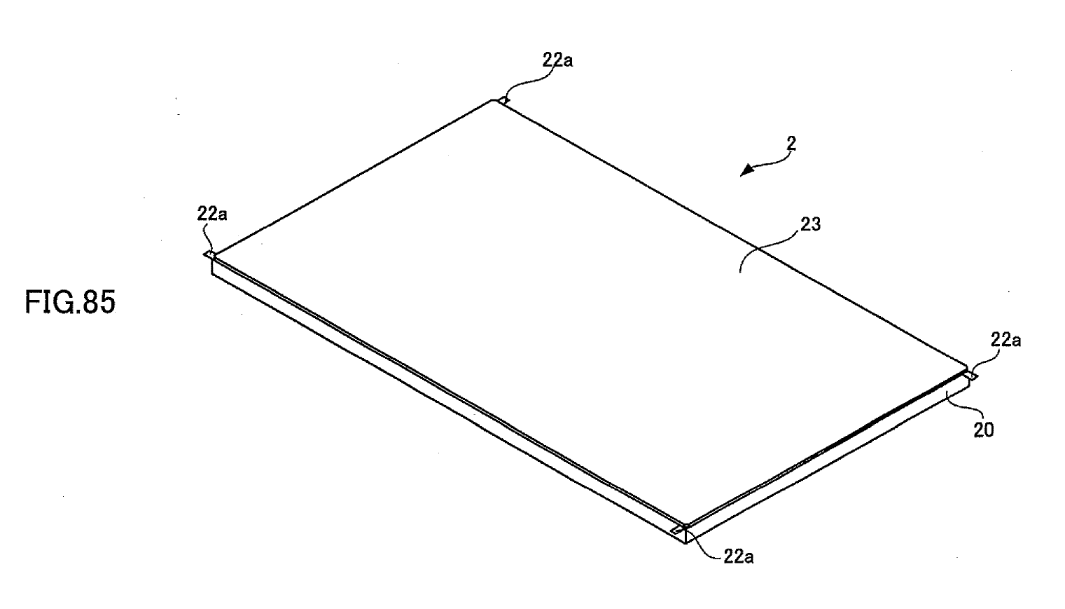

FIG. 83 is an exploded perspective view of the image display panel. Further, FIG. 84 is a perspective view illustrating a state where a double-sided adhesive tape is adhered on the image display plate. Further, FIG. 85 is a perspective view illustrating a state where a protection panel is further placed on the image display plate.

The image display panel 2 includes a rectangular image display plate 20, a double-sided adhesive tape 22, and a protection panel 23. The image display plate 20 includes the image display screen 21a and a frame body 21b peripherally surrounding the image display screen 21a. Here, as the double-sided adhesive tape 22, four double-sided adhesive tapes 22 are used so as to be adhered to the corresponding four corners of the front surface facing the front surface side (double-sided adhesive tape side) of the frame body 21b.

The double-sided adhesive tape 22 is adhered in a manner such that a tag 22a which is one end part of the double-sided adhesive tape 22 protrudes (exposed) outside the frame body 21b. Further, the double-sided adhesive tapes 22 are adhered as described above, the protection panel 23 made of transparent glass or the like is placed. The protection panel 23 is adhered to the image display plate 20 due to the four double-sided adhesive tapes 22.

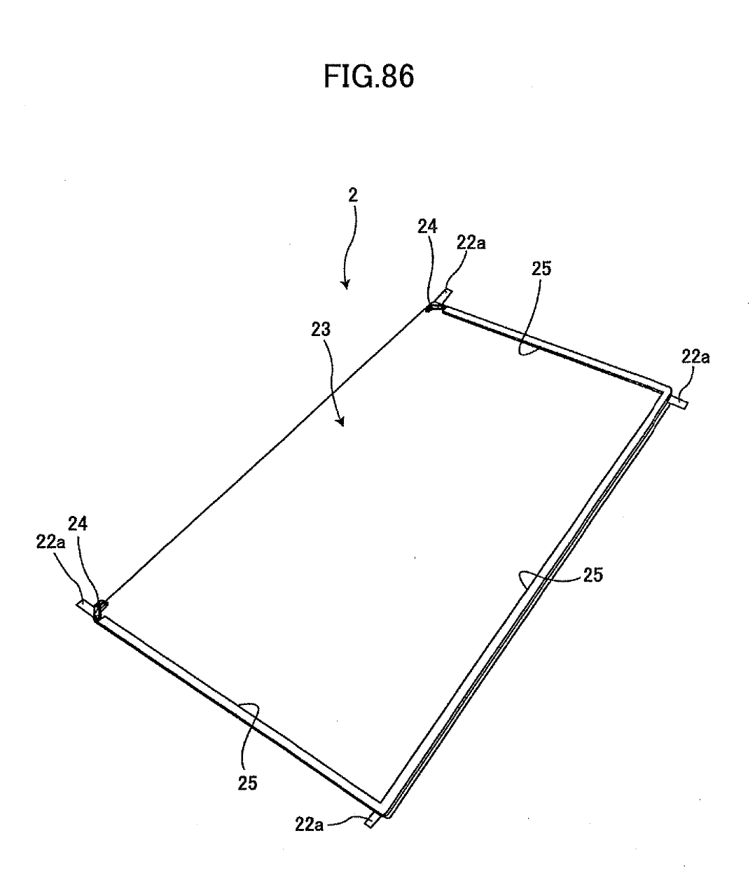

FIG. 86 is a perspective view illustrating a state where an optical touch sensor is integrated on the protection panel.

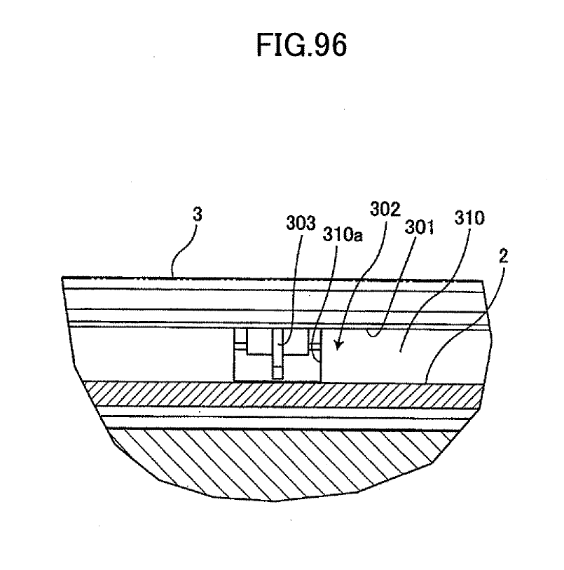

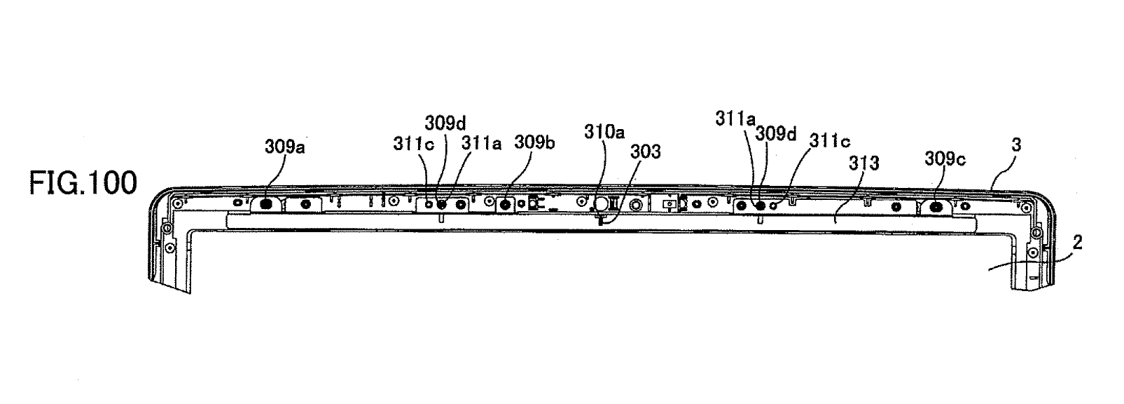

There are two infrared light emitting and receiving units 24 for touch sensors disposed at the corresponding right and left ends of the upper end of the image display panel 2. Further, reflection surfaces 25 standing (raised) on the image display panel 2 and facing inside of the image display panel 2 are disposed and extend along the right and the left ends and the lower end of the image display panel 2. However, no reflection surface is disposed along the upper end of the image display panel 2. On the part of the upper end, as described above, it may be desired to form a space except for a rib 303 (FIGS. 96 and 100) to avoid unnecessary reflection.

The infrared light emitting and receiving unit 24 emits infrared light. The infrared light emitted from the infrared light emitting and receiving unit 24 travels along the front surface of the image display panel 2 in a manner that the infrared light covers the entire front surface of the image display panel 2 and is reflected by the reflection surfaces 25.

When a finger or any other object touches the front surface of the image display panel 2, the infrared light reflected by the reflection surfaces 25 is blocked (interrupted). As a result, the infrared light emitting and receiving units 24 detects the position of the finger or any other object on the image display panel 2 by using a circuit (not shown). The circuit performing a predetermined process on the signal capturing the reflected infrared light is disposed on the upper side of the supporting member 9 (see, for example, FIG. 10) fixed to the rear surface side of the image display panel 2.

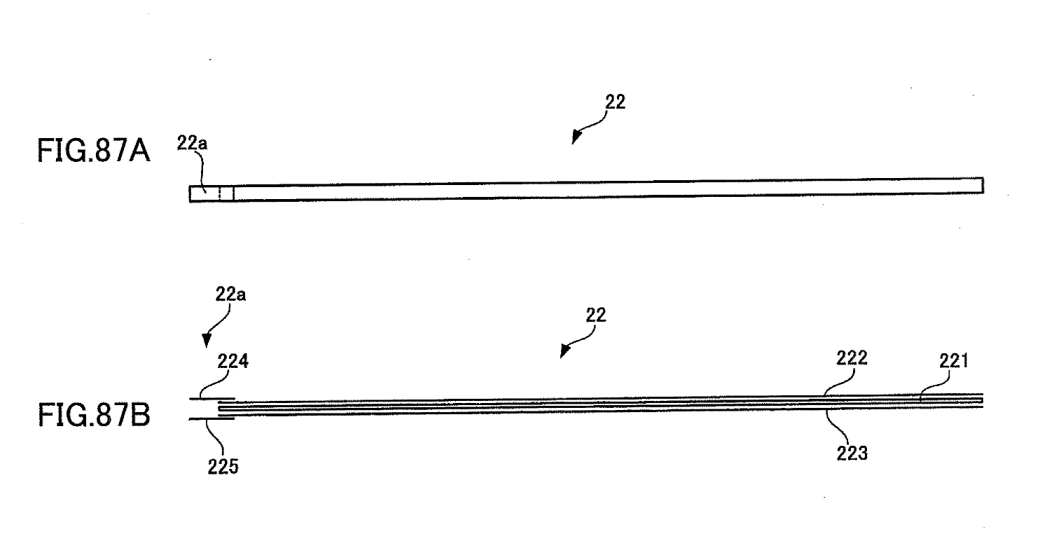

FIG. 87 is a view illustrating a configuration of the double-sided adhesive tape. Specifically, FIG. 87A is a top view, and FIG. 87B is a side view when the elements of the double-sided adhesive tape are separated from each other for explanatory purposes.

The double-sided adhesive tape 22 includes a base material 221 and films 222 and 223. The films 222 and 223 sandwich the base material 221. The base material 221 is relatively thick and has relatively great elasticity and flexibility. The films 222 and 223 are relatively thin and have relatively low elasticity but have greater stiffness.

As the films 222 and 223, for example, a polyethylene terephthalate (PET) film or the like may be used. The films 222 and 223 are adhered to base material 221, and the outer surfaces of the films 222 and 223 have adhesivity (viscosity). Further, the tag 22a formed on one end part of the double-sided adhesive tape 22 is to be protruded outside the image display plate 20 and is formed by adhering films 224 and 225 such as a PET film to the films 222 and 223, respectively. The outer surfaces of the two films 224 and 225 of the tag 22a have no adhesivity (viscosity).

It is preferable that at least one of the inner surfaces of the films 224 and 225 of the tag 22a has adhesivity so that the films 224 and 225 are adhered to each other. However, this is not essentially required. Namely, both of the inner surfaces of the films 224 and 225 may have no adhesivity, so that the films 224 and 225 are separated from each other.

As illustrated in FIG. 87, in a case where the double-sided adhesive tape 22 is configured by sandwiching the base material 221, even if the protection panel 23 is slightly curved, the base material 221 may expand or contract so as to correspond to the curve, so that the double-sided adhesive tape 22 is evenly adhered along the longitudinal direction without causing uneven adhesion.

Further, the base material 221 works effectively when the double-sided adhesive tape 22 is removed to separate the image display plate 21 from the protection panel 23 as described below.

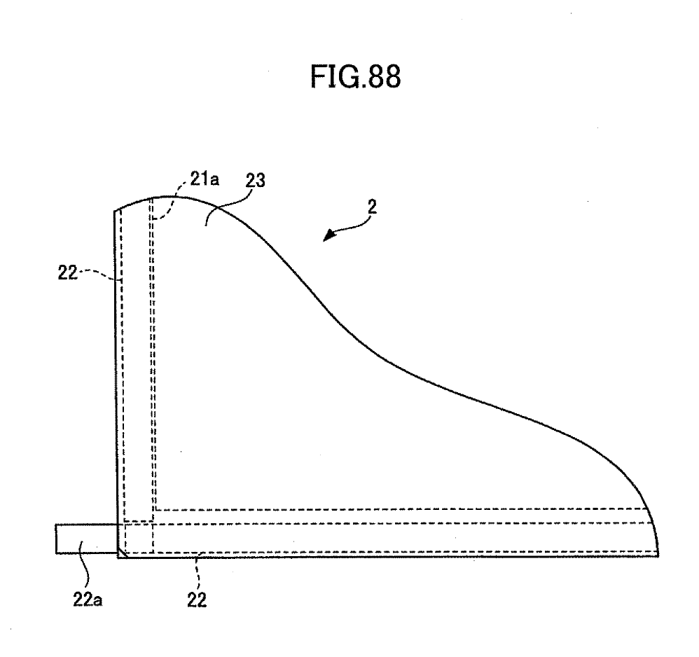

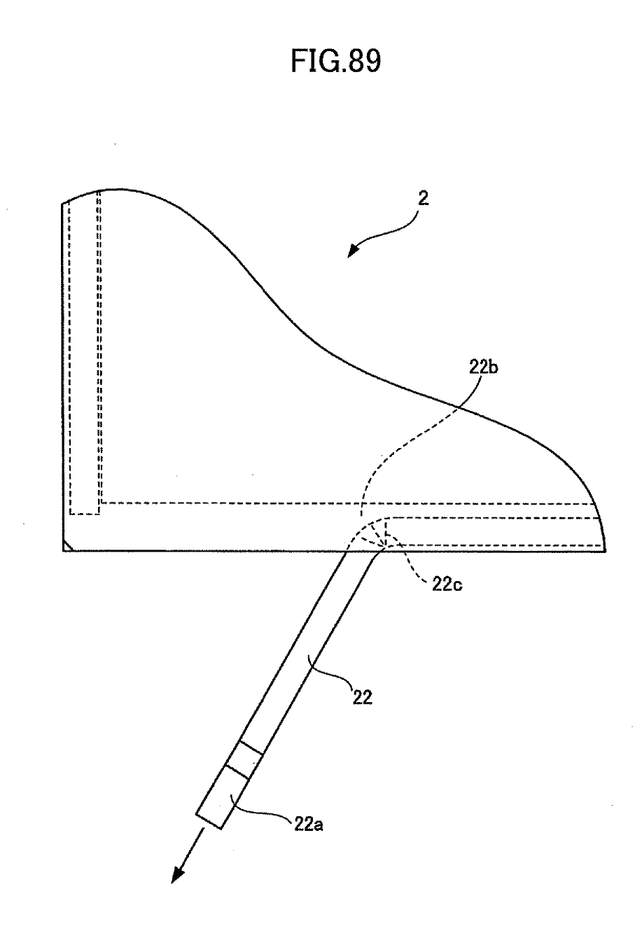

FIG. 88 is a schematic view illustrating a corner of the image display panel. Further, FIG. 89 is a view illustrating a state where the protection panel is partially separated from the image display plate by drawing a tag 22a of the double-sided adhesive tape 22.

When the tag 22a protruding outside of the image display panel 2 is pulled toward a direction crossing with the extending direction of the double-sided adhesive tape 22 of the tag 22a, a curved part 22b is formed in the double-sided adhesive tape 22 and a fold (folds) 22c is also formed at the curved part 22b. As a result, at the curved part 22b where the fold (folds) 22c is also formed, the adhesive force (viscosity force) between the image display plate 20 and the protection panel 23 may be reduced.

By doing this, it may become possible to remove the double-sided adhesive tape 22 smoothly, so that the image display plate 20 and the protection panel 23 are separated from each other smoothly without applying much stress.

The double-sided adhesive tape 22 includes not only the base material 221 but also the films 222 and 223 having elasticity lower than that of the base material 221 and having stiffness greater than that of the base material 221 and sandwiching the base material 221. The double-sided adhesive tape 22 may not be cut or broken even if the double-sided adhesive tape 22 is pulled even with a strong force.

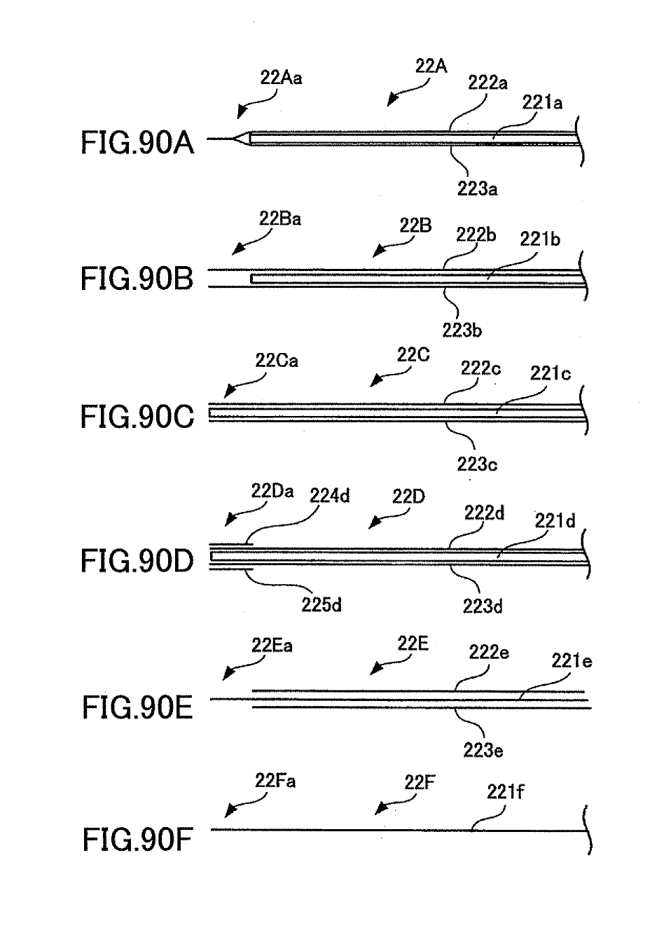

FIGS. 90A through 90F are views illustrating various types of the double-sided adhesive tapes.

A double-sided adhesive tape 22A of FIG. 90A includes a base material 221a which is relatively thick (thicker) and having relatively great (greater) elasticity and flexibility and films 222a and 223a having sufficient stiffness such as a PET film and sandwiching the base material 221a.

The two films 222a and 223a sandwiching the base material 221a are adhered to each other in the part of the tag 22Aa. The outer surfaces of the two films 222a and 223a have adhesivity. The outer surfaces of the tag 22Aa may have adhesivity. However, the outer surfaces of the tag 22Aa may be processed to have no adhesivity.

The double-sided adhesive tape 22B of FIG. 90B includes a base material 221b similar to that of the double-sided adhesive tape 22A and films 222b and 223b similar to those of the double-sided adhesive tape 22A. In the part of a tag 22Ba, there is no base material 221b, and the films 222b and 223b are directly extended. The outer surfaces of the tag 22Ba may have adhesivity. However, the outer surfaces of the tag 22Ba may be processed to have no adhesivity.

The double-sided adhesive tape 22C of FIG. 90C includes a base material 221c similar to that of the double-sided adhesive tapes 22A and 22B and films 222c and 223c similar to those of the double-sided adhesive tapes 22A and 22B. In the part of a tag 22Ca, the configuration of the tag 22Ca is similar to the configuration of the base material 221c and the films 222c and 223c.

Namely, the part including the base material 221c and the films 222c and 223c is directly extended to form the part of the tag 22Ca. The outer surfaces of the tag 22Ba may be processed to have no adhesivity.

The double-sided adhesive tape 22D of FIG. 90D includes a base material 221d similar to that of the double-sided adhesive tapes 22C and films 222c and 223c similar to those of the double-sided adhesive tapes 22C. In the part of a tag 22Da includes the base material 221d and the films 222d and 223d similar to those of the double-sided adhesive tapes 22C.

However, the part of the tag 22Da further includes two short films 224d and 225d adhered to the films 222d and 223d, respectively, so that the films 224d and 225d are outermost films, and the outer surfaces of the tag 22Da have no adhesivity.

The above FIGS. 90A through 90D illustrate examples of the double-sided adhesive tapes including the base material and the films sandwiching the base material. However, by making the protection panel 23 without being curved and adjusting the strength of the adhesivity of the double-sided adhesive tape, the following double-sided adhesive tapes 22E and 22F having configurations of FIGS. 90E and 90F, respectively, may be used.

In the double-sided adhesive tape 22E illustrated in FIG. 90E, a film 221e made of a thin PET film or the like is used as the base material, and two films 222e and 222f made of a thin PET film or the like as well are adhered to the corresponding surfaces of the base material. In the part of the tag 22Ea, there is only the extended film 221e of the base material.

The double-sided adhesive tape 22F illustrated in FIG. 90F includes only one film 221f such as a thin PET film. The both surfaces of the film 221f have adhesivity. However, the part of the tag 22Fa may have no adhesivity.

It may depend on a material, a degree of curve and the like of the image display plate 20 and the protection panel 23, various types of the double-sided adhesive tapes as illustrated in FIGS. 90A through 90F may be used.

### Reinforced Structure of Display Device Having Optical Touch Panel

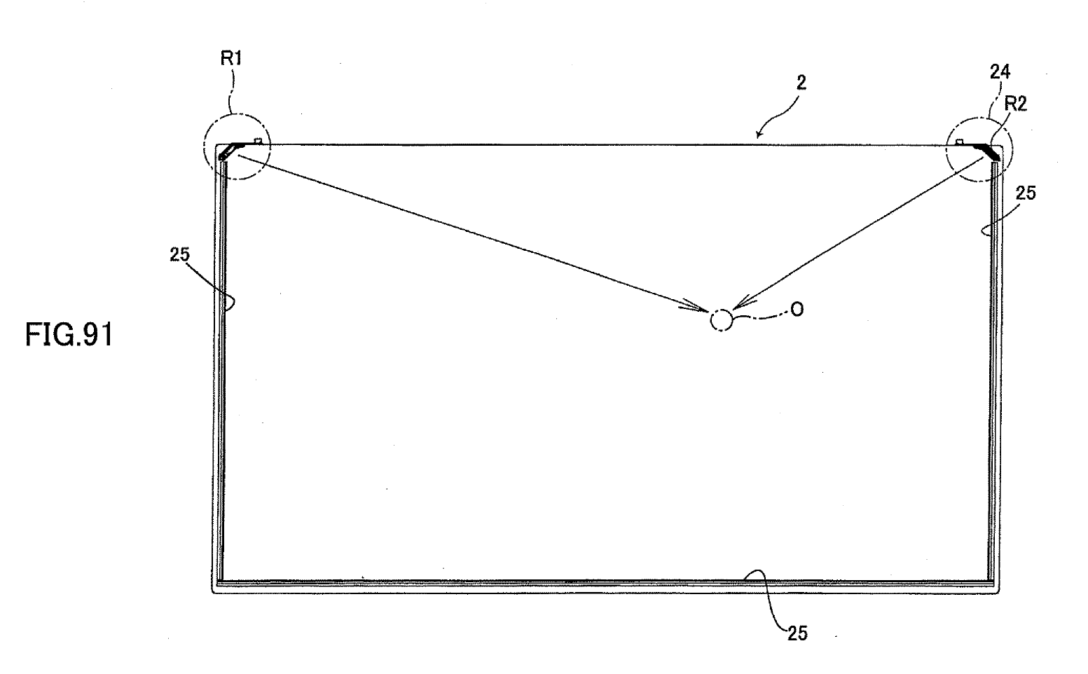

FIG. 91 is a top view illustrating a front surface of the image display panel. However, in the following, the tag of the double-sided adhesive tape may not be illustrated.

As described above, two infrared light emitting and receiving units 24 for touch sensors are disposed at the corresponding the right and the left ends of the upper end of the image display panel 2. Further the reflection surfaces 25 standing (raised) on the image display panel 2 and facing inside of the image display panel 2 are disposed and extend along the right and the left ends and the lower end of the image display panel 2. Those reflection surfaces 25 reflect the infrared light emitted from the infrared light emitting and receiving units 24.

Further, the reflection surface 25 is not disposed on the upper end side of the image display panel 2. Namely, in the above description, it is required to form a space in the region along the upper end of the image display panel 2 without disposing a reflection body to reflect the infrared light emitted from the reflection surfaces 25. However, on the upper end of the image display panel 2, as described blow, a rib having a predetermined height may be disposed at a predetermined position.

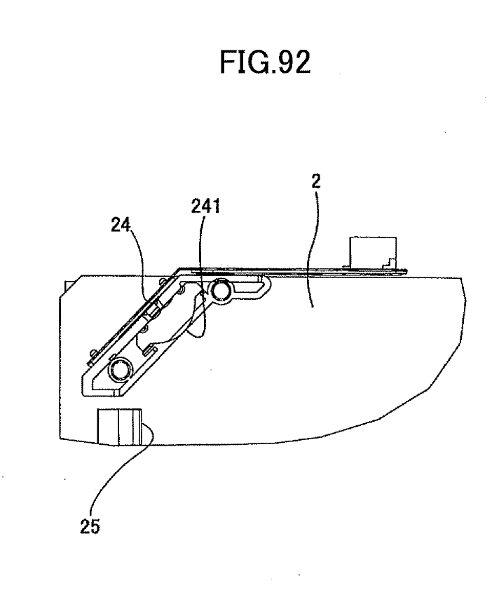

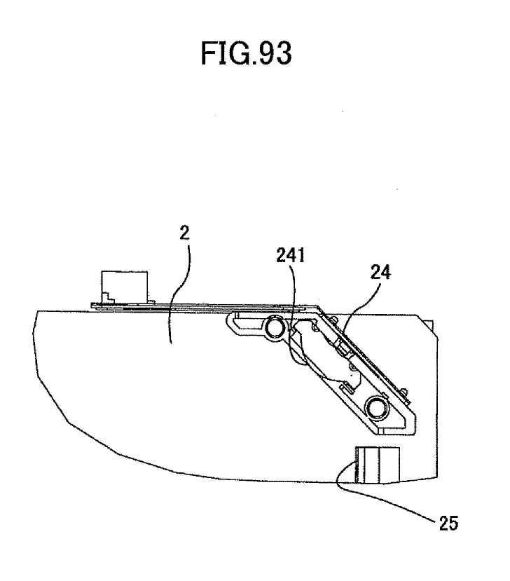

FIGS. 92 and 93 are a top view illustrating infrared light emitting and receiving units disposed at a left upper corner and a right upper corner, respectively, on the front surface of the image display panel 2.

The infrared light emitting and receiving unit 24 includes an infrared light emitting unit that emits an infrared light and an infrared light receiving unit that receives the infrared light, the infrared light emitting unit and the infrared light receiving unit being laminated to each other. The infrared light emitting unit emits infrared light flux to spread like a fan along the front surface of the image display panel 2.

The infrared light receiving unit receives infrared light via a lens 241, the infrared light being emitted by the infrared light emitting unit and being reflected by the reflection surface 25 (see FIG. 91) disposed along the left, the right, or the lower end of the image display panel 2. The infrared light receiving unit further receives returned infrared light reflected by an object “O” when the object “O” including a finger, a pen, or any other object is placed on the surface of the image display panel 2.

An acquired received signal corresponding to the infrared light received by the infrared light receiving unit is input to a processing circuit (not shown), so that the position of the object “O” on the image display panel 2 is detected.

Next, a configuration (structure), including the front cover, for supporting the image display panel 2 having the configuration described above is described.

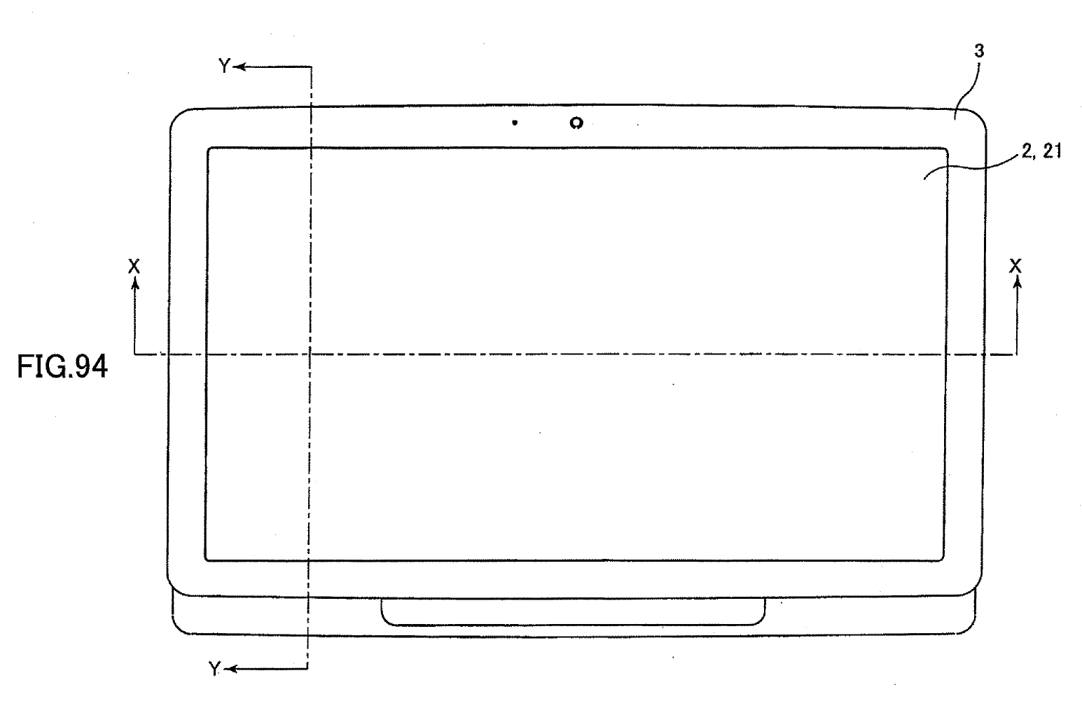

FIG. 94 is a view illustrating the front cover 3 supporting the image display panel 2 when viewed from the front side of the front cover. The front cover 3 is a member having a frame shape that circumferentially surrounds the circumferential end of the front surface of the image display panel 2. The front cover 3 supports the front surface of the image display panel 2 in a manner that the front surface excluding the circumferential end of the front surface of the image display panel 2 is exposed. The front cover 3 has a size protruding outside the circumferential end of the front surface of the image display panel 2.

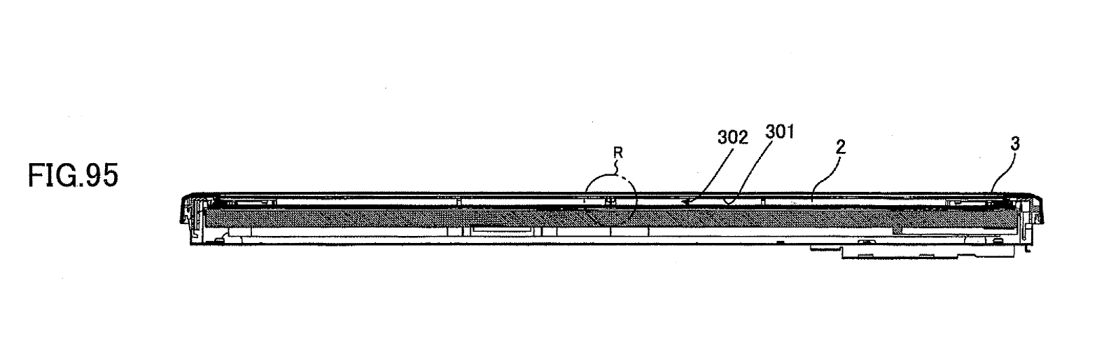

FIG. 95 is a cross-sectional view when cut along the line X-X of FIG. 94.

As illustrated in FIG. 95, in a region along the upper end of the image display panel 2, there is a gap 302 generated between an inner surface 301 of the front cover 3 and the front surface of the image display panel 2.

FIG. 96 is an enlarged view of a part of a circle R of FIG. 95. In the gap 302 between an inner surface 301 of the front cover 3 and the front surface of the image display panel 2, there is illustrated a reinforcing bracket 310 described below. Further, there is the rib 303 standing in the center part on the inner surface 301 of the front cover 3.

On the other hand, on the reinforcing bracket 310, there is formed a hole 310a to pass the rib 303. The rib 303 is allowed to be disposed along (on) the upper end of the image display panel 2 in accordance with limitations based on the height and length of the hole 310a without interfering with the detection of the infrared light by the infrared light emitting and receiving unit 24. Further, the rib 303 blocks unnecessary light.

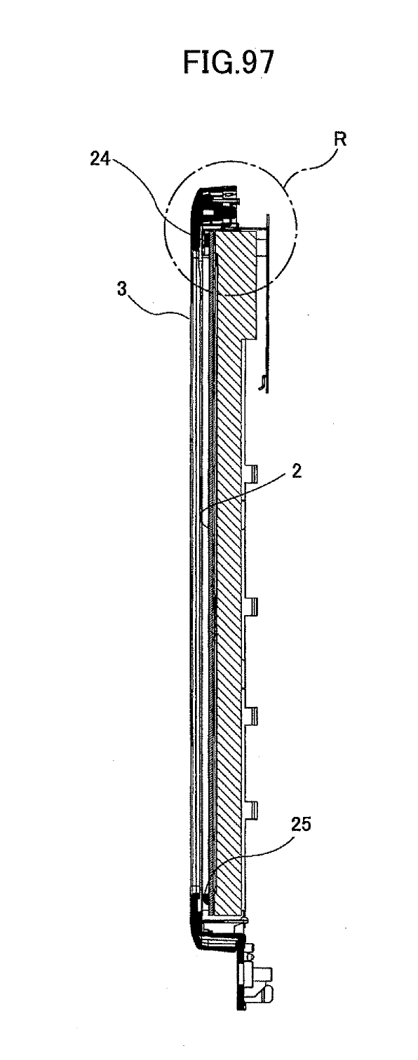

FIG. 97 is a cross-sectional view when cut along the line Y-Y of FIG. 94. The cross-sectional view illustrates the infrared light emitting and receiving unit 24 disposed at an upper end corner of the image display panel 2 and the reflection surface 25 formed along the lower end of the image display panel 2.

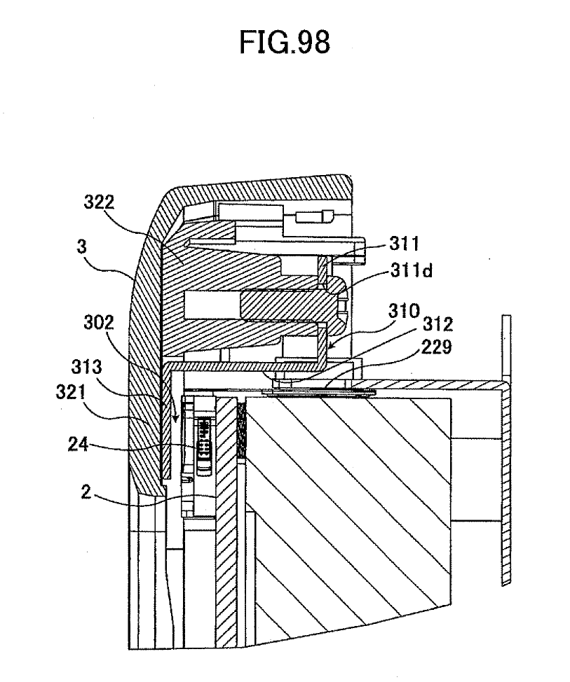

FIG. 98 is an enlarged view of a part of a circle R of FIG. 97.

As illustrated in FIG. 98, the front cover 3 includes a shield plate 321 in a part extending along the upper end of the image display panel 2. The shield plate 321 covers the upper end of the of the image display panel 2 with the gap 302 between the shield plate 321 and the front surface of the image display panel 2 and extending in the right and left direction (i.e., the vertical direction relative to the sheet of FIG. 98). Further, the front cover 3 further includes an arm part 322 disposed further on the upper side of an upper end surface 229 of the image display panel 2 and extending in the right and left direction (the vertical direction relative to the sheet of FIG. 98).

Further, FIG. 98 also illustrates the reinforcing bracket 310. As illustrated in FIG. 98, the reinforcing bracket 310 includes a first plate part 311, a second plate part 312 folded from the first plate part 311, and a third plate part 313 further folded from the second plate part 312. The first plate part 311 extends along a surface facing the rear surface side of the arm part 322.

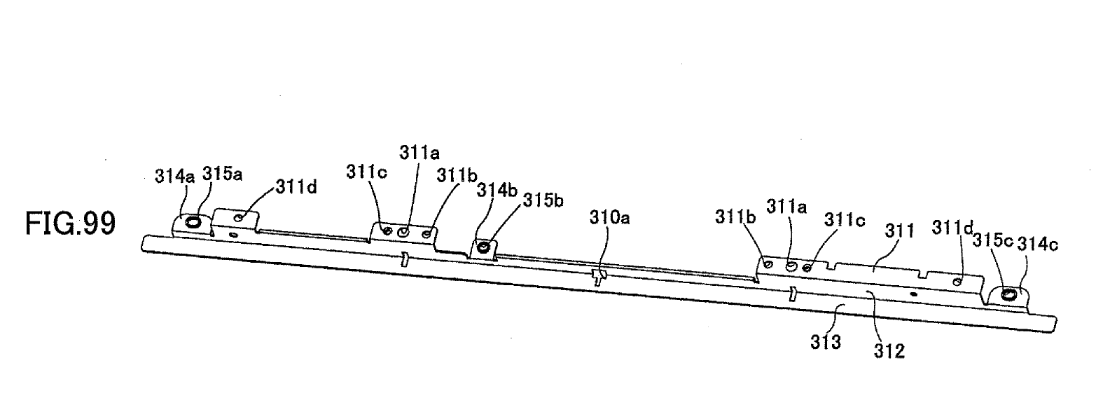

Further, the second plate part 312 extends along a surface of the arm part 322, the surface facing the upper end surface 229 of the image display panel 2. The third plate part 313 extends along a rear surface of the shield plate 321, the rear surface facing the front surface side of the image display panel 2. The reinforcing bracket 310 is fixed to the arm part 322 with screws screwing through fixing holes 311d (see FIG. 99). The reinforcing bracket 310 is folded as described above, the reinforcing bracket 310 has sufficient strength (stiffness) even when the reinforcing bracket 310 is made of a thin plate.

As described above, there is generated the gap 302 between the rear surface of the shield plate 321 of the front cover 3 and the image display panel 2. Therefore, if there is no reinforcing bracket 310, for example, the surface of the part corresponding to the gap is more likely to be deformed with a ripple shape or swollen, which may cause degradation of the quality of the product.

In this embodiment, however, the reinforcing bracket 310 having reinforced strength (stiffness) by folding as described above is fixed to a position outside a viewing field (i.e., infrared light expanding area). Therefore, the strength of the part corresponding to the shield plate 321 of the front cover 3 may be reinforced, and the product quality may also be maintained.

FIG. 99 is a perspective view of the entire supporting bracket;

As described with reference to FIG. 98, the reinforcing bracket 310 includes a first plate part 311, a second plate part 312 folded from the first plate part 311, and a third plate part 313 further folded from the second plate part 312. The reinforcing bracket 310 has includes those three plate parts folded as described above and extending in the longitudinal direction. Therefore, the reinforcing bracket 310 has sufficient strength even though the reinforcing bracket 310 is made of a thin plate.

Further, in the center part in the right and left direction of the reinforcing bracket 310, the hole 310a though which the rib 303 standing and formed on the rear surface of the front cover 3 is entered. Further, the reinforcing bracket 310 includes three folded parts 314a, 314b, and 314c extending in the direction parallel to the extending direction of the first plate part 311. On the folded parts 314a, 314b, and 314c, there are formed position-determining holes 315a, 315b, and 315c, respectively for determining the position of the reinforcing bracket 310 relative to the front cover 3.

Among those position-determining holes 315a, 315b, and 315c, the position-determining hole 315b is located in the center and has a round shape for determining the position of the center part of the reinforcing bracket 310. On the other hand, the position-determining holes 315a and 315c located on the right and the left sides have a horizontally-long ellipse shape. On the other hand, on the front cover 3, there are formed three position determining bosses 309a, 309b, and 309c (see FIG. 100). By entering the position-determining bosses 309a, 309b, and 309c into the corresponding position-determining holes 315a, 315b, and 315c, the position of the reinforcing bracket 310 relative to the front cover 3 is determined.

Here, the front cover 3 is made of a resin molded product. Therefore, the size of the front cover 3 may vary in its manufacturing process. Therefore, the shape of only the position-determining hole 315b located in the center part is a circular shape, and the shape of the position-determining holes 315a and 315c located on the right and the left sides are an ellipsoidal shape. By doing this, even when the size of the front cover varies, it becomes possible to fix the reinforcing bracket 310 to the front cover 3.

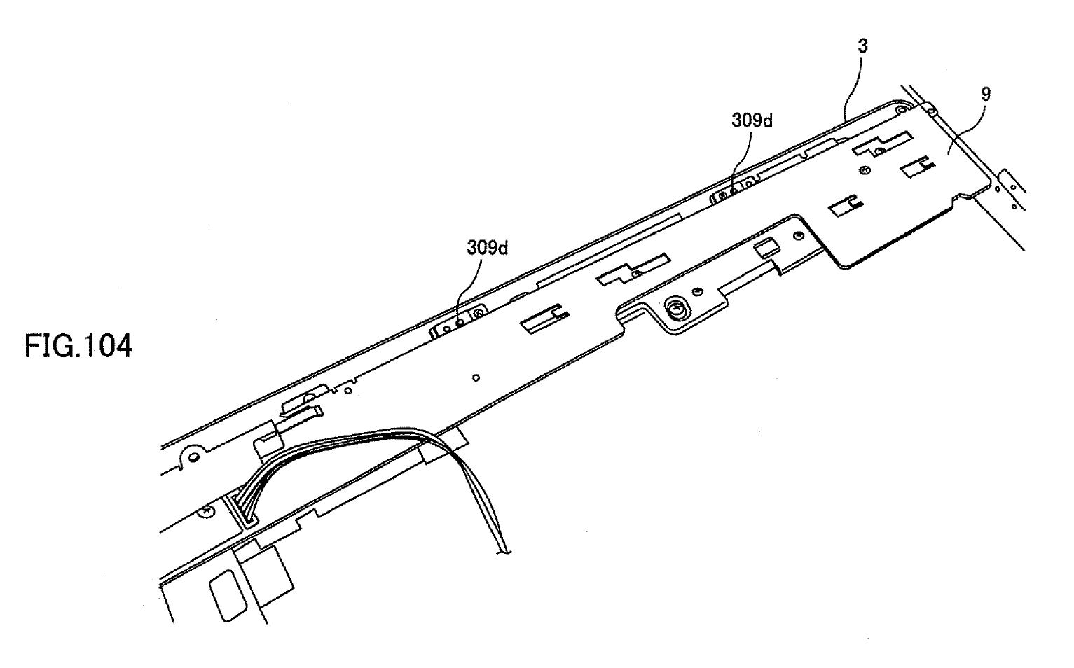

Further, on the first plate part 311, there are two groups of holes, each group including three holes which are a position-determining hole 311a, a fixing hole 311b for fixing with a screw, and a screw hole 311c for fixing the supporting member 9 (see FIGS. 10 and 104) with a screw. Further, on the first plate part 311, there are formed two fixing holes 311d for fixing the reinforcing bracket 310 with screws.

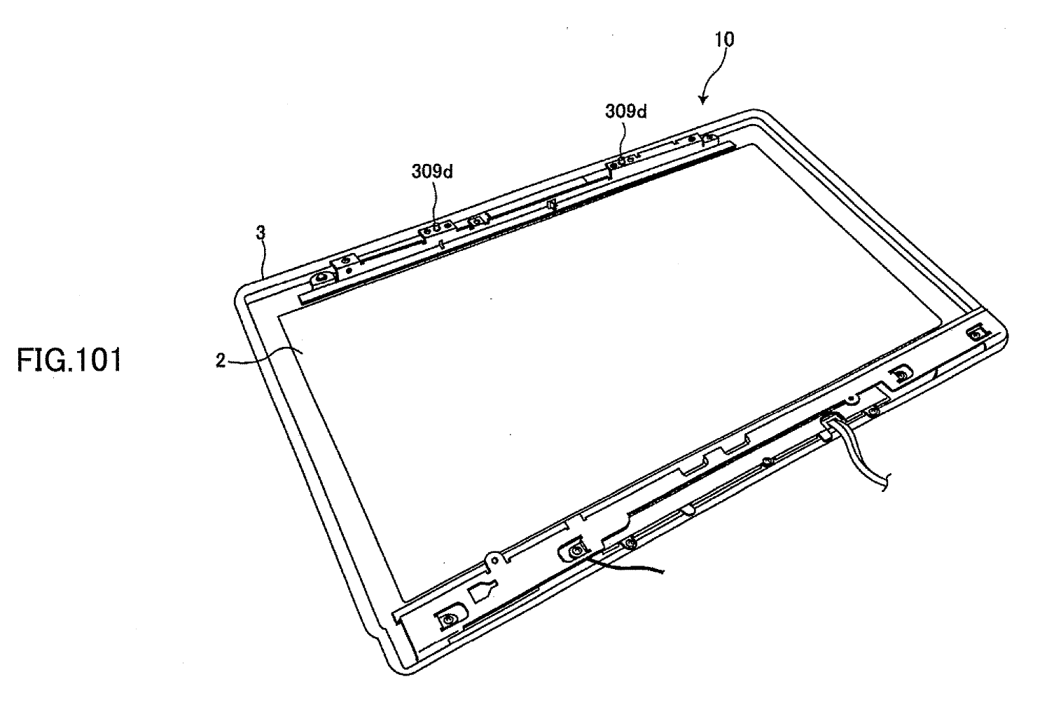

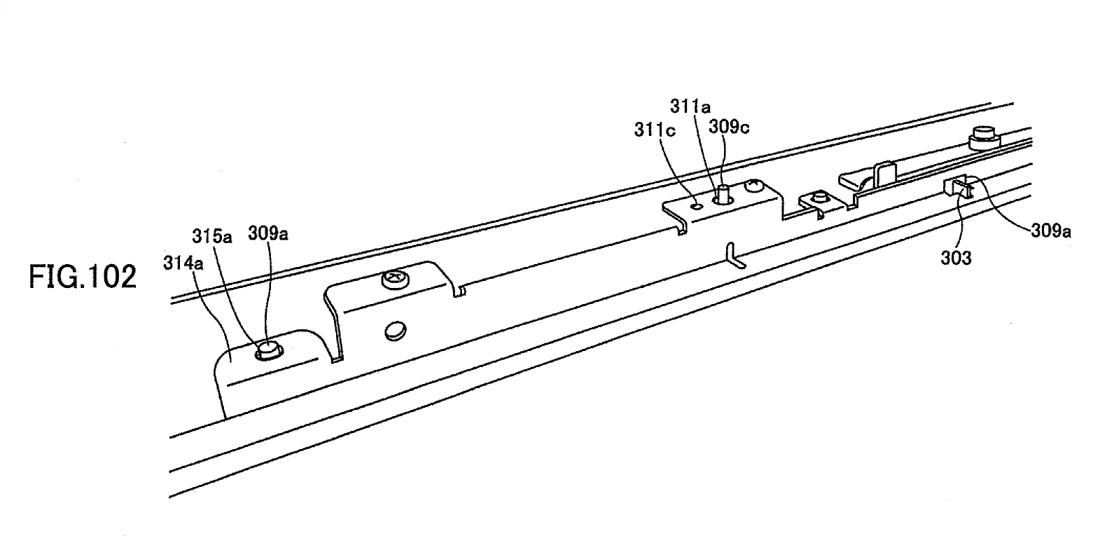

FIG. 100 is a top view illustrating an upper part of the inner surface of the front cover when the reinforcing bracket is fixed to the front cover. Further, FIG. 101 is a perspective view illustrating an inner surface side of the front cover in the state of FIG. 100. Further, FIG. 102 is an enlarged perspective view illustrating a part of the upper side of the inner surface of the front cover in the state of FIG. 100.

The position-determining hole 311a, the fixing hole 311b for fixing with a screw, and the screw hole 311c for fixing the supporting member 9 in each of the two groups are used as described below. A rib (boss) 309d formed on the inner surface of the front cover is entered into the position-determining hole 311a.

The fixing hole 311b is used to fix the first plate part 311 of the reinforcing bracket 310 to the front cover with a screw. Further, the two fixing holes 311d are used for fixing the reinforcing bracket 310 to the front cover 3 with screws. At this stage, however, the screw hole 311c for fixing the supporting member 9 is not used.

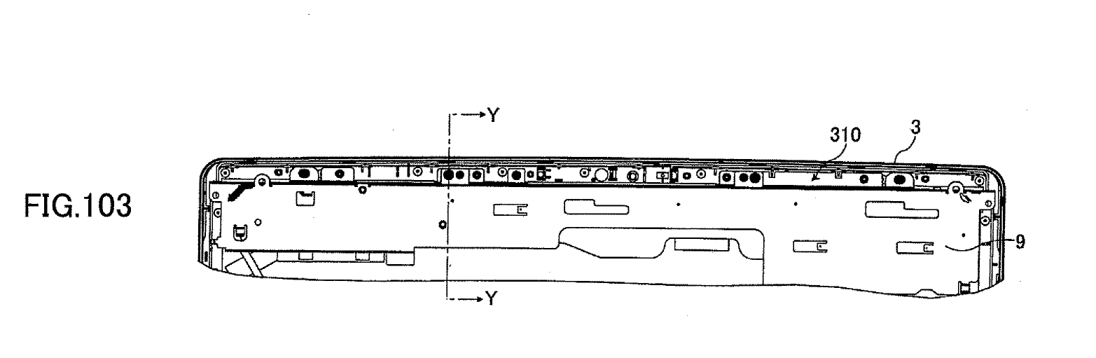

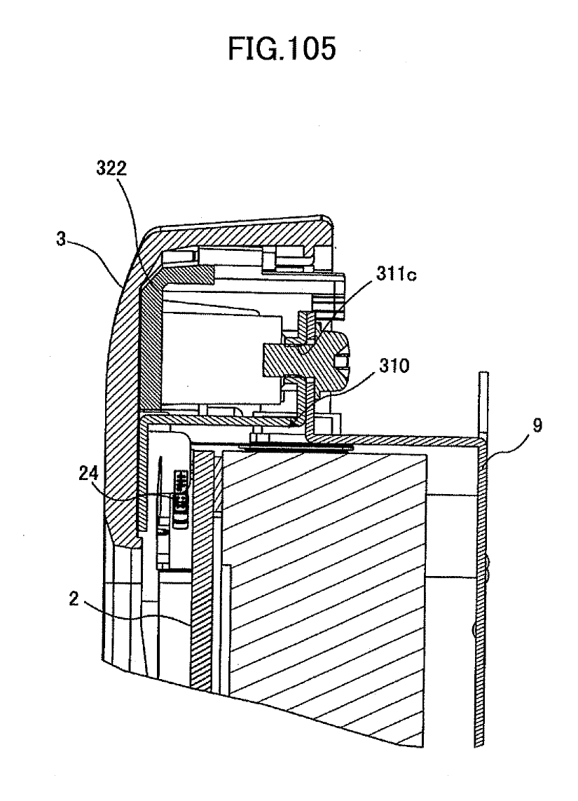

FIGS. 103 and 104 are top views illustrating the upper side of the inner surface of the front cover when a supporting member 9 is further fixed to the front cover. Further, FIG. 105 is an enlarged cross-sectional view when cut along the line Y-Y of FIG. 103.

The position of the supporting member 9 is fixed by the boss 309d same as the boss 309d used to determine the position of the reinforcing bracket 310. Further, the supporting member 9 is fixed to the reinforcing bracket 310 with a screw using the screw hole 311c on the reinforcing bracket 310.

By doing this, by using the boss 309d, which is used for fixing to the front cover 3, to directly determine the position of the supporting member 9 relative to the reinforcing bracket 310, it may become possible to reduce the positional error when determining the positions of the front cover 3, reinforcing bracket 310, and supporting member 8 in this order. Therefore, it may become possible to obtained accurate position determination of elements in the device.

All examples and conditional language recited herein are intended for pedagogical purposes to aid the reader in understanding the invention and the concepts contributed by the inventors to furthering the art, and are to be construed as being without limitation to such specifically recited examples and conditions, nor does the organization of such examples in the specification relate to a showing of superiority or inferiority of the invention. Although the embodiments of the present inventions has been described in detail, it is to be understood that various changes, substitutions, and alterations could be made hereto without departing from the sprit and scope of the invention.

What is claimed is:

1. An electronic component container comprising:
an electronic component to be contained;
a holder including
a holder base part, and
first and second ribs standing on left and right ends, respectively, of the holder base part and extending in a front and back direction so as to form a container configured to contain the electronic component; and
a supporting plate
including a supporting plate base part extending along a lower surface of the electronic component, the lower surface facing the supporting plate base part, in a manner that a gap between the lower surface and the supporting plate base part,
configured to be fixed to the electronic component, and
configured to be fixed to the holder in a manner that, when the electronic component is to be contained in the container, the supporting plate base part is placed at a mounting position of the container of the holder in the direction where the supporting plate base part is to be in contact with the holder base part, and the supporting plate is slid forward from the mounting position to a supporting position,
wherein the holder further includes latch protrusions protruding in a lateral direction from the first and the second ribs, above the holder base part, and at a height position corresponding to the height position of the supporting plate base part when the supporting plate base part is placed on the holder base part,
wherein the supporting plate includes cutout sections formed at positions on left and right ends of the supporting plate base part so as to avoid interference with the latch protrusions when the supporting plate base part is placed on the holder base part at the mounting position, and
wherein, when the supporting plate is slid forward from the mounting position to the supporting position, the supporting plate base part is latched between the latch protrusions and the holder base part.

2. The electronic component container according to claim 1,
wherein the supporting plate base part includes swollen parts swollen toward the latch protrusions and disposed at positions where the swollen parts are to be in contact with the latch protrusions when the supporting plate is slid to the supporting position.

3. The electronic component container according to claim 1,
wherein the holder further includes a front wall standing on a front end of the holder base part and extending in a left and right direction and a table part connected to the front wall and extending in a direction parallel to a direction of the holder base part and in a forward of the holder base part,
wherein the supporting plate further includes a standing part folded from the supporting plate base part at a front end of the supporting plate base part and standing along a front wall of the electronic component and a flange part folded from the standing part and extending in a direction parallel to a direction of the supporting plate base part and in a forward direction of the supporting plate base part, and the flange part is configured to be placed on the table part when the electronic component is contained,
wherein the flange part includes a fixing hole for fixing with a screw, and the table part includes a screw hole at a position where the screw hole is in communication with the fixing hole when the supporting plate is slid to the supporting position, and the supporting plate is fixed to the holder with a screw entered through the fixing hole and screwed into the screw hole.

4. The electronic component container according to claim 3,
wherein the table part includes guide protrusions and the flange part includes guide openings configured to be guided by the guide protrusions by entering the guide protrusions into the guide openings while the supporting plate is slid from the mounting position to the supporting position.

5. The electronic component container according to claim 4,
wherein the cutout sections disposed at positions on left and right ends of the supporting plate base part are formed so as to avoid interference with the latch protrusions when the guide protrusions are entered into the guide openings while a front end of the supporting plate is obliquely lowered and then a rear end of the supporting plate is lowered toward the holder base part with the latch protrusions as a rotational center.

6. The electronic component container according to claim 1,
wherein the electronic component includes a heat generating component heating a lower surface of the electronic component, the lower surface facing the supporting plate base part,
wherein the supporting plate base part include a first hole penetrating between front and rear surfaces of the supporting plate base part, and
wherein the holder base part includes a second hole penetrating between front and rear surfaces of the holder base part, the second hole being configured to be in communication with the first hole when the supporting plate is slid to the supporting position.

7. The electronic component container according to claim 1,
wherein the electronic component is a hard disk drive including a hard disk where data are magnetically written into, stored in, and read from and a motor rotating the hard disk while the data are written into and read from the hard disk.

8. An electronic device comprising:
the electronic component container according to claim 1;
an image display panel including front and rear surfaces and an image display screen displaying an image on the front surface;
a front cover configured to support the image display panel and expose the image display screen by circumferentially surrounding a peripheral border of a front surface of the image display panel; and
a rear cover configured to extend along a rear surface of the image display panel so as to form an inner space between the rear surface of the image display panel and the rear cover and define an exterior of the electronic device along with the front cover,
wherein the electronic component container is included in the inner space.
